(19) United States
(12) Patent Application Publication
(10) Pub. No.: US 2014/0014948 A1
(43) Pub. Date: Jan. 16, 2014

(54) SEMICONDUCTOR DEVICE

(71) Applicant: Semiconductor Energy Laboratory Co. Ltd., Atsugi-shi (JP)

(72) Inventor: Hideki MATSUKURA, Isehara (JP)

(21) Appl. No.: 13/933,362

(22) Filed: Jul. 2, 2013

(30) Foreign Application Priority Data
Jul. 12, 2012 (JP) 2012-156885

(51) Int. Cl. H01L 29/786

(52) U.S. Cl. CPC H01L 29/78606; H01L 29/7869
USPC 257/43

(57) ABSTRACT

To provide a structure for containing H₂O in an oxide semiconductor layer. An insulating layer is provided over a first conductive layer. A first oxide semiconductor layer is provided over the insulating layer. A second oxide semiconductor layer is provided over the insulating layer. A second conductive layer is provided over the first oxide semiconductor layer. A third conductive layer is provided over the first oxide semiconductor layer. An inorganic insulating layer is provided over the second conductive layer and the third conductive layer. A resin layer is provided over the inorganic insulating layer. The first oxide semiconductor layer includes a region overlapping with the first conductive layer. The resin layer is not in contact with the first oxide semiconductor layer. The resin layer includes a portion being in contact with the second oxide semiconductor layer in the inside of a hole of the inorganic insulating layer.

### BACKGROUND OF THE INVENTION

1. Field of the Invention

The technical field of the present invention relates to a semiconductor device.

2. Description of the Related Art

In Patent Document 1, a transistor including an oxide semiconductor layer is disclosed.

A paragraph 0012 in Patent Document 1 discloses the following: “it is said that a substance containing a hydrogen element is an element which prevents an oxide semiconductor layer from being highly purified so that the oxide semiconductor layer is not close to an i-type oxide semiconductor layer because a hydrogen element has two factors of inducing carriers”.

A paragraph 0013 in Patent Document 1 discloses the following: “as a substance containing a hydrogen element, for example, hydrogen, moisture, hydroxide, hydride, and the like can be given”.

Patent Document 1 discloses that, when a substance containing a hydrogen element is contained in an oxide semiconductor layer of a transistor, the threshold voltage of the transistor shifts in a negative direction.

### REFERENCE

### Patent Document

[Patent Document 1] Japanese Published Patent Application No. 2011-142311

### SUMMARY OF THE INVENTION

As disclosed in Patent Document 1, H₂O (water) is a molecule which prevents an oxide semiconductor layer from being purified so that the oxide semiconductor layer is not close to an i-type oxide semiconductor layer.

However, the present inventor thought that there is a merit in intentionally containing H₂O in the oxide semiconductor layer.

Thus, a first object of the invention to be disclosed below is to provide a structure for containing H₂O in an oxide semiconductor layer.

A second object is to provide a semiconductor device including a novel structure.

A third object is to use effectively a space in which an active layer is not formed.

Further, as disclosed in Patent Document 1, H (hydrogen) is an element which prevents an oxide semiconductor layer from being purified so that the oxide semiconductor layer is not close to an i-type oxide semiconductor layer.

However, the present inventor thought that there is a merit in intentionally containing H in an oxide semiconductor layer.

Thus, a fourth object of the invention to be disclosed below is to provide a structure for containing H in an oxide semiconductor layer.

The invention to be disclosed below achieves at least one of the first to the fourth objects.

For example, an inorganic insulating layer is provided over a first oxide semiconductor layer and a second oxide semiconductor layer.

For example, a hole is provided in the inorganic insulating layer.

For example, a resin layer is provided over the inorganic insulating layer.

Further, the resin layer is prevented from being in contact with the first oxide semiconductor layer, and the resin layer is made to be in contact with the second oxide semiconductor layer in the inside of the hole.

The content of H₂O in the resin layer is much higher than the content of H₂O in the inorganic insulating layer.

By the contact of the resin layer with the oxide semiconductor layer, H₂O in the resin layer easily moves into the oxide semiconductor layer.

Further, the inorganic insulating layer has a function of blocking H₂O.

Thus, the content of H₂O in the second oxide semiconductor layer can be higher than the content of H₂O in the first oxide semiconductor layer.

That is, at least a part of the second oxide semiconductor layer is made to be in contact with at least a part of the resin layer, whereby H₂O can be contained in the second oxide semiconductor layer.

Here, a use for the first oxide semiconductor layer is as an active layer of a transistor, for example.

An active layer refers to a semiconductor layer including a region where a channel can be formed (a channel formation region).

The first oxide semiconductor layer is not in contact with the resin layer; thus, the threshold voltage of the transistor can be prevented from shifting in the negative direction.

Examples of uses for the second oxide semiconductor layer include the following.

For example, the second oxide semiconductor layer is used as at least a part of a wiring. In that case, since the content of H₂O in the second oxide semiconductor layer can be increased, the resistivity of the second oxide semiconductor layer can be reduced.

For example, the second oxide semiconductor layer is used as at least a part of an electrode. In that case, since the content of H₂O in the second oxide semiconductor layer can be increased, the resistivity of the second oxide semiconductor layer can be reduced.

For example, the second oxide semiconductor layer is used as at least a part of a resistor. In that case, since the content of H₂O in the second oxide semiconductor layer can be increased, the resistivity of the second oxide semiconductor layer can be reduced.

For example, the second oxide semiconductor layer is used as an active layer of a transistor. In that case, the content of H₂O in the second oxide semiconductor layer can be increased. Thus, the transistor including the first oxide semiconductor layer and the transistor including the second oxide semiconductor layer can have different threshold voltage values.

The first object is to provide a structure for containing H₂O in the oxide semiconductor layer.

Hence, in view of the first object, it is apparent that the uses for the second oxide semiconductor layer are not limited to those given as the above examples.

In the case where the second oxide semiconductor layer is used as at least a part of a wiring or in the case where the second oxide semiconductor layer is used as at least a part of an electrode, in order to increase the content of H (hydrogen) in the second oxide semiconductor layer, a substance containing H may be contained in the second oxide semiconductor layer.

The substance containing H is made to be contained in the second oxide semiconductor layer, whereby the resistivity of the second oxide semiconductor layer can be reduced.

As a method for making the substance containing H be contained in the second oxide semiconductor layer, there is a method in which the substance containing H is added by ion doping or ion implantation, or the like. However, the method is not limited to this.

For example, there is a method in which H₂, H₂O, PH₃, B₂H₆, or the like is added by ion doping or ion implantation.

Incidentally, H₂O released from the second oxide semiconductor layer moves in the inorganic insulating layer or under the inorganic insulating layer and reaches the first oxide semiconductor layer in some cases.

Although the amount of H₂O that moves in the inorganic insulating layer or under the inorganic insulating layer is very small, such H₂O affects the electrical characteristics of the transistor including the first oxide semiconductor layer in some cases.

Thus, it is preferable to provide a third oxide semiconductor layer between the first oxide semiconductor layer and the second oxide semiconductor layer.

H₂O is absorbed into the third oxide semiconductor layer; thus, the amount of H₂O reaching the first oxide semiconductor layer can be reduced.

In the case where the third oxide semiconductor layer is in contact with the resin layer, H₂O released from the third oxide semiconductor layer reaches the first oxide semiconductor layer in some cases.

Thus, it is preferable that the third oxide semiconductor layer be not in contact with the resin layer.

The second object is to provide a semiconductor device including a novel structure.

In the case of achieving the second object, the semiconductor layer is not limited to an oxide semiconductor layer; a layer containing silicon or the like may be used as the semiconductor layer.

The third object is to use effectively a space in which an active layer is not formed.

A second oxide semiconductor layer having a predetermined use is formed; thus, a space in which an active layer is not formed can be used effectively.

For example, the second oxide semiconductor layer can be used as at least a part of a wiring.

For example, the second oxide semiconductor layer can be used as at least a part of an electrode.

For example, the second oxide semiconductor layer can be used as at least a part of a resistor.

The uses for the second oxide semiconductor layer are not limited to those given as the above examples.

In the case of achieving the third object, the semiconductor layer is not limited to an oxide semiconductor layer; a layer containing silicon or the like may be used as the semiconductor layer.

To achieve the fourth object, a layer containing hydrogen (H) is provided.

The layer containing hydrogen is prevented from being in contact with the first oxide semiconductor layer, and the layer containing hydrogen is made to be in contact with the second oxide semiconductor layer.

The content of H in the layer containing hydrogen is higher than that in the inorganic insulating layer.

The layer containing hydrogen can be formed using an insulating layer, a semiconductor layer, a conductive layer, or the like.

For example, after a predetermined layer (an insulating layer, a semiconductor layer, a conductive layer, or the like) is formed, a substance containing H is made to be contained in the predetermined layer; thus, the layer containing hydrogen can be formed.

A method in which a substance containing H is added by ion doping or ion implantation is given, for example; however, the method for forming the layer containing hydrogen is not limited to this.

For example, film formation is performed with the use of the substance containing H as part of a film formation gas, whereby the layer containing hydrogen can be formed.

Examples of a film formation method include a sputtering method and a CVD method, but the film formation method is not limited to these examples.

Examples of the substance containing H include H₂, H₂O, PH₃, and B₂H₆, but the substance containing H is not limited to these examples.

By the contact of the layer containing hydrogen with the oxide semiconductor layer, H in the layer containing hydrogen easily moves into the oxide semiconductor layer.

Thus, the content of H in the second oxide semiconductor layer can be higher than the content of H in the first oxide semiconductor layer.

That is, at least a part of the second oxide semiconductor layer is made to be in contact with at least a part of the layer containing hydrogen, whereby H can be contained in the second oxide semiconductor layer.

Here, a use for the first oxide semiconductor layer is as an active layer of a transistor, for example.

An active layer refers to a semiconductor layer including a region where a channel can be formed (a channel formation region).

The first oxide semiconductor layer is not in contact with the layer containing hydrogen; thus, the threshold voltage of the transistor can be prevented from shifting in the negative direction.

Examples of uses for the second oxide semiconductor layer include the following.

For example, the second oxide semiconductor layer is used as at least a part of a wiring. In that case, since the content of H in the second oxide semiconductor layer can be increased, the resistivity of the second oxide semiconductor layer can be reduced.

For example, the second oxide semiconductor layer is used as at least a part of an electrode. In that case, since the content of H in the second oxide semiconductor layer can be increased, the resistivity of the second oxide semiconductor layer can be reduced.

For example, the second oxide semiconductor layer is used as at least a part of a resistor. In that case, since the content of H in the second oxide semiconductor layer can be increased, the resistivity of the second oxide semiconductor layer can be reduced.

For example, the second oxide semiconductor layer is used as an active layer of a transistor. In that case, the content of H in the second oxide semiconductor layer can be increased. Thus, the transistor including the first oxide semiconductor layer and the transistor including the second oxide semiconductor layer can have different threshold voltage values.

The fourth object is to provide a structure in which H is contained in an oxide semiconductor layer.

Hence, in view of the fourth object, it is apparent that the uses for the second oxide semiconductor layer are not limited to those given as the above examples.

Note that when H in the second oxide semiconductor layer is released, the H is released in a state where the H is bonded to O in the second oxide semiconductor layer in some cases.

Thus, H₂O is released from the second oxide semiconductor layer in some cases.

Further, H₂O released from the second oxide semiconductor layer moves in the inorganic insulating layer or under the inorganic insulating layer and reaches the first oxide semiconductor layer in some cases.

Although the amount of H₂O that moves in the inorganic insulating layer or under the inorganic insulating layer is very small, such H₂O affects the electrical characteristics of the transistor including the first oxide semiconductor layer in some cases

Thus, it is preferable to provide the third oxide semiconductor layer between the first oxide semiconductor layer and the second oxide semiconductor layer.

H₂O is absorbed into the third oxide semiconductor layer; thus, the amount of H₂O reaching the first oxide semiconductor layer can be reduced.

In the case where the third oxide semiconductor layer is in contact with the layer containing hydrogen, H₂O released from the third oxide semiconductor layer reaches the first oxide semiconductor layer in some cases.

Thus, it is preferable that the third oxide semiconductor layer be not in contact with the layer containing hydrogen.

The following are examples of the invention by which at least one of the first to the fourth objects can be achieved.

For example, a semiconductor device including a first conductive layer over a substrate, an insulating layer over the first conductive layer, a first oxide semiconductor layer over the insulating layer, a second oxide semiconductor layer over the insulating layer, a second conductive layer over the first oxide semiconductor layer, a third conductive layer over the first oxide semiconductor layer, an inorganic insulating layer over the second conductive layer and the third conductive layer, and a resin layer over the inorganic insulating layer is provided. In the semiconductor device, the first oxide semiconductor layer includes a region overlapping with the first conductive layer, the resin layer is not in contact with the first oxide semiconductor layer, and the resin layer includes a portion being in contact with the second oxide semiconductor layer in an inside of a hole of the inorganic insulating layer.

For example, a semiconductor device including a first conductive layer over a substrate, an insulating layer over the first conductive layer, a first oxide semiconductor layer over the insulating layer, a second oxide semiconductor layer over the insulating layer, a third oxide semiconductor layer over the insulating layer, a second conductive layer over the first oxide semiconductor layer, a third conductive layer over the first oxide semiconductor layer, an inorganic insulating layer over the second conductive layer and the third conductive layer, and a resin layer over the inorganic insulating layer is provided. In the semiconductor device, the first oxide semiconductor layer includes a region overlapping with the first conductive layer, the resin layer is not in contact with the first oxide semiconductor layer, the resin layer includes a portion being in contact with the second oxide semiconductor layer in an inside of a hole of the inorganic insulating layer, the resin layer is not in contact with the third oxide semiconductor layer, the substrate includes a first region, a second region, and a third region, the first oxide semiconductor layer includes a region overlapping with the first region, the second oxide semiconductor layer includes a region overlapping with the second region, the third oxide semiconductor layer includes a region overlapping with the third region, and the third region is located between the first region and the second region.

For example, a semiconductor device including a first conductive layer over a substrate, an insulating layer over the first conductive layer, a first layer over the insulating layer, a second layer over the insulating layer, a second conductive layer over the first layer, a third conductive layer over the first layer, an inorganic insulating layer over the second conductive layer and the third conductive layer, and a resin layer over the inorganic insulating layer is provided. In the semiconductor device, the first layer includes indium, gallium, zinc, and oxygen, the second layer includes indium, gallium, zinc, and oxygen, the first layer includes a region overlapping with the first conductive layer, the resin layer is not in contact with the first layer, and the resin layer includes a portion being in contact with the second layer in an inside of a hole of the inorganic insulating layer.

For example, a semiconductor device including a first conductive layer over a substrate, an insulating layer over the first conductive layer, a first layer over the insulating layer, a second layer over the insulating layer, a third layer over the insulating layer, a second conductive layer over the first layer, a third conductive layer over the first layer, an inorganic insulating layer over the second conductive layer and the third conductive layer, and a resin layer over the inorganic insulating layer is provided. In the semiconductor device, the first layer includes indium, gallium, zinc, and oxygen, the second layer includes indium, gallium, zinc, and oxygen, the third layer includes indium, gallium, zinc, and oxygen, the first layer includes a region overlapping with the first conductive layer, the resin layer is not in contact with the first layer, the resin layer includes a portion being in contact with the second layer in an inside of a hole of the inorganic insulating layer, the resin layer is not in contact with the third layer, the substrate includes a first region, a second region, and a third region, the first layer includes a region overlapping with the first region, the second layer includes a region overlapping with the second region, the third layer includes a region overlapping with the third region, and the third region is located between the first region and the second region.

By the contact of at least a part of the oxide semiconductor layer with at least a part of the resin layer, H₂O can be contained in the oxide semiconductor layer.

A novel semiconductor device can be provided.

An oxide semiconductor layer having a predetermined use (e.g., an electrode, a wiring, or a resistor) is formed. Thus, a space in which an active layer is not formed can be used effectively.

By the contact of at least a part of the oxide semiconductor layer with at least a part of the layer containing hydrogen, H can be contained in the oxide semiconductor layer.

### BRIEF DESCRIPTION OF THE DRAWINGS

FIG. 1 illustrates an example of a semiconductor device.

FIG. 2 illustrates an example of a semiconductor device.

FIG. 3 illustrates an example of a method for fabricating a semiconductor device.

FIGS. 4A and 4B illustrate an example of the method for fabricating a semiconductor device.

FIG. 5 illustrates an example of the method for fabricating a semiconductor device.

FIGS. 6A and 6B illustrate an example of the method for fabricating a semiconductor device.

FIG. 7 illustrates an example of the method for fabricating a semiconductor device.

FIGS. 8A and 8B illustrate an example of the method for fabricating a semiconductor device.

FIG. 9 illustrates an example of the method for fabricating a semiconductor device.

FIGS. 10A and 10B illustrate an example of the method for fabricating a semiconductor device.

FIGS. 11A and 11B illustrate an example of the method for fabricating a semiconductor device.

FIG. 12 illustrates an example of the method for fabricating a semiconductor device.

FIGS. 13A and 13B illustrate an example of the method for fabricating a semiconductor device.

FIG. 14 illustrates an example of a semiconductor device.

FIG. 15 illustrates an example of a semiconductor device.

FIG. 16 illustrates an example of a semiconductor device.

FIG. 17 illustrates an example of a semiconductor device.

FIG. 18 illustrates an example of a semiconductor device.

FIG. 19 illustrates an example of a semiconductor device.

FIG. 20 illustrates an example of a semiconductor device.

FIG. 21 illustrates an example of a semiconductor device.

FIG. 22 illustrates an example of a semiconductor device.

FIG. 23 illustrates an example of a semiconductor device.

FIG. 24 illustrates an example of a semiconductor device.

FIG. 25 illustrates an example of a semiconductor device.

FIG. 26 illustrates an example of a semiconductor device.

FIG. 27 illustrates an example of a semiconductor device.

FIG. 28 illustrates an example of a semiconductor device.

FIG. 29 illustrates an example of a semiconductor device.

FIG. 30 illustrates an example of a semiconductor device.

FIG. 31 illustrates an example of a semiconductor device.

FIG. 32 illustrates an example of a semiconductor device.

FIG. 33 illustrates an example of a semiconductor device.

FIG. 34 illustrates an example of a semiconductor device.

FIG. 35 illustrates an example of a semiconductor device.

FIG. 36 illustrates an example of a semiconductor device.

FIG. 37 illustrates an example of a semiconductor device.

FIG. 38 illustrates an example of a semiconductor device.

FIG. 39 illustrates an example of a semiconductor device.

FIG. 40 illustrates an example of a semiconductor device.

FIG. 41 illustrates an example of a semiconductor device.

FIG. 42 illustrates an example of a semiconductor device.

FIG. 43 illustrates an example of a semiconductor device.

FIG. 44 illustrates an example of a semiconductor device.

FIG. 45 illustrates an example of a semiconductor device.

FIG. 46 illustrates an example of a semiconductor device.

FIG. 47 illustrates an example of a semiconductor device.

FIG. 48 illustrates an example of a semiconductor device.

FIG. 49 illustrates an example of a semiconductor device.

FIG. 50 illustrates an example of a semiconductor device.

FIG. 51 illustrates an example of a semiconductor device.

FIG. 52 illustrates an example of a semiconductor device.

FIG. 53 illustrates an example of a semiconductor device.

FIG. 54 illustrates an example of a semiconductor device.

FIG. 55 illustrates an example of a semiconductor device.

FIG. 56 illustrates an example of a semiconductor device.

FIG. 57 illustrates an example of a semiconductor device.

FIG. 58 illustrates an example of a semiconductor device.

FIG. 59 illustrates an example of a semiconductor device.

FIG. 60 illustrates an example of a semiconductor device.

FIG. 61 illustrates an example of a semiconductor device.

FIG. 62 illustrates an example of a semiconductor device.

FIG. 63 illustrates an example of a semiconductor device.

FIG. 64 illustrates an example of a semiconductor device.

FIG. 65 illustrates an example of a semiconductor device.

FIG. 66 illustrates an example of a semiconductor device.

FIG. 67 illustrates an example of a semiconductor device.

FIG. 68 illustrates an example of a semiconductor device.

FIG. 69 illustrates an example of a semiconductor device.

FIG. 70 illustrates an example of a semiconductor device.

FIG. 71 illustrates an example of a semiconductor device.

FIG. 72 illustrates an example of a semiconductor device.

FIG. 73 illustrates an example of a semiconductor device.

FIG. 74 illustrates an example of a semiconductor device.

FIG. 75 illustrates an example of a semiconductor device.

FIG. 76 illustrates an example of a semiconductor device.

FIG. 77 illustrates an example of a semiconductor device.

FIG. 78 illustrates an example of a semiconductor device.

FIG. 79 illustrates an example of a semiconductor device.

FIG. 80 illustrates an example of a semiconductor device.

FIG. 81 illustrates an example of a semiconductor device.

FIG. 82 illustrates an example of a semiconductor device.

FIG. 83 illustrates an example of a semiconductor device.

FIG. 84 illustrates an example of a semiconductor device.

FIG. 85 illustrates an example of a semiconductor device.

FIG. 86 illustrates an example of a semiconductor device.

FIG. 87 illustrates an example of a semiconductor device.

FIG. 88 illustrates an example of a semiconductor device.

FIG. 89 illustrates an example of a semiconductor device.

FIG. 90 illustrates an example of a semiconductor device.

FIG. 91 illustrates an example of a semiconductor device.

FIG. 92 illustrates an example of a semiconductor device.

FIG. 93 illustrates an example of a semiconductor device.

FIG. 94 illustrates an example of a semiconductor device.

FIG. 95 illustrates an example of a semiconductor device.

FIG. 96 illustrates an example of a semiconductor device.

FIG. 97 illustrates an example of a semiconductor device.

FIG. 98 illustrates an example of a semiconductor device.

FIG. 99 illustrates an example of a semiconductor device.

FIG. 100 illustrates an example of a semiconductor device.

FIG. 101 illustrates an example of a semiconductor device.

FIG. 102 illustrates an example of a semiconductor device.

FIG. 103 illustrates an example of a semiconductor device.

FIG. 104 illustrates an example of a semiconductor device.

FIG. 105 illustrates an example of a semiconductor device.

FIG. 106 illustrates an example of a semiconductor device.

FIG. 107 illustrates an example of a semiconductor device.

FIG. 108 illustrates an example of a semiconductor device.

FIG. 109 illustrates an example of a semiconductor device.

FIG. 110 illustrates an example of a semiconductor device.

FIG. 111 illustrates an example of a semiconductor device.

FIG. 112 illustrates an example of a semiconductor device.

FIG. 113 illustrates an example of a semiconductor device.

FIG. 114 illustrates an example of a semiconductor device.

FIG. 115 illustrates an example of a semiconductor device.

FIG. 116 illustrates an example of a semiconductor device.

FIG. 117 illustrates an example of a semiconductor device.

FIG. 118 illustrates an example of a semiconductor device.

FIG. 119 illustrates an example of a semiconductor device.

FIG. 120 illustrates an example of a semiconductor device.

FIG. 121 illustrates an example of a semiconductor device.

FIG. 122 illustrates an example of a semiconductor device.

FIG. 123 illustrates an example of a semiconductor device.

FIG. 124 illustrates an example of a semiconductor device.

FIG. 125 illustrates an example of a semiconductor device.

FIGS. 126A to 126C illustrate examples of a semiconductor device.

FIG. 127 illustrates an example of a semiconductor device.

FIG. 128 illustrates an example of a semiconductor device.

FIG. 129 illustrates an example of a semiconductor device.

### DETAILED DESCRIPTION OF THE INVENTION

Embodiments are described in detail with reference to the drawings.

It is easily understood by those skilled in the art that modes and details thereof can be modified in various ways without departing from the spirit of the invention.

Therefore, the scope of the invention should not be interpreted as being limited to what is described in the embodiments described below.

In the structures to be described below, the same portions or portions having similar functions are denoted by the same reference numerals or the same hatching patterns in different drawings, and explanation thereof will not be repeated.

Part or the whole of the following embodiments can be combined as appropriate.

### Embodiment 1

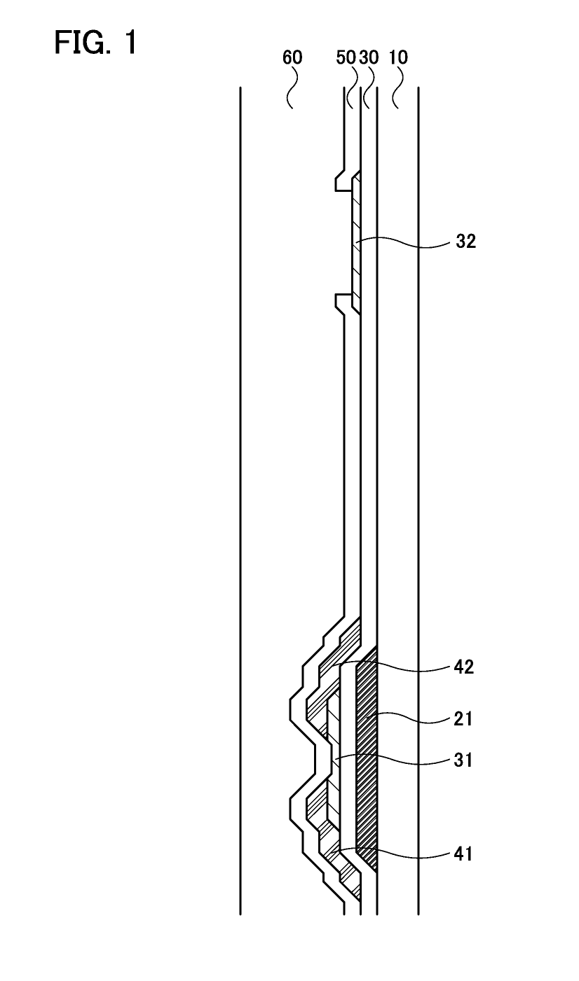

FIG. 1 illustrates an example of a semiconductor device including an oxide semiconductor layer 31 and an oxide semiconductor layer 32.

A conductive layer 21 is provided over a substrate 10.

At least a part of the conductive layer 21 can function as a gate electrode of a transistor.

An insulating layer may be provided between the substrate 10 and the conductive layer 21.

An insulating layer 30 is provided over the conductive layer 21.

At least a part of the insulating layer 30 can function as a gate insulating film of the transistor.

The oxide semiconductor layer 31 is provided over the insulating layer 30.

At least a part of the oxide semiconductor layer 31 can function as an active layer of the transistor.

A conductive layer 41 is provided over the oxide semiconductor layer 31.

A conductive layer 42 is provided over the oxide semiconductor layer 31.

At least a part of the conductive layer 41 can function as one of a source electrode and a drain electrode of the transistor.

At least a part of the conductive layer 42 can function as the other of the source electrode and the drain electrode of the transistor.

The oxide semiconductor layer 32 is provided over the insulating layer 30.

At least a part of the oxide semiconductor layer 32 can function as, for example, a wiring, an electrode, a resistor, an active layer of the transistor, or the like.

Note that the function of the oxide semiconductor layer 32 is not limited to the wiring, the electrode, the resistor, the active layer of the transistor, or the like.

An inorganic insulating layer 50 is provided at least over the oxide semiconductor layer 31, the conductive layer 41, and the conductive layer 42.

FIG. 1 illustrates the case where the inorganic insulating layer 50 exists also over the oxide semiconductor layer 32.

The inorganic insulating layer 50 has a hole.

A resin layer 60 is provided over the inorganic insulating layer 50.

The resin layer 60 is not in contact with the oxide semiconductor layer 31.

The resin layer 60 includes a portion being in contact with the oxide semiconductor layer 32 in the inside of the hole.

The resin layer 60 is not in contact with the oxide semiconductor layer 31, whereby the content of H₂O in the oxide semiconductor layer 31 can be lower than the content of H₂O in the oxide semiconductor layer 32.

Since the oxide semiconductor layer 31 can function as the active layer of the transistor, the threshold voltage of the transistor can be prevented from shifting in the negative direction.

The resin layer 60 includes the portion being in contact with the oxide semiconductor layer 32; thus, the content of H₂O in the oxide semiconductor layer 32 can be higher than the content of H₂O in the oxide semiconductor layer 31.

The content of H₂O in the oxide semiconductor layer 32 is made higher than that in the oxide semiconductor layer 31; thus, the property of the oxide semiconductor layer 32 can be differentiated from the property of the oxide semiconductor layer 31.

For example, the oxide semiconductor layer 32 can have lower resistivity than the oxide semiconductor layer 31; thus, the oxide semiconductor layer 32 can be used as at least a part of the wiring, the electrode, or the resistor.

For example, in the case where the oxide semiconductor layer 32 is used as the active layer of the transistor, the transistor including the oxide semiconductor layer 32 and the transistor including the oxide semiconductor layer 31 can have different threshold voltage values.

In the case where the oxide semiconductor layer 32 is not the active layer of the transistor, the oxide semiconductor layer 32 does not overlap with a region capable of functioning as a gate electrode.

The region capable of functioning as the gate electrode is a region overlapping with a channel formation region included in the active layer of the transistor.

That is, in the case where the oxide semiconductor layer 32 is not the active layer of the transistor, the oxide semiconductor layer 32 does not include a channel formation region.

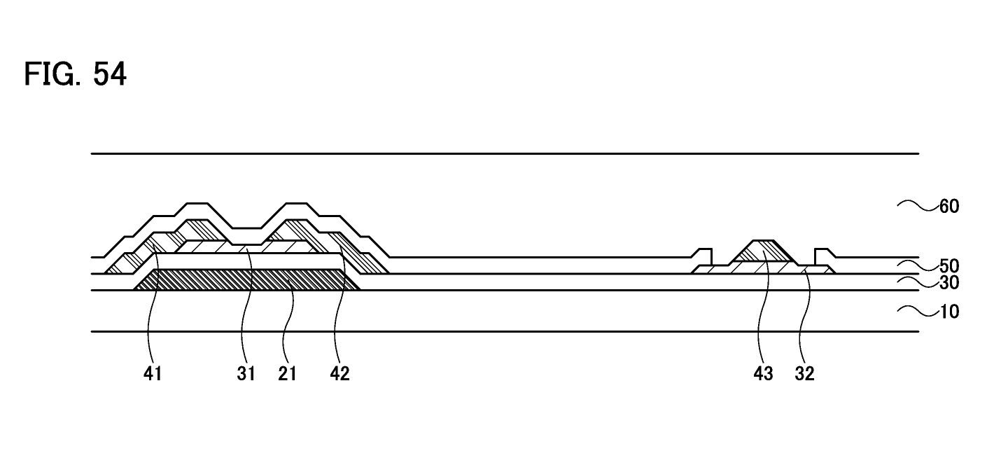

FIGS. 54 to 58 illustrate examples of the oxide semiconductor layer 32.

FIG. 54 illustrates an example of a drawing which is different from FIG. 1 in that a conductive layer 43 is provided.

At least a part of the oxide semiconductor layer 32 can function as a wiring.

At least a part of the conductive layer 43 can function as a wiring.

One of the oxide semiconductor layer 32 and the conductive layer 43 can function as an auxiliary wiring.

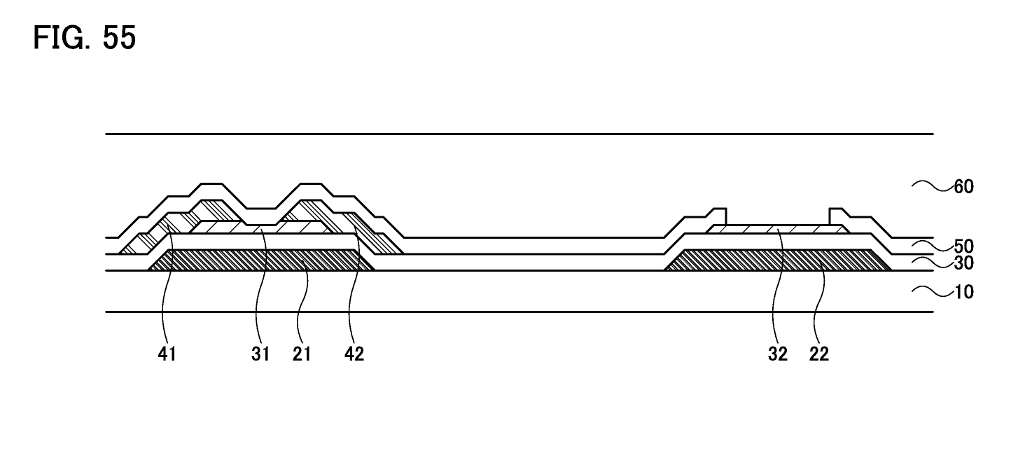

FIG. 55 illustrates an example of a drawing which is different from FIG. 1 in that a conductive layer 22 is provided.

At least a part of the oxide semiconductor layer 32 can function as one electrode of a capacitor.

At least a part of the conductive layer 22 can function as the other electrode of the capacitor.

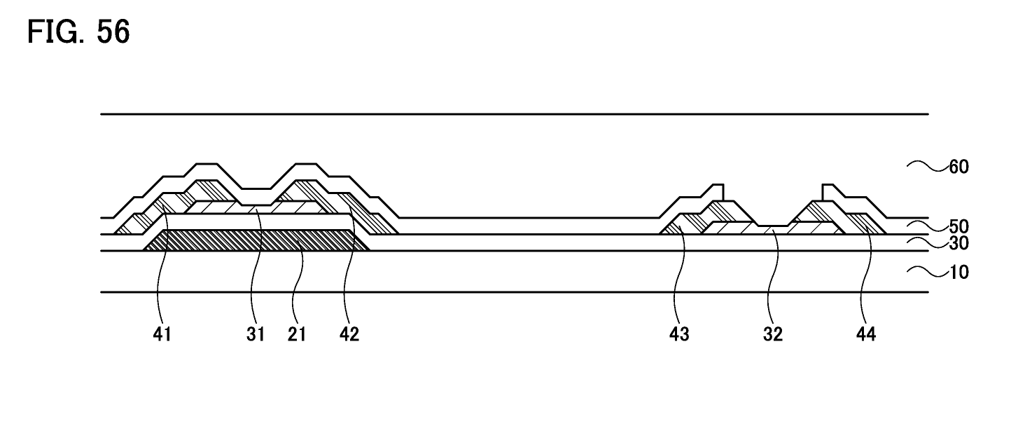

FIG. 56 illustrates an example of a drawing which is different from FIG. 1 in that the conductive layer 43 and a conductive layer 44 are provided.

At least a part of the oxide semiconductor layer 32 can function as a resistive element of a resistor.

At least a part of the conductive layer 43 can function as one terminal of the resistor.

At least a part of the conductive layer 44 can function as the other terminal of the resistor.

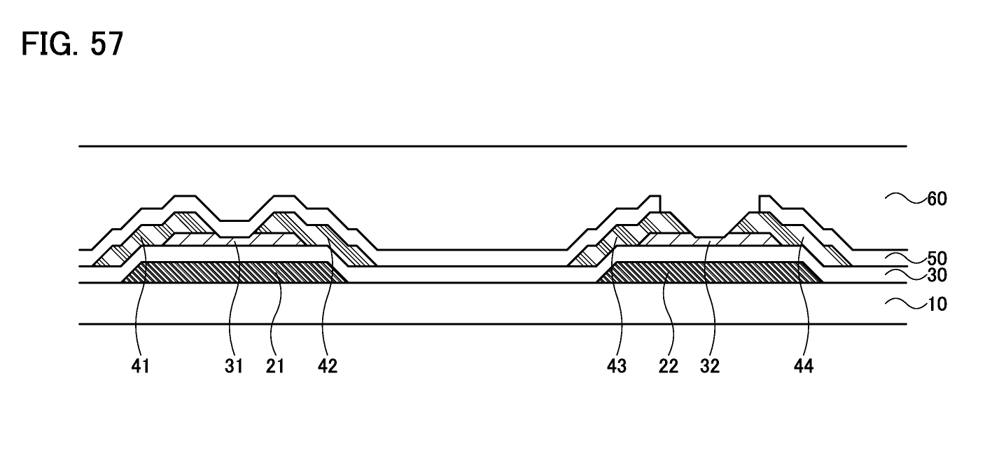

FIG. 57 illustrates an example of a drawing which is different from FIG. 1 in that the conductive layer 22, the conductive layer 43, and the conductive layer 44 are provided.

At least a part of the oxide semiconductor layer 32 can function as an active layer of a transistor.

At least a part of the conductive layer 22 can function as a gate electrode of the transistor.

At least a part of the conductive layer 43 can function as one of a source electrode and a drain electrode of the transistor.

At least a part of the conductive layer 44 can function as the other of the source electrode and the drain electrode of the transistor.

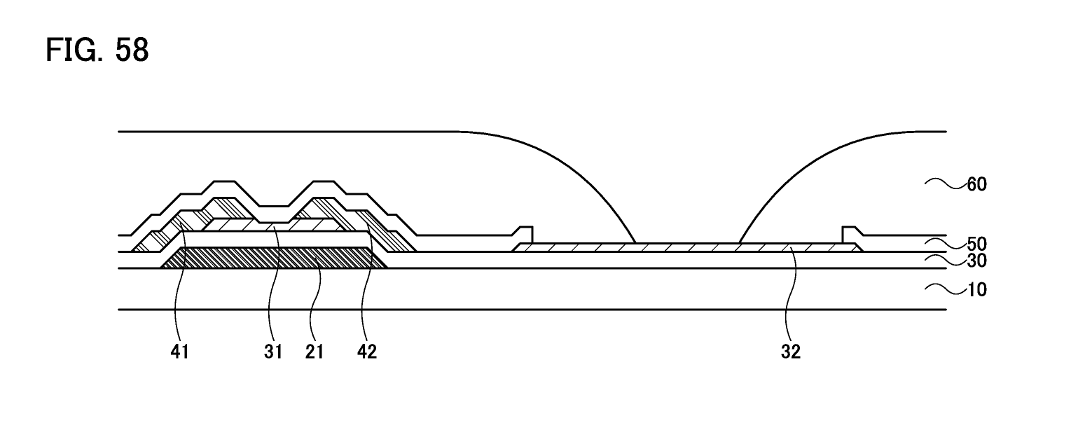

FIG. 58 illustrates an example of a drawing which is different from FIG. 1 in that a hole is provided in the resin layer 60.

The resin layer 60 includes a portion being in contact with the oxide semiconductor layer 32 in the inside of the hole of the inorganic insulating layer 50.

The oxide semiconductor layer 32 includes an exposed region in the inside of the hole of the resin layer 60.

A predetermined layer can be provided over the exposed region.

Thus, at least a part of the oxide semiconductor layer 32 can function as one electrode of an element.

Examples of the element include a display element, a memory element, and a capacitor, but the element is not limited to these examples.

For example, in the case where the element is a display element, at least the part of the oxide semiconductor layer 32 can function as a pixel electrode.

The function of the oxide semiconductor layer 32 is not limited to one electrode of the element.

The oxide semiconductor layer 32 may be a wiring, an electrode, a resistive element, an active layer, or the like.

Note that the conductive layer 21 and the conductive layer 22 can be formed in the same step.

The conductive layer 43, the conductive layer 41, and the conductive layer 42 can be formed in the same step.

The conductive layer 44, the conductive layer 41, and the conductive layer 42 can be formed in the same step.

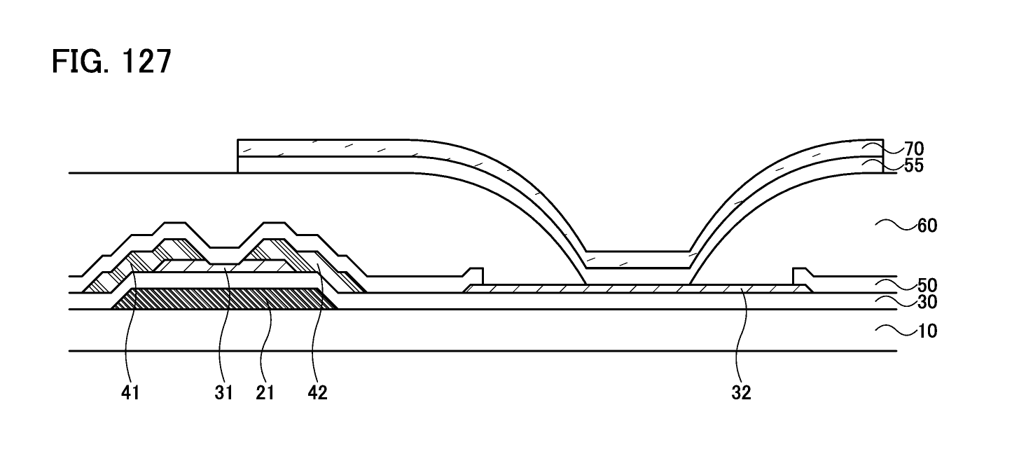

For example, FIG. 127 illustrates an example of a drawing which is different from FIG. 58 in that a functional layer 55 is provided over the resin layer 60 and a conductive layer 70 is provided over the functional layer 55.

In the case of a liquid crystal element, for example, the functional layer 55 is a liquid crystal layer.

In the case of an EL element, for example, the functional layer 55 is a layer containing an organic compound.

In the case of a capacitor, for example, the functional layer 55 is an insulating layer (a dielectric layer).

In FIG. 127, the oxide semiconductor layer 32 can function as one electrode of the element.

In FIG. 127, the conductive layer 70 can function as the other electrode of the element.

Note that although the functional layer 55 is locally provided in the example illustrated in FIG. 127, the functional layer 55 may be provided over an entire surface of the substrate.

Note that although the conductive layer 70 is locally provided in the example illustrated in FIG. 127, the conductive layer 70 may be provided over an entire surface of the substrate.

The functional layer 55 preferably contains H₂O or H, in which case the resistance of the oxide semiconductor layer 32 can be reduced.

The amount of H₂O or H in the functional layer 55 is preferably larger than the amount of H₂O or H in the inorganic insulating layer 50.

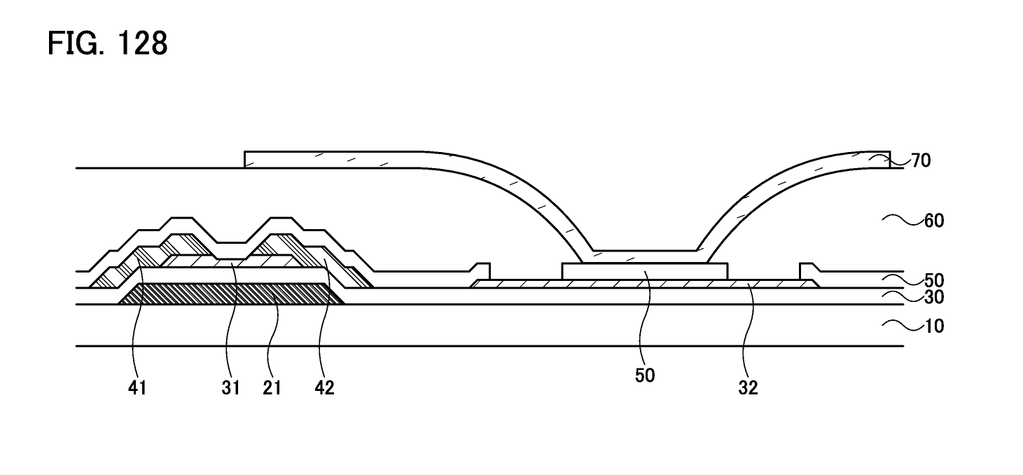

FIG. 128 illustrates an example of a drawing which is different from FIG. 58 in that the inorganic insulating layer 50 is left in a bottom portion of the hole of the resin layer 60 and the conductive layer 70 is provided over the inorganic insulating layer 50 and the resin layer 60.

In FIG. 128, in the inside of the hole of the inorganic insulating layer 50, the resin layer 60 is in contact with the oxide semiconductor layer 32.

In FIG. 128, the oxide semiconductor layer 32 can function as one electrode of a capacitor.

In FIG. 128, the conductive layer 70 can function as the other electrode of the capacitor.

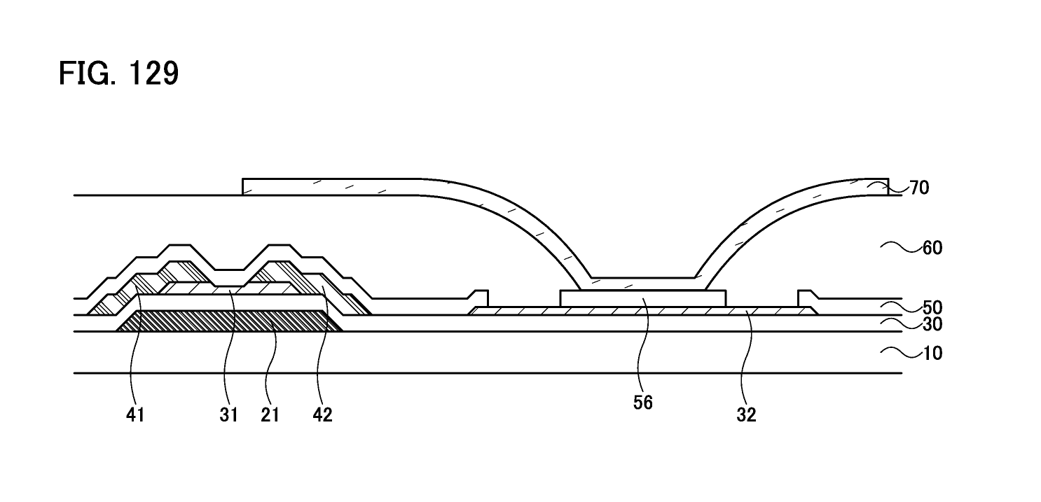

FIG. 129 illustrates an example of a drawing which is different from FIG. 128 in that, instead of the inorganic insulating layer 50 left in the bottom portion of the hole of the resin layer 60, an insulating layer 56 is provided. That is, in the example, the insulating layer 56 is provided in the inside of the hole of the inorganic insulating layer 50, the resin layer 60 is provided over the insulating layer 56 and the inorganic insulating layer 50, and the conductive layer 70 is provided over the resin layer 60 and the insulating layer 56.

The insulating layer 56 can function as a dielectric layer of the capacitor.

The insulating layer 56 preferably contains H₂O or H, in which case the resistance of the oxide semiconductor layer 32 can be reduced.

The amount of H₂O or H in the insulating layer 56 is preferably larger than the amount of H₂O or H in the inorganic insulating layer 50.

Note that in FIGS. 127 to 129, when the conductive layer 70 has a light-transmitting property, a capacitor having a light-transmitting property can be fabricated.

Further, in FIGS. 127 to 129, the dielectric layer of the capacitor can be thinned; thus, a capacitance of the capacitor can be increased.

For example, the dielectric layer (the functional layer 55, the inorganic insulating layer 50, the insulating layer 56, or the like) of the capacitor can be thinner than the resin layer 60.

For example, the dielectric layer (the functional layer 55, the insulating layer 56, or the like) of the capacitor can be thinner than the inorganic insulating layer 50.

At least part of the structure described in this embodiment can be combined with at least part of a structure described in any of the other embodiments.

### Embodiment 2

For example, H₂O is preferably prevented from entering the oxide semiconductor layer 31.

In contrast, H₂O is intentionally contained in the oxide semiconductor layer 32.

Incidentally, H₂O moves along the interface between the insulating layer 30 and the inorganic insulating layer 50 in some cases.

Hence, H₂O that is released from the oxide semiconductor layer 32 moves along the interface between the insulating layer 30 and the inorganic insulating layer 50 and enters the oxide semiconductor layer 31 in some cases.

Although the amount of H₂O that moves along the interface between the insulating layer 30 and the inorganic insulating layer 50 is very small, such H₂O affects the electrical characteristics of the transistor including the oxide semiconductor layer 31 in some cases.

Further, in the case where the insulating layer 30 does not have enough ability to block H₂O, H₂O might move in the insulating layer 30 (particularly in the vicinity of the interface between the insulating layer 30 and the inorganic insulating layer 50).

Hence, H₂O that is released from the oxide semiconductor layer 32 moves in the insulating layer 30 and enters the oxide semiconductor layer 31 in some cases.

Although the amount of H₂O that moves in the insulating layer 30 is very small, such H₂O affects the electrical characteristics of the transistor including the oxide semiconductor layer 31 in some cases.

Further, in the case where the inorganic insulating layer 50 does not have enough ability to block H₂O, H₂O might move in the inorganic insulating layer 50 (particularly in the vicinity of the interface between the insulating layer 30 and the inorganic insulating layer 50).

Hence, H₂O that is released from the oxide semiconductor layer 32 moves in the inorganic insulating layer 50 and enters the oxide semiconductor layer 31 in some cases.

Although the amount of H₂O that moves in the inorganic insulating layer 50 is very small, such H₂O affects the electrical characteristics of the transistor including the oxide semiconductor layer 31 in some cases.

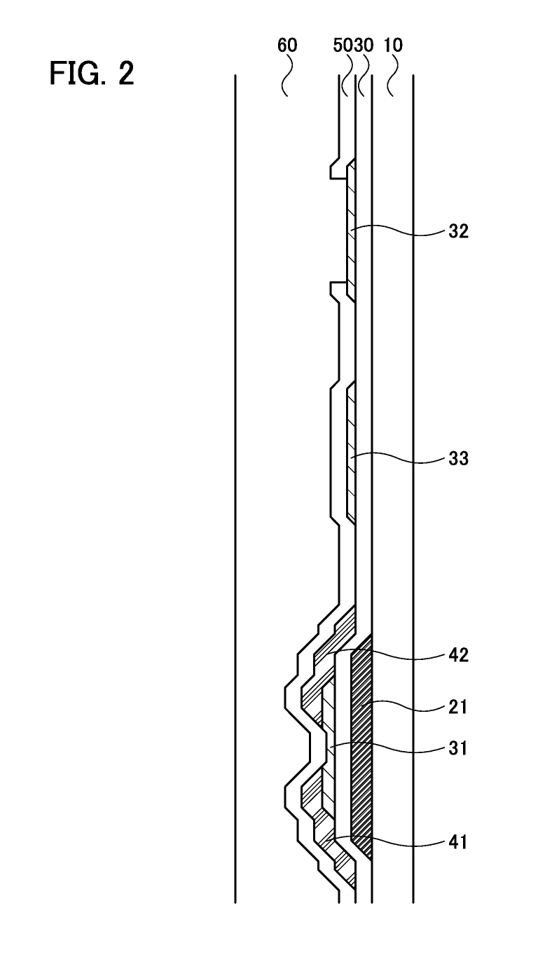

For these reasons, it is preferable to use a structure including an oxide semiconductor layer 33 between the oxide semiconductor layer 31 and the oxide semiconductor layer 32 as illustrated in FIG. 2.

The positional relation among the oxide semiconductor layer 31, the oxide semiconductor layer 32, and the oxide semiconductor layer 33 in FIG. 2 is described in detail.

The case where the substrate 10 includes a first region, a second region, and a third region is described.

The third region is located between the first region and the second region.

The oxide semiconductor layer 31 includes a region overlapping with the first region.

The oxide semiconductor layer 32 includes a region overlapping with the second region.

The oxide semiconductor layer 33 includes a region overlapping with the third region.

The case where the resin layer 60 includes a first region, a second region, and a third region is described.

The third region is located between the first region and the second region.

The oxide semiconductor layer 31 includes a region overlapping with the first region.

The oxide semiconductor layer 32 includes a region overlapping with the second region.

The oxide semiconductor layer 33 includes a region overlapping with the third region.

H₂O that moves along the interface between the insulating layer 30 and the inorganic insulating layer 50, in the insulating layer 30, or in the inorganic insulating layer 50 is absorbed in the oxide semiconductor layer 33. Thus, the amount of H₂O reaching the oxide semiconductor layer 31 can be reduced.

In order to prevent H₂O from moving from the oxide semiconductor layer 33 to the oxide semiconductor layer 31, the oxide semiconductor layer 33 is preferably not in contact with the resin layer 60.

The oxide semiconductor layer 33 may be electrically connected to a wiring or an electrode.

The oxide semiconductor layer 33 may be electrically insulated from a wiring or an electrode (may be in a floating state or an electrically isolated state).

In the case where the oxide semiconductor layer 33 is not an active layer of a transistor, the oxide semiconductor layer 33 does not overlap with a region capable of functioning as a gate electrode.

The region capable of functioning as a gate electrode is a region overlapping with a channel formation region of an active layer of a transistor.

That is, in the case where the oxide semiconductor layer 33 is not an active layer of a transistor, the oxide semiconductor layer 33 does not include a channel formation region.

The oxide semiconductor layer 33 may be an active layer of a transistor.

For example, the oxide semiconductor layer 33 can be used as an active layer of a transistor (a transistor (A)) which hardly affects a circuit operation in the case where the threshold voltage of the transistor shifts in the negative direction.

Further, the oxide semiconductor layer 32 can be used as an active layer of a transistor (a transistor (B)) which largely affects a circuit operation in the case where the threshold voltage of the transistor shifts in the negative direction.

For example, the transistor (A) can be used as a transistor in a digital circuit, and the transistor (B) can be used as a transistor in an analog circuit.

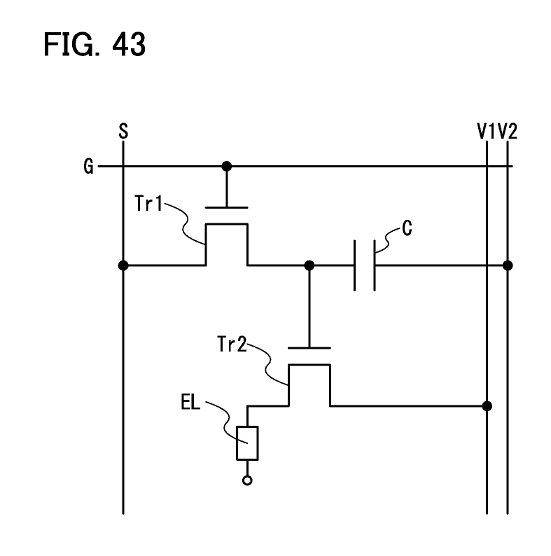

In the case of a configuration shown in FIG. 43, for example, the transistor (A) can be used as a transistor Tr1, and the transistor (B) can be used as a transistor Tr2.

At least part of the structure described in this embodiment can be combined with at least part of a structure described in any of the other embodiments.

### Embodiment 3

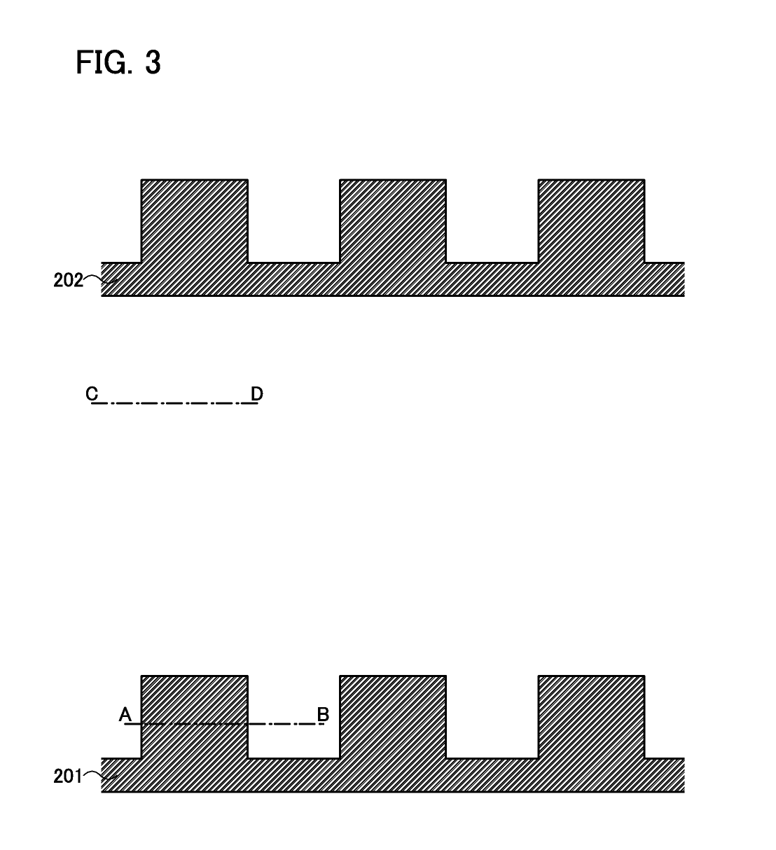

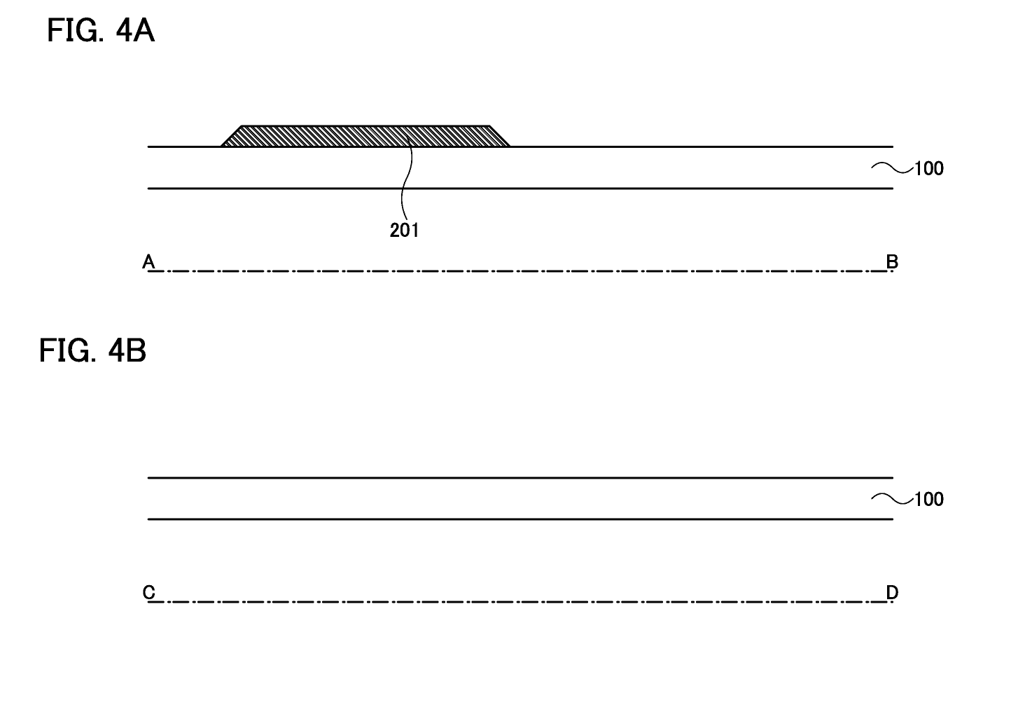

An example of a method for fabricating a semiconductor device is described (FIG. 3, FIGS. 4A and 4B, FIG. 5, FIGS. 6A and 6B, FIG. 7, FIGS. 8A and 8B, FIG. 9, FIGS. 10A and 10B, FIGS. 11A and 11B, FIG. 12, and FIGS. 13A and 13B).

A conductive layer 201 and a conductive layer 202 are formed over a substrate 100 (FIG. 3 and FIGS. 4A and 4B).

FIG. 4A illustrates an example of a cross-sectional view taken along the line A-B in FIG. 3.

FIG. 4B illustrates an example of a cross-sectional view taken along the line C-D in FIG. 3.

At least a part of the conductive layer 201 can function as a gate electrode.

That is, the conductive layer 201 includes a plurality of regions each capable of functioning as a gate electrode.

Further, at least a part of the conductive layer 201 can function as a wiring which electrically connects the regions each capable of functioning as a gate electrode.

At least a part of the conductive layer 202 can function as a gate electrode.

That is, the conductive layer 202 includes a plurality of regions each capable of functioning as a gate electrode.

Further, at least a part of the conductive layer 202 can function as a wiring which electrically connects the regions each capable of functioning as a gate electrode.

An insulating layer may be provided between the substrate 100 and the conductive layer 201.

An insulating layer may be provided between the substrate 100 and the conductive layer 202.

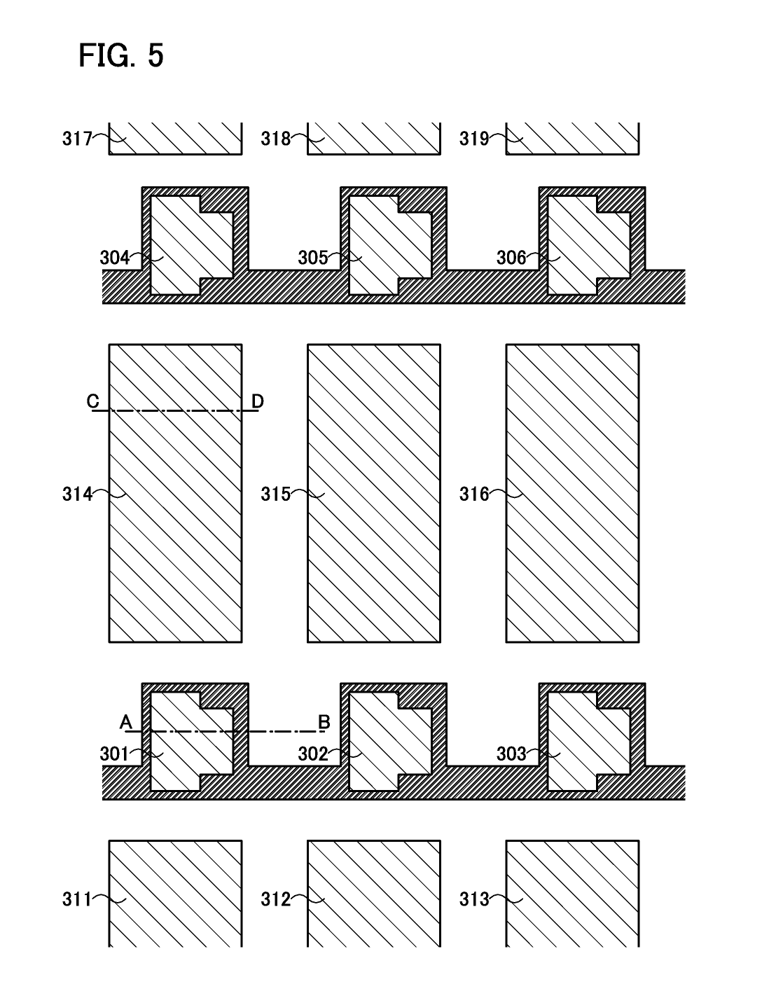

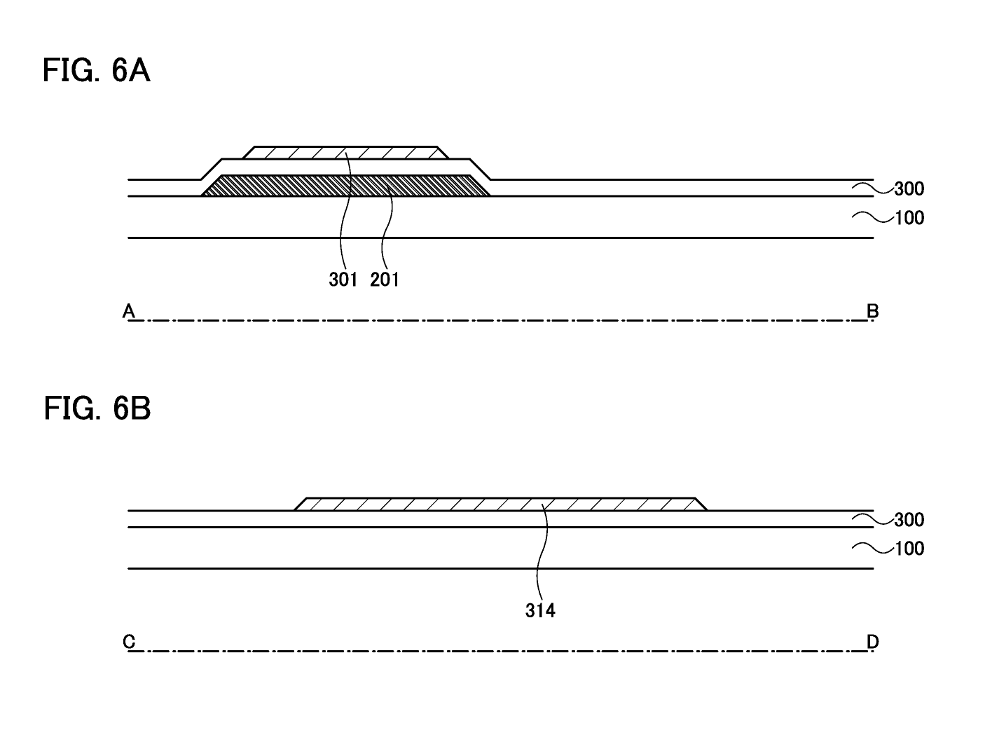

Next, an insulating layer 300 is formed over the conductive layer 201 and the conductive layer 202, and an oxide semiconductor layer 301, an oxide semiconductor layer 302, an oxide semiconductor layer 303, an oxide semiconductor layer 304, an oxide semiconductor layer 305, an oxide semiconductor layer 306, an oxide semiconductor layer 311, an oxide semiconductor layer 312, an oxide semiconductor layer 313, an oxide semiconductor layer 314, an oxide semiconductor layer 315, an oxide semiconductor layer 316, an oxide semiconductor layer 317, an oxide semiconductor layer 318, and an oxide semiconductor layer 319 are formed over the insulating layer 300 (FIG. 5 and FIGS. 6A and 6B).

FIG. 6A illustrates an example of a cross-sectional view taken along the line A-B in FIG. 5.

FIG. 6B illustrates an example of a cross-sectional view taken along the line C-D in FIG. 5.

The oxide semiconductor layers 301 to 306 each include a region having a function, which can serve as an active layer.

The oxide semiconductor layers 301 to 306 each include a region overlapping with the region capable of functioning as a gate electrode.

The oxide semiconductor layers 311 to 319 each include a region capable of functioning as at least a part of a wiring.

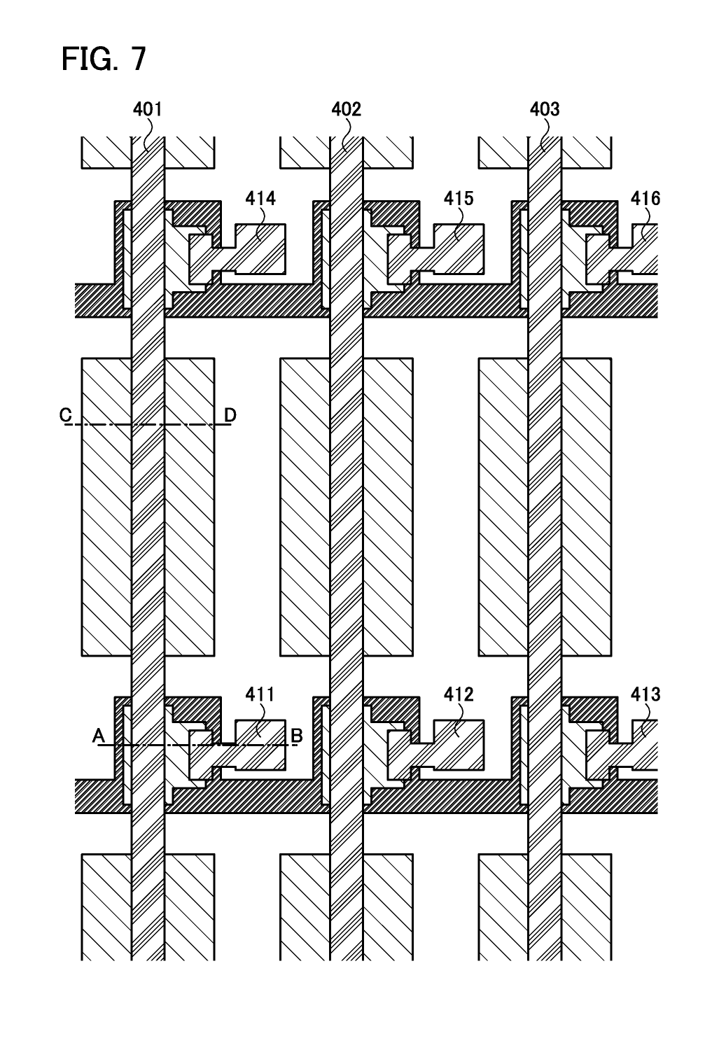

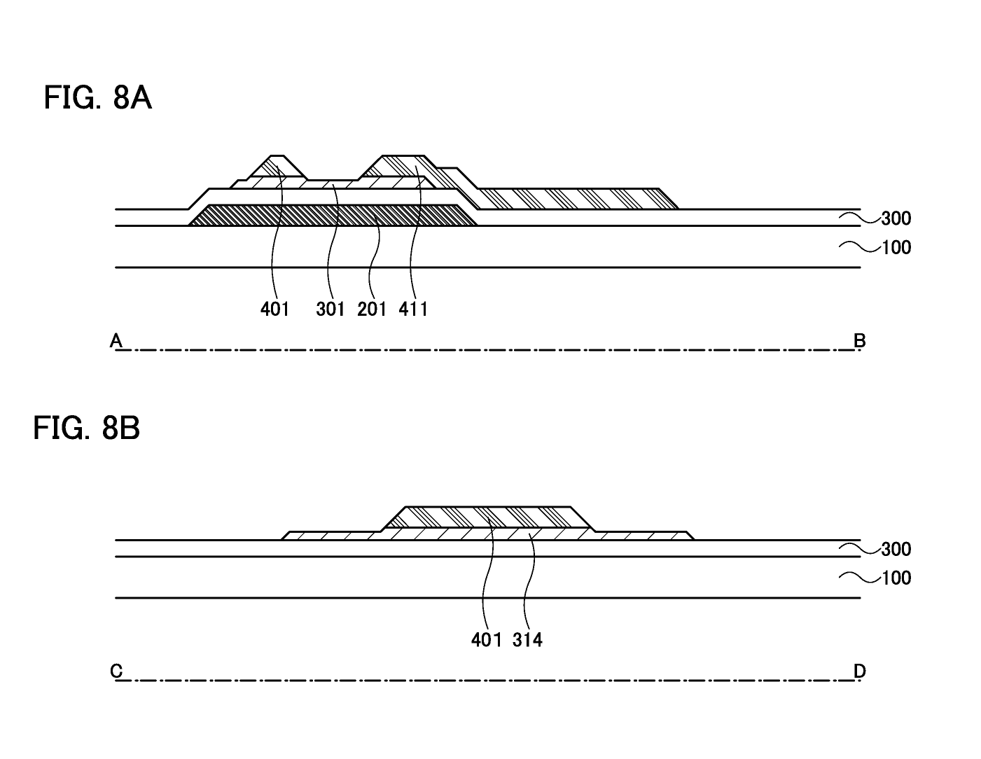

Next, a conductive layer 401, a conductive layer 402, a conductive layer 403, a conductive layer 411, a conductive layer 412, a conductive layer 413, a conductive layer 414, a conductive layer 415, and a conductive layer 416 are formed (FIG. 7 and FIGS. 8A and 8B).

FIG. 8A illustrates an example of a cross-sectional view taken along the line A-B in FIG. 7.

FIG. 8B illustrates an example of a cross-sectional view taken along the line C-D in FIG. 7.

The conductive layers 401 to 403 each include a region capable of functioning as at least a part of a wiring.

The conductive layers 401 to 403 each include a region capable of functioning as one of a source electrode and a drain electrode of a transistor.

The conductive layers 411 to 416 each include a region capable of functioning as at least a part of a wiring.

The conductive layers 411 to 416 each include a region capable of functioning as the other of the source electrode and the drain electrode of the transistor.

The positional relation between the conductive layer and the oxide semiconductor layer is described with reference to FIGS. 8A and 8B, for example. The conductive layer 401 includes a region being in contact with the oxide semiconductor layer 314.

The oxide semiconductor layer 314 has resistivity such that current can flow, though the resistivity of the oxide semiconductor layer 314 is higher than the resistivity of the conductive layer 401. Hence, the oxide semiconductor layer 314 can function as at least a part of a wiring.

Note that the oxide semiconductor layers 311 to 313 and the oxide semiconductor layers 315 to 319 each have a function similar to that of the oxide semiconductor layer 314.

That is, each of the oxide semiconductor layers 311 to 319 can function as an auxiliary wiring.

Note that in the case where an object is to form an auxiliary wiring, a semiconductor layer except the oxide semiconductor layer may be used instead of the oxide semiconductor layer.

A layer containing silicon and the like are given as examples of the semiconductor layer except the oxide semiconductor layer, but the semiconductor layer that is not the oxide semiconductor layer is not limited to this.

A silicon layer, a silicon germanium layer, a silicon carbide layer, and the like are given as examples of the layer containing silicon, but the layer containing silicon is not limited to these examples.

The shape of the semiconductor layer capable of functioning as an auxiliary wiring preferably has a long length direction.

A rectangular shape, an oval shape, a polygonal shape, and the like are given as examples of the shape having a long length direction, but the shape having a long length direction is not limited to these examples.

Here, for example, the long length direction of the semiconductor layer is defined as a first direction.

Further, for example, a direction in which current flows in a wiring electrically connected to the semiconductor layer is defined as a second direction.

In the case where the first direction and the second direction are parallel to each other, an angle between the first direction and the second direction is 0°.

In the case where the first direction and the second direction are perpendicular to each other, an angle between the first direction and the second direction is 90°.

It is preferable that the first direction (the long length direction) and the second direction (the direction in which current flows) be roughly parallel to each other.

When the first direction and the second direction are roughly parallel to each other, the area of contact between the auxiliary wiring and the wiring can be increased.

The phrase “the first direction and the second direction are roughly parallel to each other” indicates that an angle between the first direction and the second direction is greater than or equal to 0° and less than 35°.

Note that the angle between the first direction and the second direction may be greater than or equal to 35° and less than or equal to 90°.

The semiconductor layer capable of functioning as an auxiliary wiring is located between one of two active layers and the other of the two active layers, whereby the resistance of a wiring that electrically connects one of the two active layers to the other of the two active layers can be reduced.

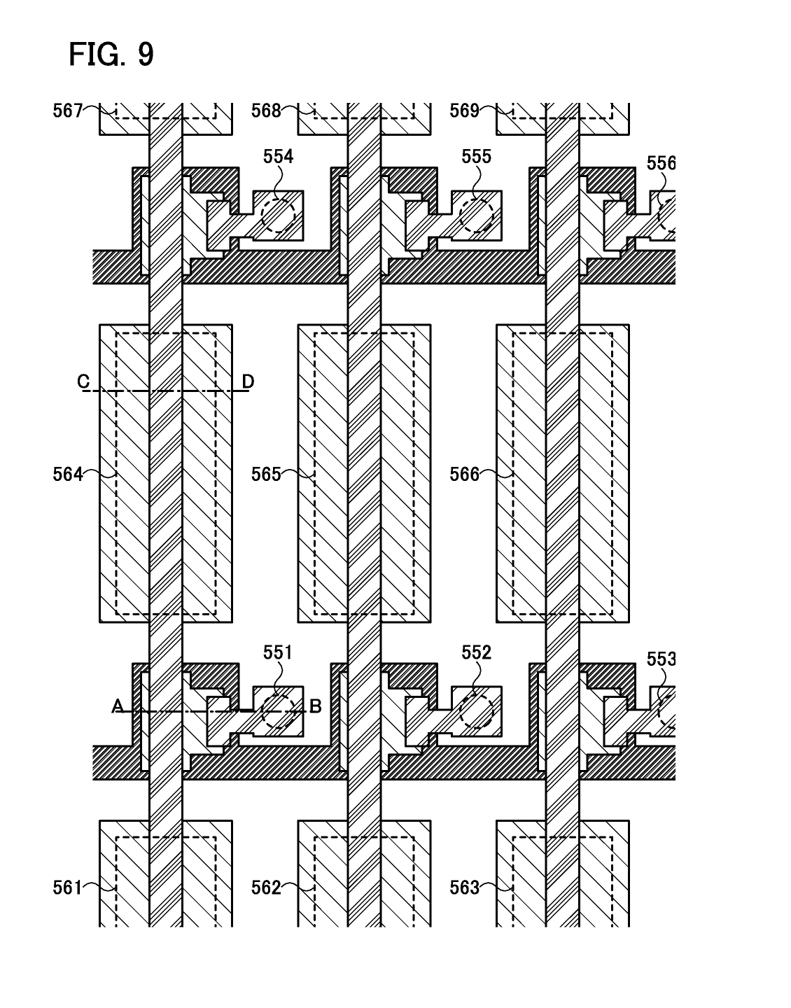

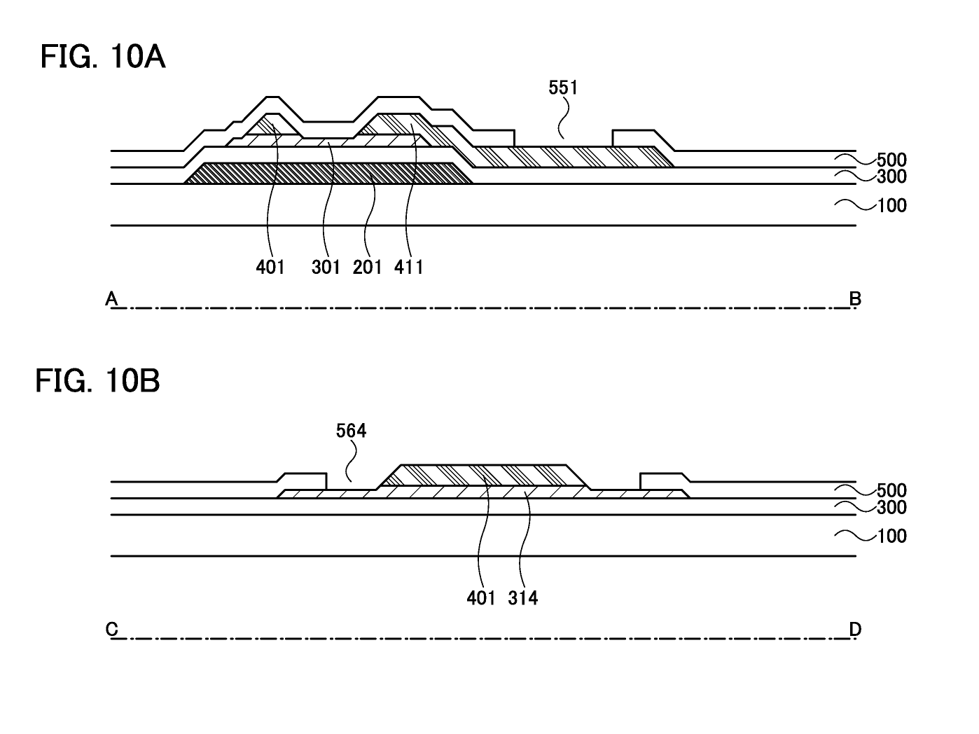

Next, an inorganic insulating layer 500 is formed over a plurality of transistors, and a hole 561, a hole 562, a hole 563, a hole 564, a hole 565, a hole 566, a hole 567, a hole 568, a hole 569, a contact hole 551, a contact hole 552, a contact hole 553, a contact hole 554, a contact hole 555, and a contact hole 556 are formed in the inorganic insulating layer 500 (FIG. 9 and FIGS. 10A and 10B).

FIG. 10A illustrates an example of a cross-sectional view taken along the line A-B in FIG. 9.

FIG. 10B illustrates an example of a cross-sectional view taken along the line C-D in FIG. 9.

In a state shown in FIGS. 10A and 10B, a substance containing H may be added to the oxide semiconductor layers 311 to 319 by ion doping or ion implantation.

Examples of the substance containing H include H₂, H₂O, PH₃, and B₂H₆, but the substance containing H is not limited to these examples.

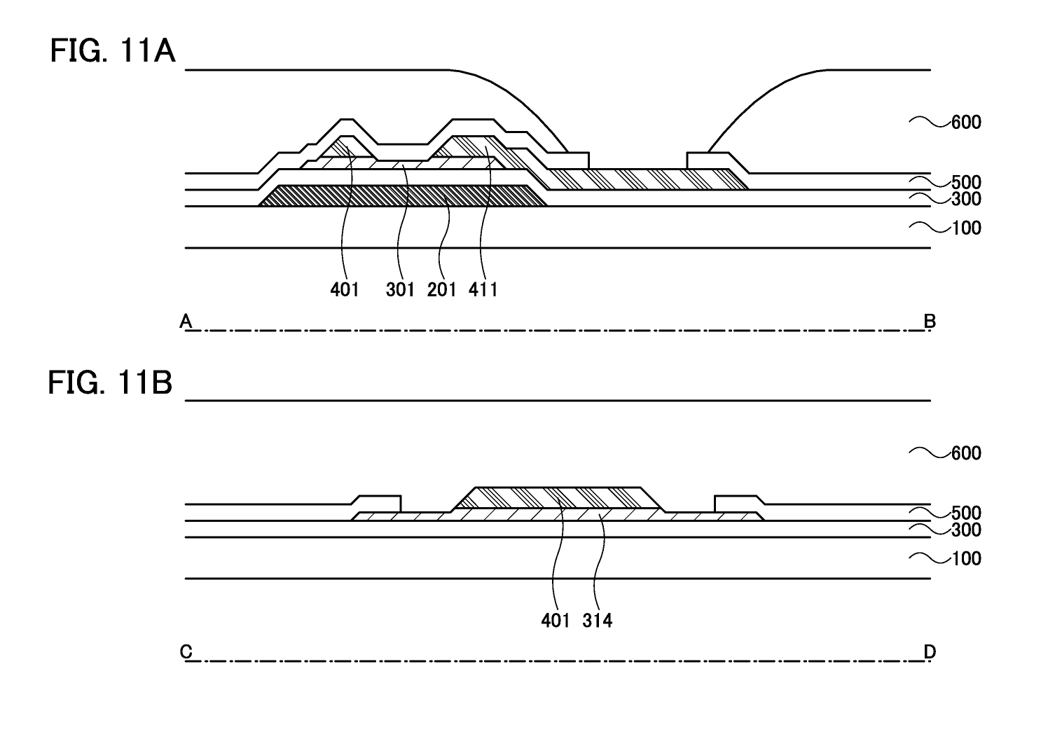

Next, a resin layer 600 is formed over the inorganic insulating layer 500, and a plurality of contact holes is formed in the resin layer 600 (FIG. 9 and FIGS. 11A and 11B).

FIG. 11A illustrates an example of a cross-sectional view taken along the line A-B in FIG. 9.

FIG. 11B illustrates an example of a cross-sectional view taken along the line C-D in FIG. 9.

The hole may be referred to as an opening or an opening portion.

The contact hole may be referred to as a hole, an opening, or an opening portion.

Although the inorganic insulating layer 500 is formed over an entire surface of the substrate in FIG. 9, FIGS. 10A and 10B, and FIGS. 11A and 11B, it is also possible to use a structure in which a plurality of island-like inorganic insulating layers is formed so that the plurality of island-like inorganic insulating layers each cover one of the plurality of transistors.

However, since the adhesion between the resin layer and the conductive layer is poor, even when the resin layer is formed on the conductive layer, the resin layer is separated in some cases.

In the case where the conductive layer is a film containing metal, the adhesion between the resin layer and the conductive layer is especially poor.

For that reason, the area of contact between the resin layer and the conductive layer is preferably small.

Hence, in consideration of the reduction in the area of contact between the resin layer and the conductive layer, the structure shown in FIG. 9, FIGS. 10A and 10B, and FIGS. 11A and 11B is preferable to the structure in which the plurality of island-like inorganic insulating layers is formed.

The positional relation between the resin layer and the oxide semiconductor layer is described with reference to FIGS. 10A and 10B and FIGS. 11A and 11B, for example. The resin layer 600 includes a portion being in contact with the oxide semiconductor layer 314 in the inside of the hole 564.

In contrast, the oxide semiconductor layer 301 is not in contact with the resin layer 600 because the transistor is covered with the inorganic insulating layer 500.

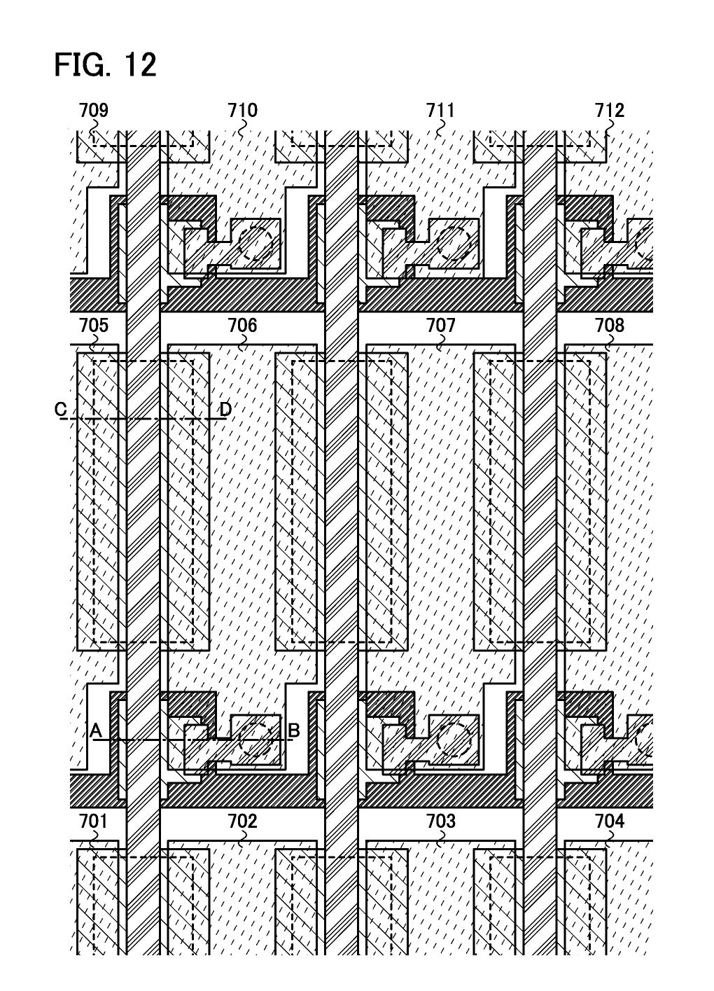

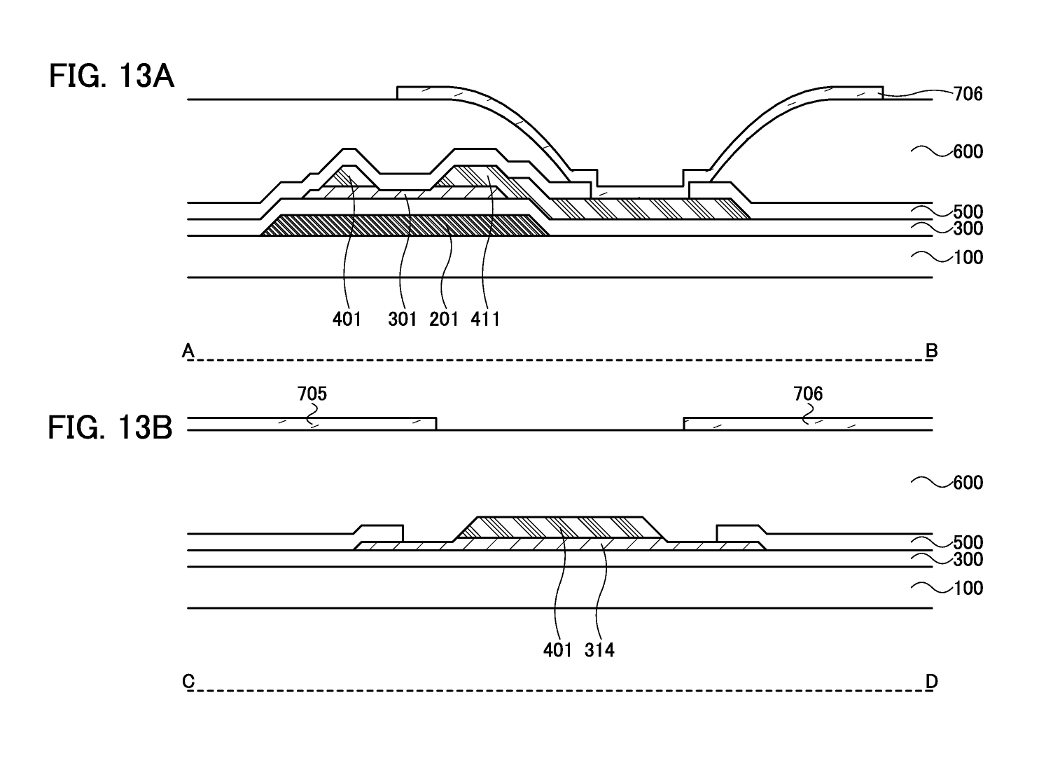

Next, a conductive layer 701, a conductive layer 702, a conductive layer 703, a conductive layer 704, a conductive layer 705, a conductive layer 706, a conductive layer 707, a conductive layer 708, a conductive layer 709, a conductive layer 710, a conductive layer 711, and a conductive layer 712 are formed over the resin layer 600 (FIG. 12 and FIGS. 13A and 13B).

FIG. 13A illustrates an example of a cross-sectional view taken along the line A-B in FIG. 12.

FIG. 13B illustrates an example of a cross-sectional view taken along the line C-D in FIG. 12.

The conductive layers 701 to 712 can each function as one electrode of an element.

A display element, a memory element, a capacitor, and the like are given as examples of the element, but the element is not limited to these examples.

A liquid crystal element, a light-emitting element (an EL element), an electrophoresis element, and the like are given as examples of the display element, but the display element is not limited to these examples.

A resistive random access memory, a ferroelectric memory, a magnetoresistive random access memory, an organic memory, and the like are given as examples of the memory element, but the memory element is not limited to these examples.

The conductive layers 701 to 712 each have a light-transmitting property in some cases.

The conductive layers 701 to 712 each have a light-blocking property in some cases.

The conductive layers 701 to 712 each have reflectivity in some cases.

The oxide semiconductor layer has a light-transmitting property.

In the case where one electrode of the element has a light-transmitting property and the element is a display element, it is preferable that one electrode of the element overlap with the oxide semiconductor layer because an aperture ratio can be increased.

The positional relation between one electrode of the element and the oxide semiconductor layer is described with reference to FIGS. 13A and 13B, for example. At least a part of the conductive layer 705 overlaps with at least a part of the oxide semiconductor layer 314. At least a part of the conductive layer 706 overlaps with at least a part of the oxide semiconductor layer 314.

A functional layer is formed over the conductive layers 701 to 712.

Note that the element includes one electrode of the element, the functional layer, and the other electrode of the element.

In the case of a liquid crystal element, for example, the functional layer is a liquid crystal layer.

In the case of an EL element, for example, the functional layer is a layer containing an organic compound.

In the case of a capacitor, for example, the functional layer is an insulating layer (a dielectric layer).

The functional layer is not limited to the examples given above.

Next, the other electrode of the element is formed over the functional layer.

Next, as necessary, the oxide semiconductor layer and the element are sealed. Thus, the semiconductor device can be fabricated.

A sealing body can be provided over the element to seal the oxide semiconductor layer and the element.

Examples of the sealing body include a substrate and a sealant can, but the sealing body is not limited to these examples.

A sealant (a sealing material) is preferably provided between the sealing body and the substrate.

Examples of the sealant (the sealing material) include an adhesive containing an organic material and glass frit, but the sealant is not limited to these examples.

The sealant is preferably provided in a position overlapping with a first predetermined region (a sealing region) of the substrate.

The oxide semiconductor layer is preferably provided in a position overlapping with a second predetermined region (an element region (a region where at least an element is provided), a driver circuit region (a region where at least a circuit for driving an element is provided), a region between the element region and the driver circuit region, a region outside the element region, a region outside the driver circuit region, or the like) of the substrate.

In the case where the element is a display element, the element region is called a pixel region.

The element is preferably provided in the element region.

The first predetermined region has a shape that surrounds the second predetermined region.

Since the first predetermined region has a shape that surrounds the second predetermined region, the resin layer that is directly on the oxide semiconductor layer is not exposed to outside air (atmospheric air).

The amount of H₂O that moves to the oxide semiconductor layer can be controlled by adjusting the amount of H₂O in the resin layer.

If the resin layer that is directly on the oxide semiconductor layer is exposed to outside air (atmospheric air), H₂O contained in the outside air (the atmospheric air) moves to the resin layer, and thus, the amount of H₂O in the resin layer might be greatly changed.

Hence, when at least the resin layer that is directly on the oxide semiconductor layer is not exposed to outside air (atmospheric air), a great change in the amount of H₂O in the resin layer due to outside air (atmospheric air) can be prevented from being caused.

Note that the resin layer may be provided in a position overlapping with both the first predetermined region and the second predetermined region.

In the case where the resin layer is provided in the position overlapping with both the first predetermined region and the second predetermined region, a side surface of the resin layer is exposed to outside air (atmospheric air), but it does not become a serious problem because the side surface of the resin layer is apart from the oxide semiconductor layer.

On the other hand, it is preferable that the resin layer be provided so as not to overlap with the first predetermined region and the resin layer be provided in the position overlapping with the second predetermined region, in which case the resin layer can be prevented from being exposed to outside air (atmospheric air).

There is a case where the resin layer directly on the oxide semiconductor layer may be exposed to outside air (atmospheric air).

For example, when the oxide semiconductor layer functions as an electrode or a wiring, the amount of H₂O that moves to the oxide semiconductor layer is preferably as large as possible. In that case, there is no problem even when the resin layer directly on the oxide semiconductor layer is exposed to outside air (atmospheric air).

At least part of the structure described in this embodiment can be combined with at least part of a structure described in any of the other embodiments.

### Embodiment 4

An example of a display device is described.

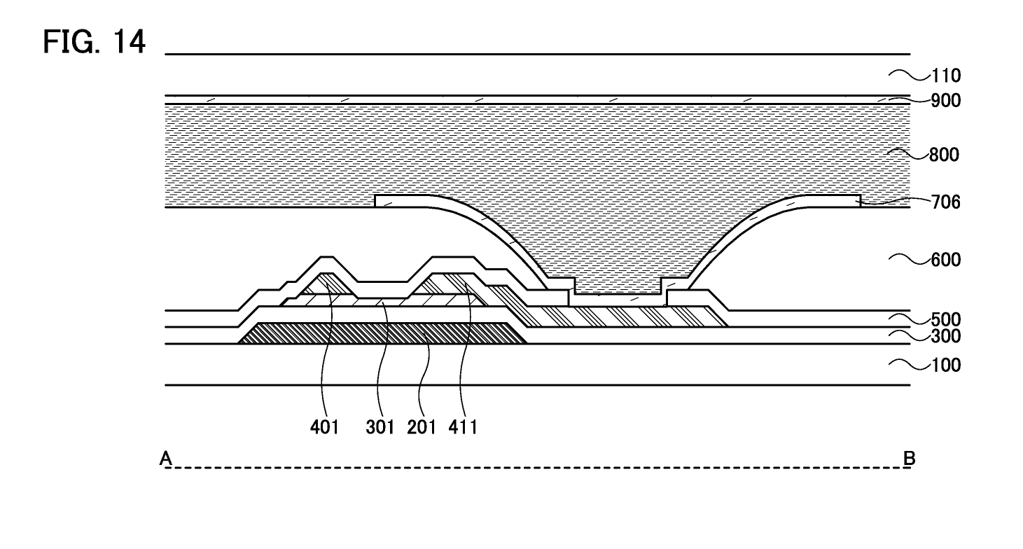

FIG. 14 illustrates an example of a liquid crystal display device (one kind of semiconductor devices).

FIG. 14 is different from FIG. 13A in that a liquid crystal layer 800, a conductive layer 900, and a substrate 110 are provided.

The conductive layer 900 is formed on the substrate 110.

The liquid crystal layer 800 is sandwiched between the conductive layer 706 and the conductive layer 900.

An alignment film may be provided between the conductive layer 706 and the liquid crystal layer 800.

An alignment film may be provided between the conductive layer 900 and the liquid crystal layer 800.

The substrate 100 or the substrate 110 may be provided with a color filter, a black matrix, and the like.

A sealant is preferably provided between the substrate 100 and the substrate 110.

The oxide semiconductor layer and the element are preferably provided in a region surrounded by the sealant.

The resin layer is preferably not exposed to outside air (atmospheric air).

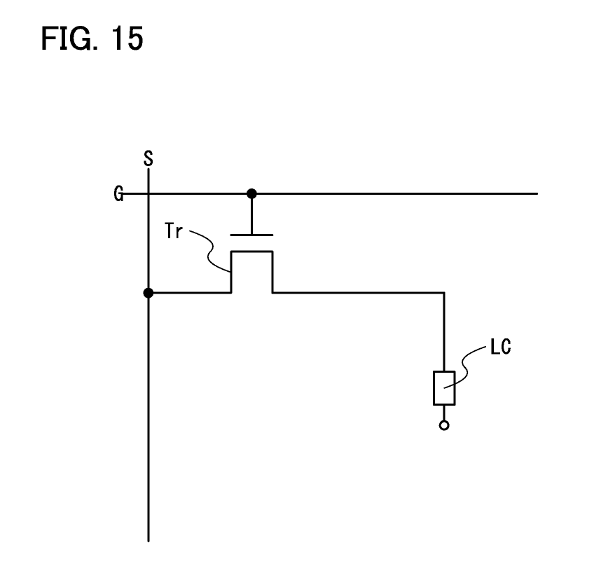

FIG. 15 illustrates an example of a circuit diagram of the liquid crystal display device (one kind of semiconductor devices).

A wiring G is electrically connected to a gate of a transistor Tr.

A wiring S is electrically connected to one of a source and a drain of the transistor Tr.

One electrode of a liquid crystal element LC is electrically connected to the other of the source and the drain of the transistor Tr.

The relation between FIG. 14 and FIG. 15 is described.

At least a part of the conductive layer 201 can function as a gate electrode of a transistor Tr, for example.

At least a part of the conductive layer 201 can function as a wiring G for example.

At least a part of the insulating layer 300 can function as a gate insulating film of the transistor Tr, for example.

At least a part of the oxide semiconductor layer 301 can function as an active layer of the transistor Tr, for example.

At least a part of the conductive layer 401 can function as one of a source electrode and a drain electrode of the transistor Tr, for example.

At least a part of the conductive layer 401 can function as a wiring S, for example.

At least a part of the conductive layer 411 can function as the other of the source electrode and the drain electrode of the transistor Tr, for example.

At least a part of the conductive layer 706 can function as one electrode of a liquid crystal element LC, for example.

At least a part of the liquid crystal layer 800 can function as a functional layer of the liquid crystal element LC, for example.

At least a part of the conductive layer 900 can function as the other electrode of the liquid crystal element LC, for example.

At least part of the structure described in this embodiment can be combined with at least part of a structure described in any of the other embodiments.

### Embodiment 5

An example of a display device is described.

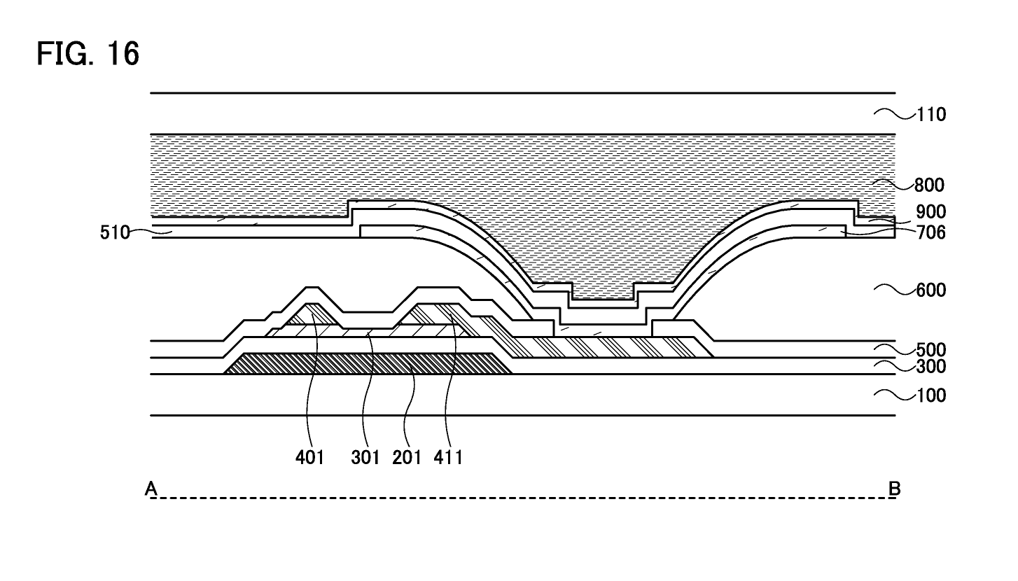

FIG. 16 illustrates an example of a liquid crystal display device (one kind of semiconductor devices) using fringe field switching (FFS) driving.

FIG. 16 is different from FIG. 13A in that an insulating layer 510, the liquid crystal layer 800, the conductive layer 900, and the substrate 110 are provided.

The insulating layer 510 is formed over the conductive layer 706.

The conductive layer 900 is formed over the insulating layer 510.

The liquid crystal layer 800 is sandwiched between the conductive layer 900 and the substrate 110.

The alignment film may be provided between the conductive layer 900 and the liquid crystal layer 800.

A hole may be provided in the conductive layer 900.

The liquid crystal layer is controlled by an electric field generated between the conductive layer 900 and the conductive layer 706.

The substrate 100 or the substrate 110 may be provided with a color filter, a black matrix, and the like.

The sealant is preferably provided between the substrate 100 and the substrate 110.

The oxide semiconductor layer and the element are preferably provided in the region surrounded by the sealant.

The resin layer is preferably not exposed to outside air (atmospheric air).

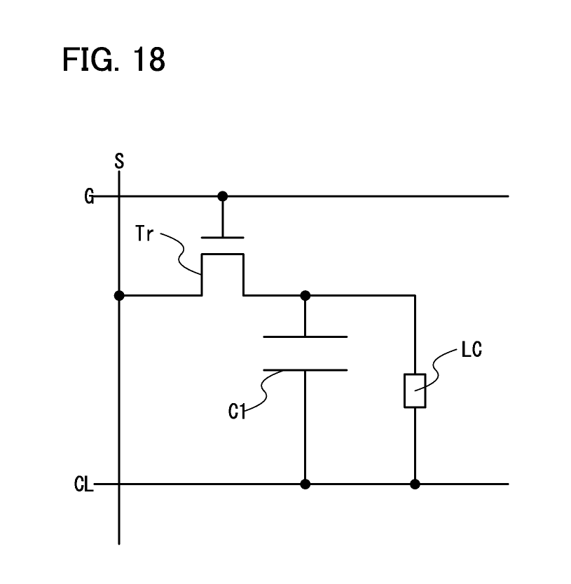

FIG. 18 illustrates an example of a circuit diagram of the liquid crystal display device (one kind of semiconductor devices).

The wiring G is electrically connected to the gate of the transistor Tr.

The wiring S is electrically connected to one of the source and the drain of the transistor Tr.

One electrode of the liquid crystal element LC is electrically connected to the other of the source and the drain of the transistor Tr.

The other electrode of the liquid crystal element LC is electrically connected to a wiring CL.

One electrode of a capacitor C 1 is electrically connected to the other of the source and the drain of the transistor Tr.

The other electrode of the capacitor C 1 is electrically connected to the wiring CL.

The relation between FIG. 16 and FIG. 18 is described.

At least a part of the conductive layer 201 can function as the gate electrode of the transistor Tr, for example.

At least a part of the conductive layer 201 can function as the wiring Q for example.

At least a part of the insulating layer 300 can function as the gate insulating film of the transistor Tr, for example.

At least a part of the oxide semiconductor layer 301 can function as the active layer of the transistor Tr, for example.

At least a part of the conductive layer 401 can function as one of the source electrode and the drain electrode of the transistor Tr, for example.

At least a part of the conductive layer 401 can function as the wiring S, for example.

At least a part of the conductive layer 411 can function as the other of the source electrode and the drain electrode of the transistor Tr, for example.

At least a part of the conductive layer 706 can function as one electrode of the liquid crystal element LC, for example.

At least a part of the conductive layer 706 can function as one electrode of a capacitor C1, for example.

At least a part of the liquid crystal layer 800 can function as the functional layer of the liquid crystal element LC, for example.

At least a part of the conductive layer 900 can function as the other electrode of the liquid crystal element LC, for example.

At least a part of the conductive layer 900 can function as the other electrode of the capacitor C1, for example.

At least a part of the conductive layer 900 can function as the wiring CL, for example.

At least part of the structure described in this embodiment can be combined with at least part of a structure described in any of the other embodiments.

### Embodiment 6

An example of a display device is described.

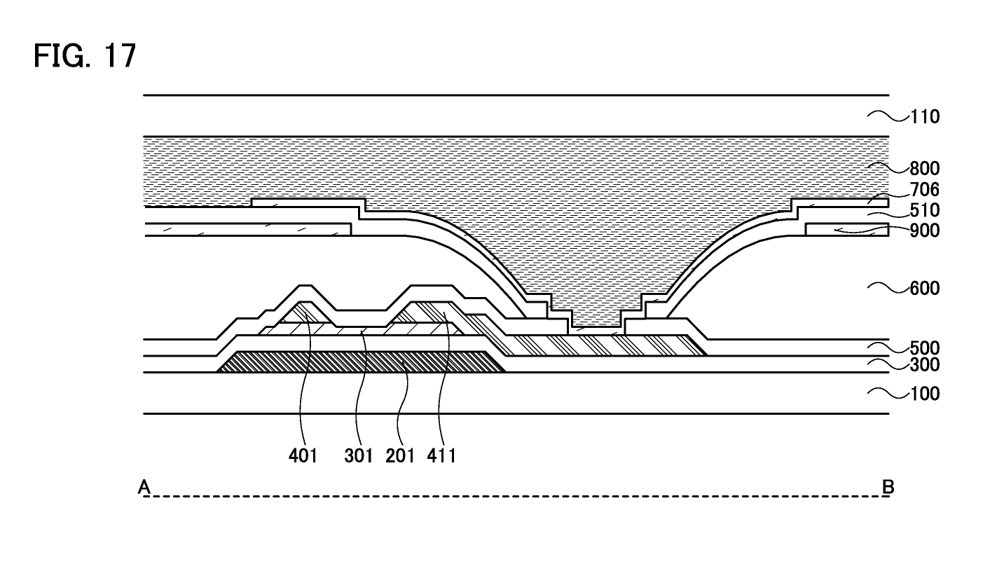

FIG. 17 illustrates an example of a liquid crystal display device (one kind of semiconductor devices) using fringe field switching (FFS) driving.

FIG. 17 is different from FIG. 13A in that the insulating layer 510, the liquid crystal layer 800, the conductive layer 900, and the substrate 110 are provided.

The conductive layer 900 is formed over the resin layer 600.

The insulating layer 510 is formed over the conductive layer 900.

The conductive layer 706 is formed over the insulating layer 510.

The liquid crystal layer 800 is sandwiched between the conductive layer 706 and the substrate 110.

The alignment film may be provided between the conductive layer 706 and the liquid crystal layer 800.

A hole may be provided in the conductive layer 706.

The liquid crystal layer is controlled by an electric field generated between the conductive layer 900 and the conductive layer 706.

The substrate 100 or the substrate 110 may be provided with a color filter, a black matrix, and the like.

The sealant is preferably provided between the substrate 100 and the substrate 110.

The oxide semiconductor layer and the element are preferably provided in the region surrounded by the sealant.

The resin layer is preferably not exposed to outside air (atmospheric air).

FIG. 18 illustrates an example of a circuit diagram of the liquid crystal display device (one kind of semiconductor devices).

The wiring G is electrically connected to the gate of the transistor Tr.

The wiring S is electrically connected to one of the source and the drain of the transistor Tr.

One electrode of the liquid crystal element LC is electrically connected to the other of the source and the drain of the transistor Tr.

The other electrode of the liquid crystal element LC is electrically connected to the wiring CL.

One electrode of the capacitor C1 is electrically connected to the other of the source and the drain of the transistor Tr.

The other electrode of the capacitor C 1 is electrically connected to the wiring CL.

The relation between FIG. 17 and FIG. 18 is described.

At least a part of the conductive layer 201 can function as the gate electrode of the transistor Tr, for example.

At least a part of the conductive layer 201 can function as the wiring G for example.

At least a part of the insulating layer 300 can function as the gate insulating film of the transistor Tr, for example.

At least a part of the oxide semiconductor layer 301 can function as the active layer of the transistor Tr, for example.

At least a part of the conductive layer 401 can function as one of the source electrode and the drain electrode of the transistor Tr, for example.

At least a part of the conductive layer 401 can function as the wiring S, for example.

At least a part of the conductive layer 411 can function as the other of the source electrode and the drain electrode of the transistor Tr, for example.

At least a part of the conductive layer 706 can function as one electrode of the liquid crystal element LC, for example.

At least a part of the conductive layer 706 can function as one electrode of the capacitor C1, for example.

At least a part of the liquid crystal layer 800 can function as the functional layer of the liquid crystal element LC, for example.

At least a part of the conductive layer 900 can function as the other electrode of the liquid crystal element LC, for example.

At least a part of the conductive layer 900 can function as the other electrode of the capacitor C1, for example.

At least a part of the conductive layer 900 can function as the wiring CL, for example.

At least part of the structure described in this embodiment can be combined with at least part of a structure described in any of the other embodiments.

### Embodiment 7

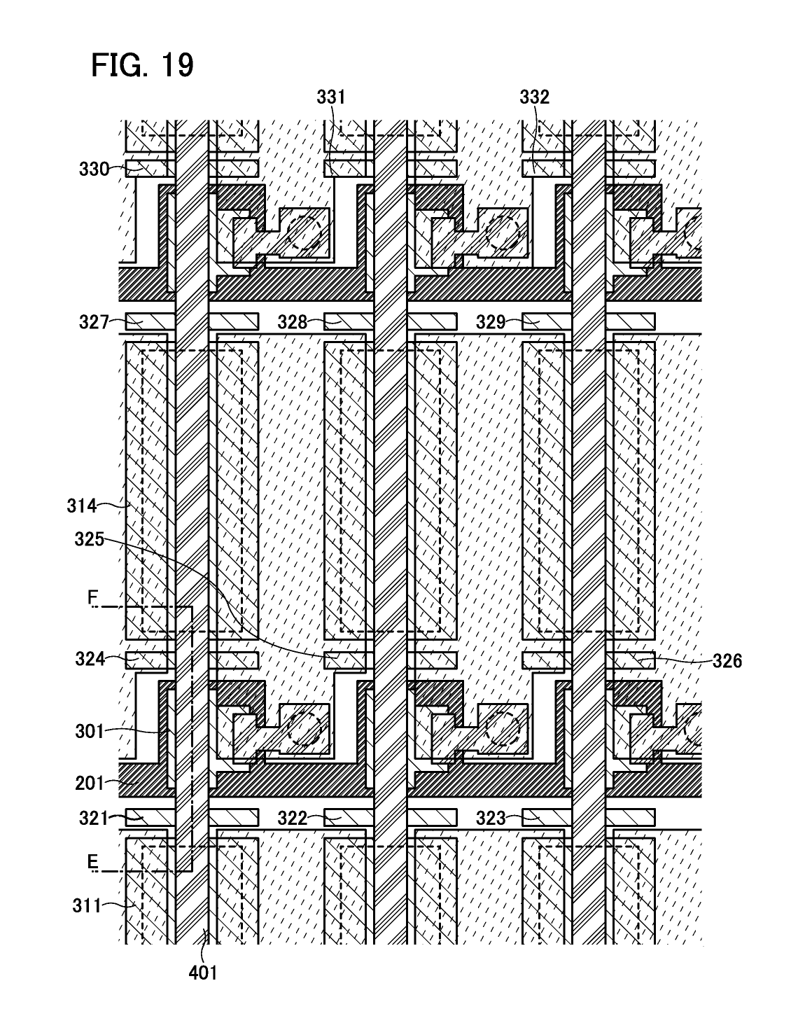

FIG. 19 illustrates an example of a drawing which is different from FIG. 12 in that an oxide semiconductor layer 321, an oxide semiconductor layer 322, an oxide semiconductor layer 323, an oxide semiconductor layer 324, an oxide semiconductor layer 325, an oxide semiconductor layer 326, an oxide semiconductor layer 327, an oxide semiconductor layer 328, an oxide semiconductor layer 329, an oxide semiconductor layer 330, an oxide semiconductor layer 331, and an oxide semiconductor layer 332 are provided.

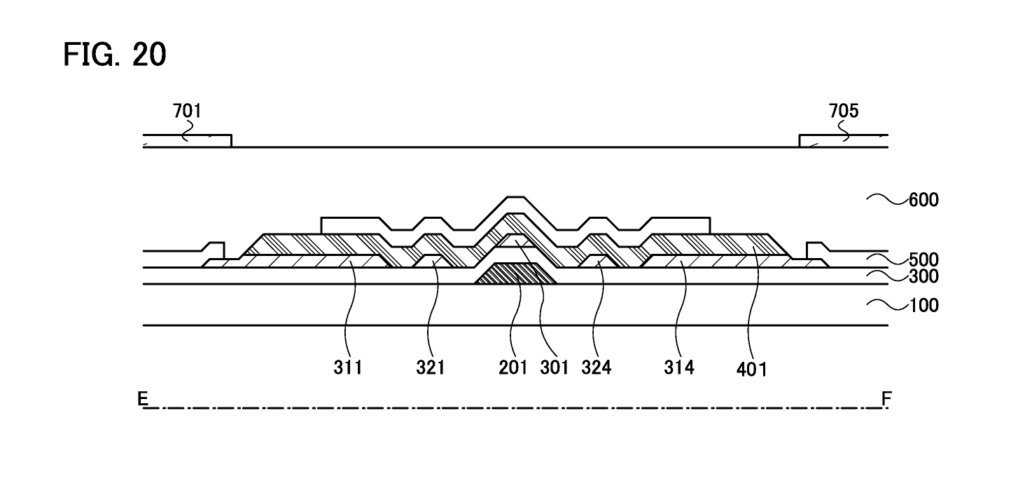

FIG. 20 illustrates an example of a cross-sectional view taken along the line E-F in FIG. 19.

The positional relation among the oxide semiconductor layers is described with reference to FIG. 19 and FIG. 20, for example.

The oxide semiconductor layer 321 is provided between the oxide semiconductor layer 311 and the oxide semiconductor layer 301.

The oxide semiconductor layer 324 is provided between the oxide semiconductor layer 314 and the oxide semiconductor layer 301.

The oxide semiconductor layers 321 to 332 are covered with the inorganic insulating layer 500 and are therefore not in contact with the resin layer 600.

H₂O that moves along the interface between the insulating layer 300 and the inorganic insulating layer 500, in the insulating layer 300, or in the inorganic insulating layer 500 can be absorbed in the oxide semiconductor layers 321 to 332. Accordingly, the amount of H₂O reaching the oxide semiconductor layer having a function as the active layer of the transistor can be reduced.

At least part of the structure described in this embodiment can be combined with at least part of a structure described in any of the other embodiments.

### Embodiment 8

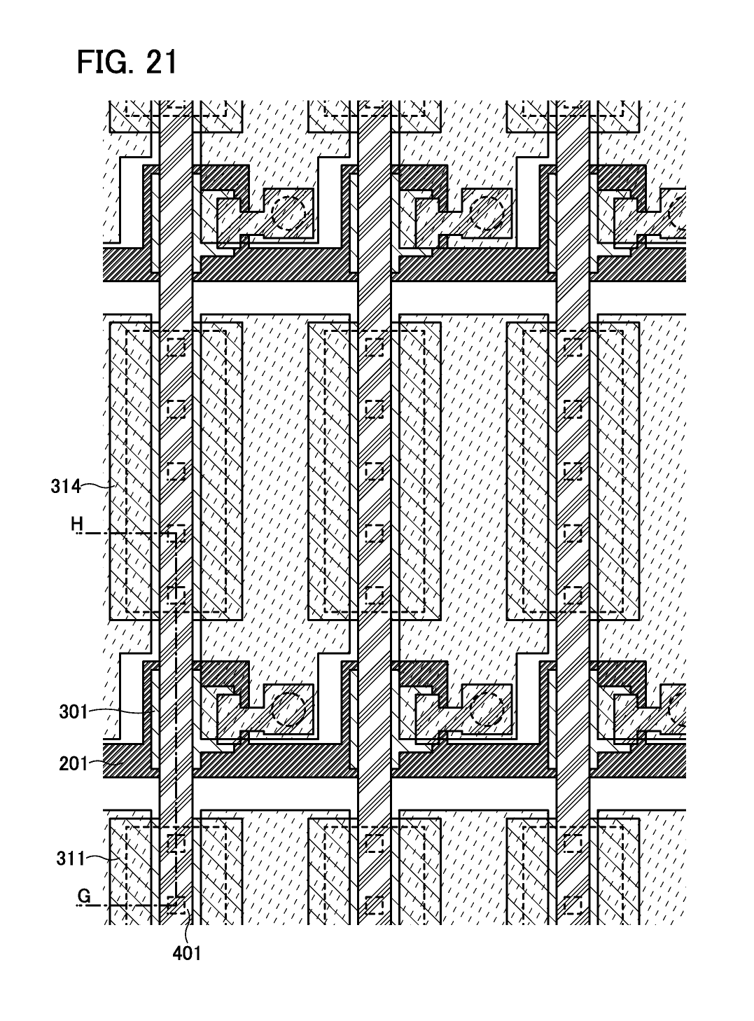

FIG. 21 illustrates an example of a drawing which is different from FIG. 12 in that holes are provided in the oxide semiconductor layers 311 to 319.

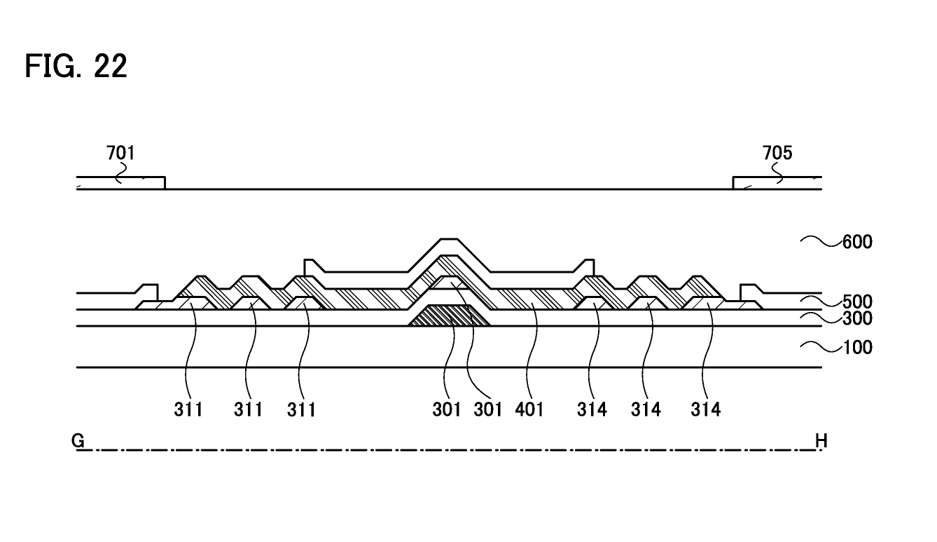

FIG. 22 illustrates an example of a cross-sectional view taken along the line G-H in FIG. 21.

In FIG. 22, for example, the conductive layer 401 includes regions overlapping with a plurality of holes provided in the oxide semiconductor layer 311.

In FIG. 22, for example, the conductive layer 401 includes regions overlapping with a plurality of holes provided in the oxide semiconductor layer 314.

When current is fed to a predetermined location, the higher the resistance of the location in which current flows is, the more easily the location is heated.

In the case where the contact resistance between the oxide semiconductor layer and the conductive layer is high, the temperature of a portion where the oxide semiconductor layer is in contact with the conductive layer becomes high.

Hence, the larger the area of contact between the oxide semiconductor layer and the conductive layer is, the higher the temperatures of the conductive layer and the oxide semiconductor layer become.

When the temperatures of the conductive layer and the oxide semiconductor layer increase, the temperature of the resin layer also increases.

When the temperature of the resin layer increases, gas (e.g., H₂O gas) is released from the resin layer in some cases.

The release of gas from the resin layer might affect the characteristics of the element provided over the resin layer.

The holes provided in the oxide semiconductor layers can reduce the area of contact between each of the oxide semiconductor layers and the conductive layer.

The reduction of the area of contact between each of the oxide semiconductor layers and the conductive layer can inhibit a rise in temperatures of the conductive layer and the oxide semiconductor layers; hence, it is possible to inhibit the release of gas from the resin layer.

Further, if the temperature of the conductive layer increases, the temperature of the active layer in contact with the conductive layer increases and an adverse effect on the operation of the transistor might arise.

Hence, the reduction of the area of contact between each of the oxide semiconductor layers and the conductive layer can inhibit a rise in temperature of the transistor.

At least part of the structure described in this embodiment can be combined with at least part of a structure described in any of the other embodiments.

### Embodiment 9

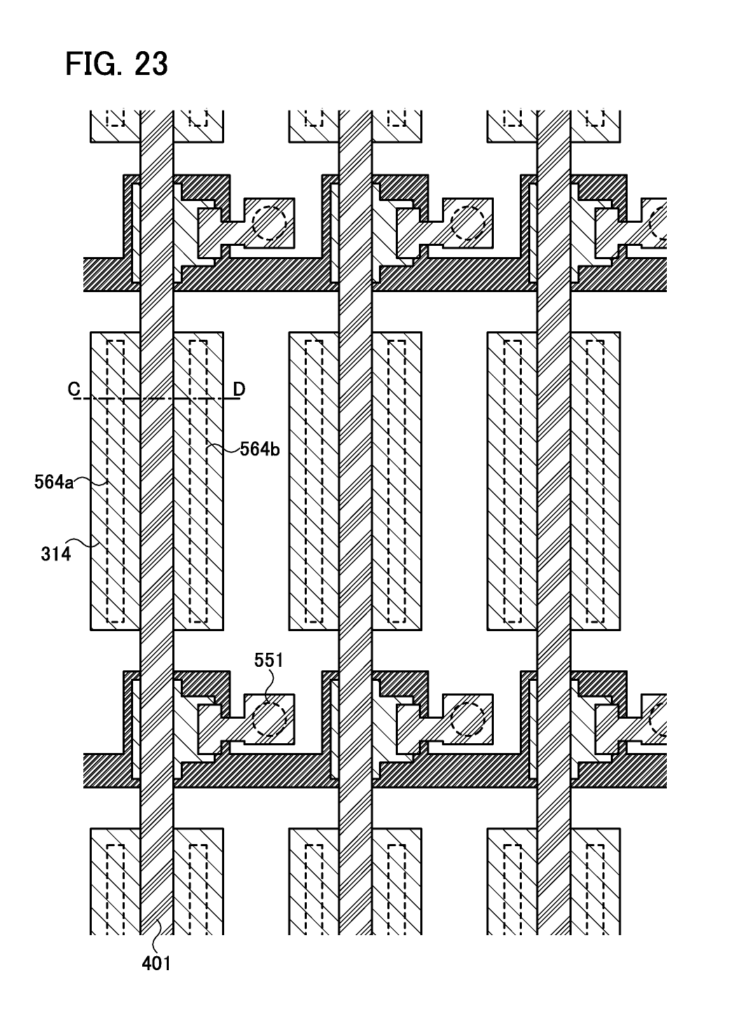

FIG. 23 illustrates an example of a drawing which is different from FIG. 9 in the shape of the holes of the inorganic insulating layer 500.

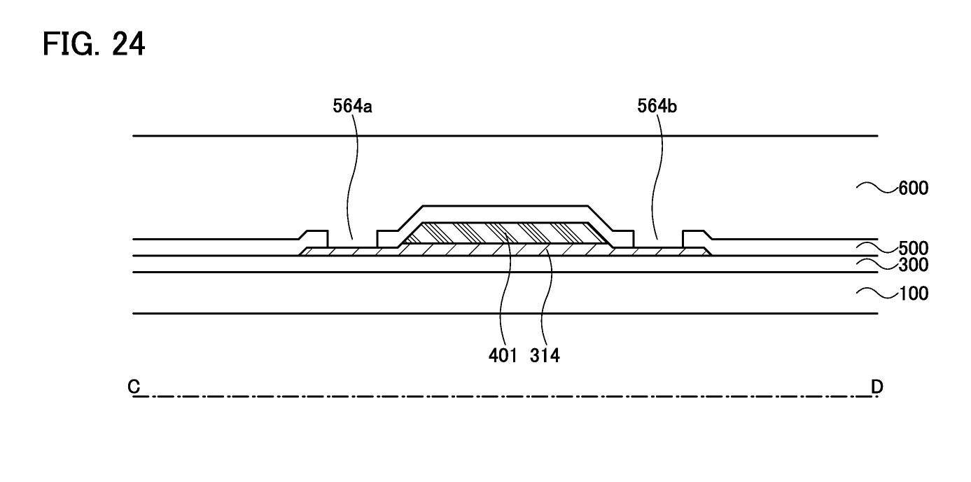

FIG. 24 illustrates an example of a cross-sectional view taken along the line C-D in FIG. 23.

Since the adhesion between the conductive layer and the resin layer is poor, when the resin layer is formed on the conductive layer, the resin layer is separated in some cases.

In FIG. 9, the conductive layer is in contact with the resin layer.

Hence, in FIG. 23, the holes of the inorganic insulating layer 500 each have a shape such that the conductive layer is not in contact with the resin layer.

In FIGS. 23 and 24, a hole 564a and a hole 564b are provided in the inorganic insulating layer 500.

The hole 564a and the hole 564b do not overlap with the conductive layer 401, so that the conductive layer 401 and the resin layer 600 can be prevented from being in contact with each other.

At least part of the structure described in this embodiment can be combined with at least part of a structure described in any of the other embodiments.

### Embodiment 10

In FIG. 9, the area of the hole 564 is larger than the area of the contact hole 551.

Also in FIG. 23, the area of each of the hole 564a and the hole 564b is larger than the area of the contact hole 551.

Incidentally, when the conductive layer is formed on and in contact with the semiconductor layer, a surface of the oxide semiconductor layer that does not overlap with the conductive layer is etched.

Hence, a part of the oxide semiconductor layer that does not overlap with the conductive layer becomes thinner than a part of the oxide semiconductor layer that overlaps with the conductive layer.

Further, also when the hole is formed in the inorganic insulating layer 500, a surface of the oxide semiconductor layer is etched in some cases.

In general, the larger the area of the hole to be provided in the insulating layer is, the more the etching rate of the insulating layer tends to increase.

Hence, when a hole having a large area is provided, a part of the oxide semiconductor layer disappears in the inside of the hole in some cases.

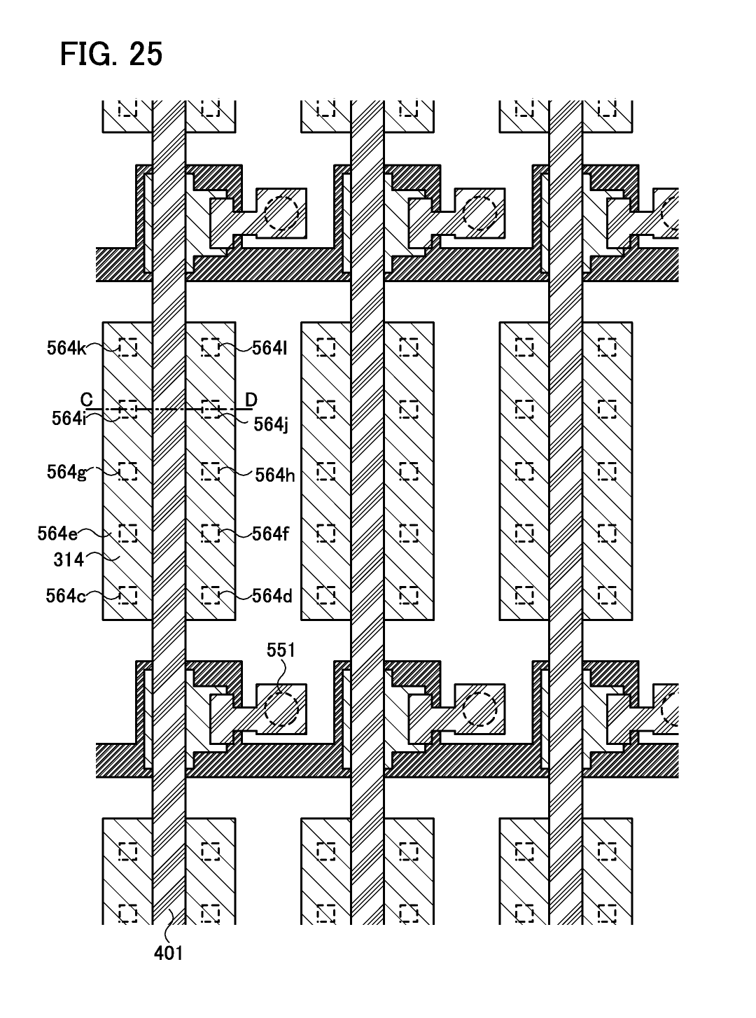

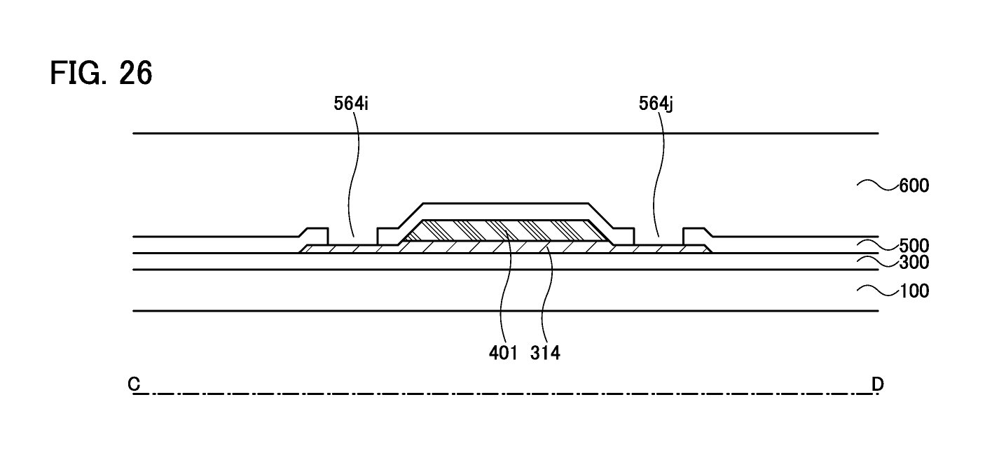

Thus, an example of the case where the area of the hole is smaller than the area of the contact hole is illustrated in FIGS. 25 and 26.

FIG. 26 illustrates an example of a cross-sectional view taken along the line C-D in FIG. 25.

In FIGS. 25 and 26, a hole 564c, a hole 564d, a hole 564e, a hole 564f, a hole 564g, a hole 564h, a hole 564i, a hole 564j, a hole 564k, and a hole 564l are provided in the inorganic insulating layer 500.

The area of each of the holes 564c to 564l is smaller than the area of the contact hole 551. Thus, it is possible to reduce a probability of disappearance of a part of the oxide semiconductor layer in the inside of each of the holes 564c to 564l.

It is preferable to form a plurality of holes, though one hole is also acceptable.

With the plurality of holes, the amount of H₂O that moves from the resin layer to the oxide semiconductor layer can be increased.

At least part of the structure described in this embodiment can be combined with at least part of a structure described in any of the other embodiments.

### Embodiment 11

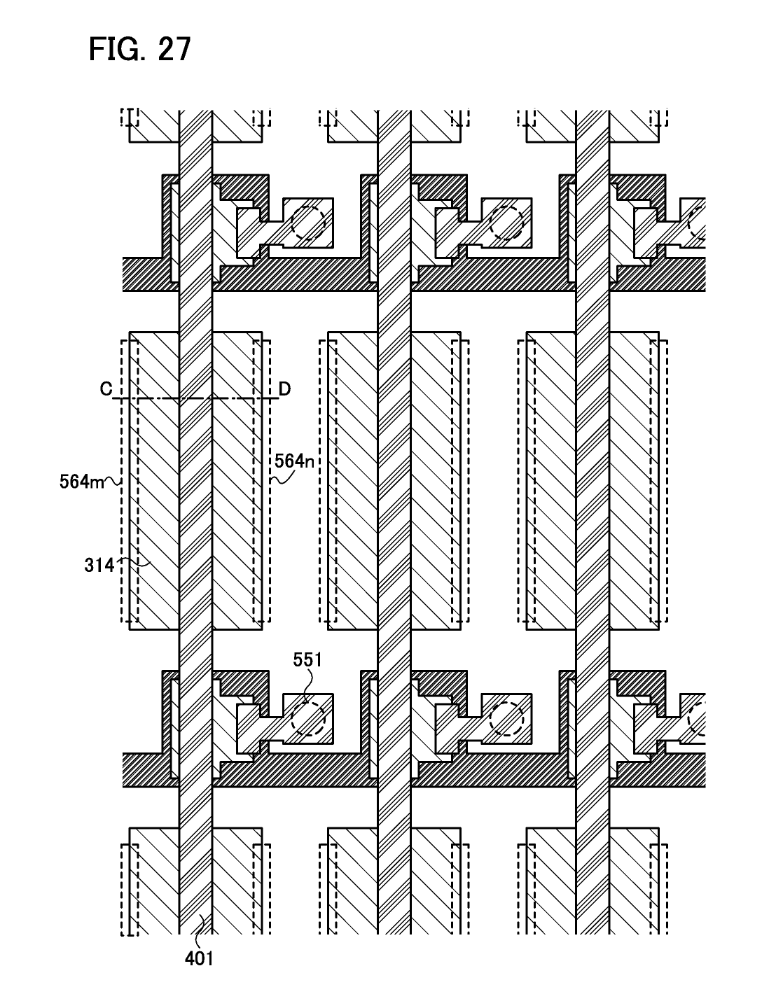

FIG. 27 illustrates an example of a drawing which is different from FIG. 9 in the shape of the holes of the inorganic insulating layer 500.

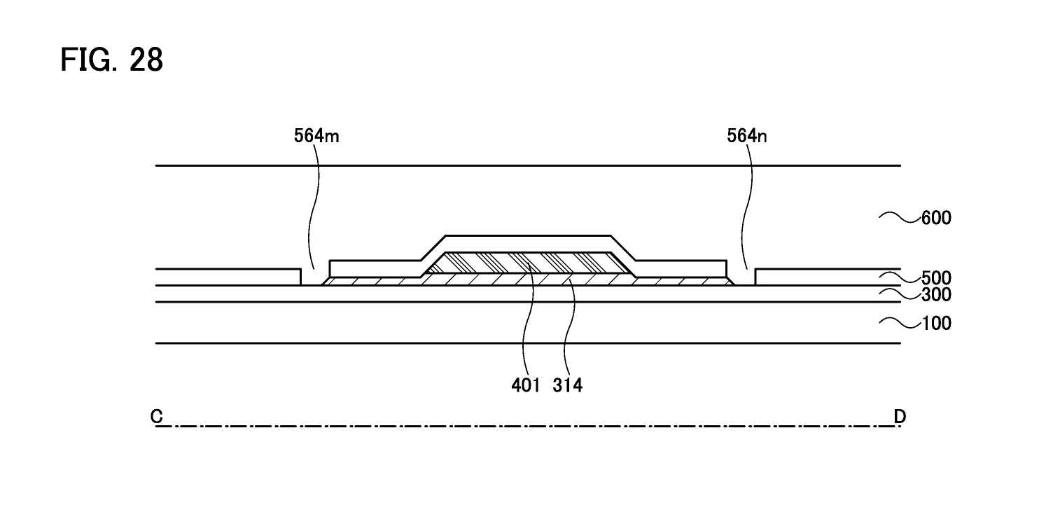

FIG. 28 illustrates an example of a cross-sectional view taken along the line C-D in FIG. 27.

In FIGS. 27 and 28, a hole 564m and a hole 564n are provided in the inorganic insulating layer 500.

The hole 564m and the hole 564n each have a region overlapping with a side surface of the oxide semiconductor layer 314. Hence, H₂O enters the oxide semiconductor layer 314 from its side surface.

It is preferable that the side surface of the oxide semiconductor layer be tapered.

The area of each of the holes 564m and 564n may be larger or smaller than the area of the contact hole 551.

In the case where the area of each of the holes 564m and 564n is larger than the area of the contact hole 551, H₂O can enter the oxide semiconductor layer 314 from its top and side surfaces, for example.

When the area of each of the holes 564m and 564n is smaller than the area of the contact hole 551, the oxide semiconductor layer 314 can be prevented from partially disappearing, for example.

By the entry of H₂O from the top and side surfaces of the oxide semiconductor layer 314, the amount of H₂O that moves from the resin layer 600 to the oxide semiconductor layer 314 can be increased.

At least part of the structure described in this embodiment can be combined with at least part of a structure described in any of the other embodiments.

### Embodiment 12

In FIG. 11A, the contact hole in the resin layer 600 is larger than the contact hole in the inorganic insulating layer 500.

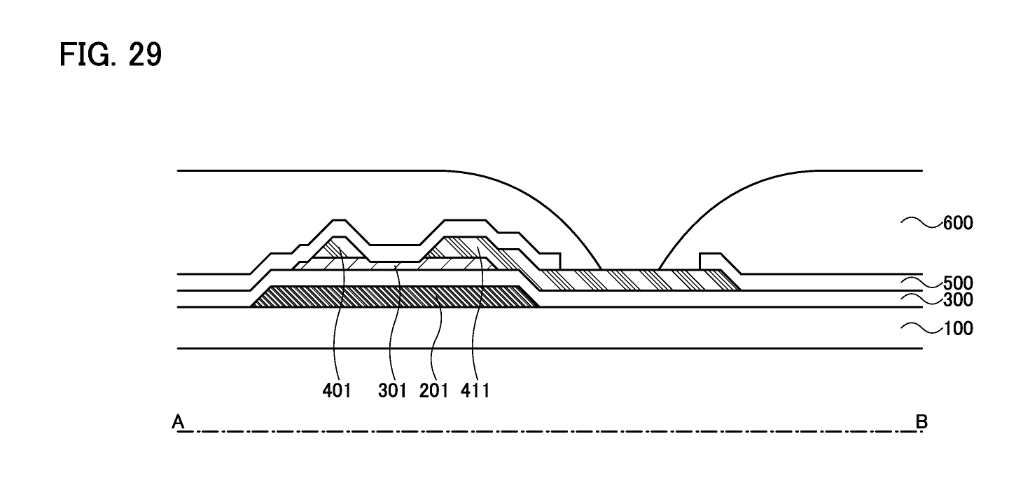

In contrast, as illustrated in FIG. 29, the contact hole in the resin layer 600 can be made smaller than the contact hole in the inorganic insulating layer 500.

By providing a region where the edge portion of the resin layer 600 is in contact with the conductive layer 411 as illustrated in FIG. 29, a distance between one electrode of the element and the transistor can be increased.

The increase of the distance between one electrode of the element and the transistor can reduce an adverse effect of an electric field generated in the periphery of one electrode of the element on the operation of the transistor.

However, in the structure as in FIG. 29, the area of the contact hole is small.

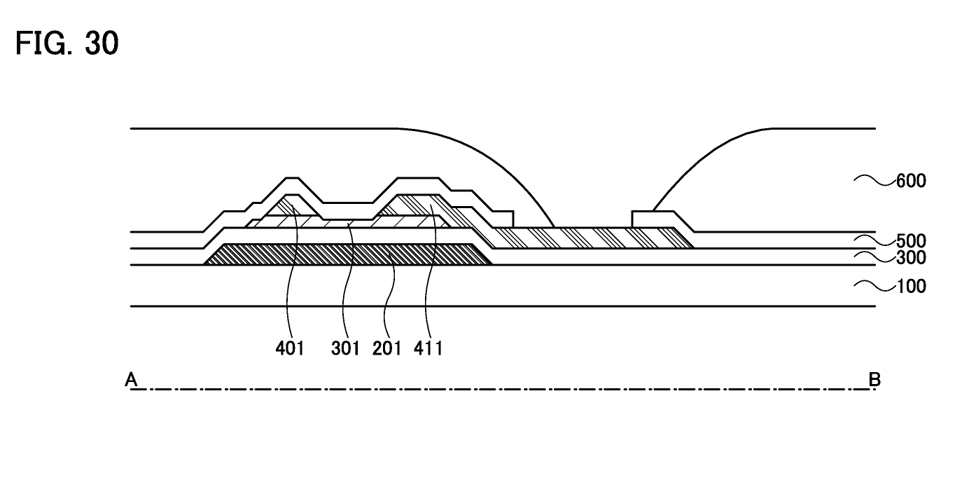

Thus, a structure as in FIG. 30 can be used, in which case the area of the contact hole can be larger than that in FIG. 29.

In FIG. 30, a region where the resin layer 600 is in contact with the conductive layer 411 is provided.

In FIG. 30, a part of a top surface of the inorganic insulating layer 500 is exposed in the inside of the contact hole of the resin layer 600.

That is, in FIG. 30, in the contact hole of the resin layer 600, there is a region where the top surface of the inorganic insulating layer 500 is exposed.

Hence, in FIG. 30, the region where the resin layer 600 is in contact with the conductive layer 411 is located between the transistor and the region where the top surface of the inorganic insulating layer 500 is exposed.

Also in FIG. 30, the distance between one electrode of the element and the transistor can be increased.

In the case where the structures in FIG. 29 and FIG. 30 are used, a semiconductor layer except the oxide semiconductor layer may be used.

At least part of the structure described in this embodiment can be combined with at least part of a structure described in any of the other embodiments.

### Embodiment 13

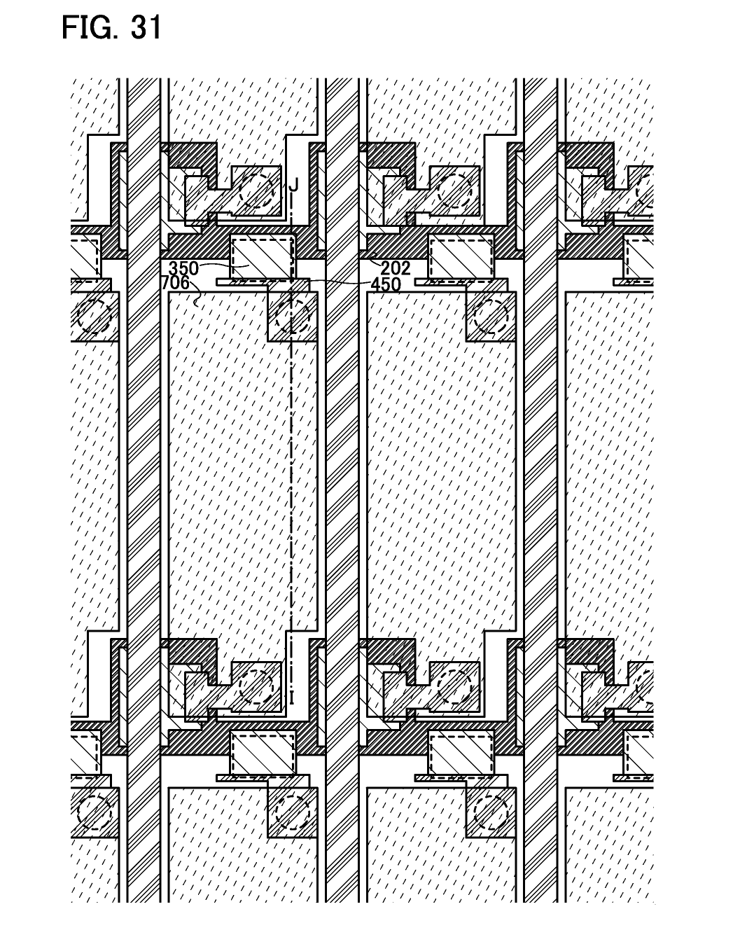

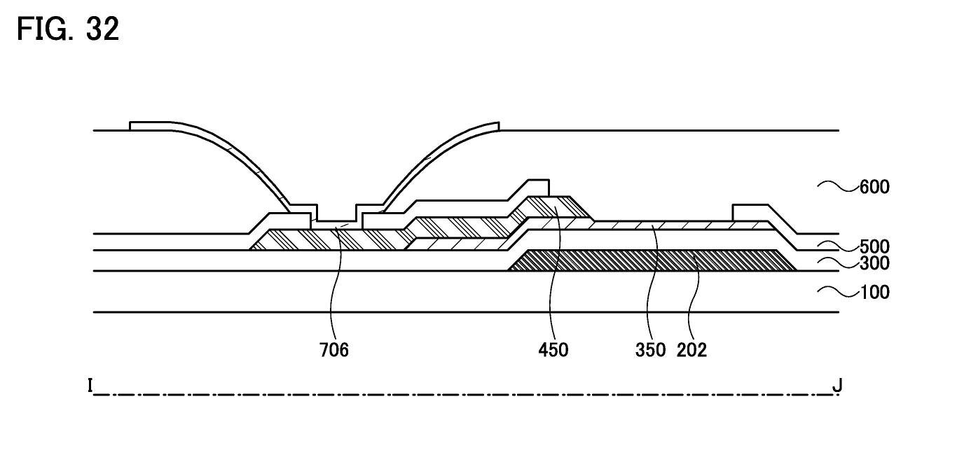

An example in which an oxide semiconductor layer being in contact with the resin layer is used as one electrode of a capacitor is illustrated in FIG. 31 and FIG. 32.

FIG. 31 illustrates an example of a drawing which is different from FIG. 12 in that the oxide semiconductor layers 311 to 319 and the like are not provided and an oxide semiconductor layer 350, a conductive layer 450, and the like are provided.

Note that FIG. 12 may be combined with FIG. 31.

That is, all the oxide semiconductor layers 311 to 319, the oxide semiconductor layer 350, the conductive layer 450, and the like may be provided.

FIG. 32 illustrates an example of a cross-sectional view taken along the line I-J in FIG. 31.

In FIGS. 31 and 32, the resin layer 600 includes a portion being in contact with the oxide semiconductor layer 350 in the inside of a hole provided in the inorganic insulating layer 500.

The conductive layer 706 is electrically connected to the conductive layer 450.

The conductive layer 450 is electrically connected to the oxide semiconductor layer 350.

Note that in FIGS. 31 and 32, the insulating layer 300 is provided over the conductive layer 202.

Further, in FIGS. 31 and 32, the oxide semiconductor layer 350 is provided over the insulating layer 300.

Furthermore, in FIGS. 31 and 32, the conductive layer 706 is provided over the oxide semiconductor layer 350.

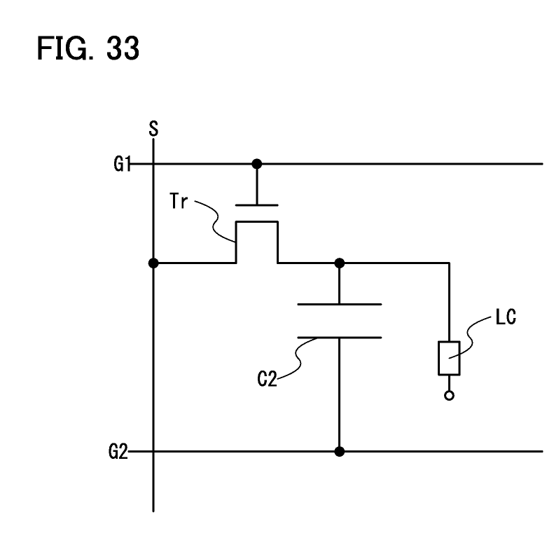

FIG. 33 illustrates an example of a circuit diagram of the case where the structure in FIGS. 31 and 32 is used for a liquid crystal display device.

A wiring G1 is electrically connected to the gate of the transistor Tr.

The wiring S is electrically connected to one of the source and the drain of the transistor Tr.

One electrode of the liquid crystal element LC is electrically connected to the other of the source and the drain of the transistor Tr.

One electrode of a capacitor C2 is electrically connected to the other of the source and the drain of the transistor Tr.

The other electrode of the capacitor C2 is electrically connected to a wiring G2.

The wiring G2 is electrically connected to a gate of a transistor in a pixel adjacent to a pixel including the transistor Tr. In this case, the wiring G2 functions as a gate wiring. Note that when the wiring G2 is made to function only as a capacitor wiring, the wiring G2 is not necessarily made to function as a gate wiring.

The relation between FIG. 33 and FIG. 32 is described.

At least a part of the conductive layer 202 can function as a wiring G2, for example.

At least a part of the conductive layer 202 can function as the other electrode of the capacitor C2, for example.

At least a part of the oxide semiconductor layer 350 can function as one electrode of the capacitor C2, for example.

At least a part of the conductive layer 706 can function as one electrode of the liquid crystal element LC, for example.

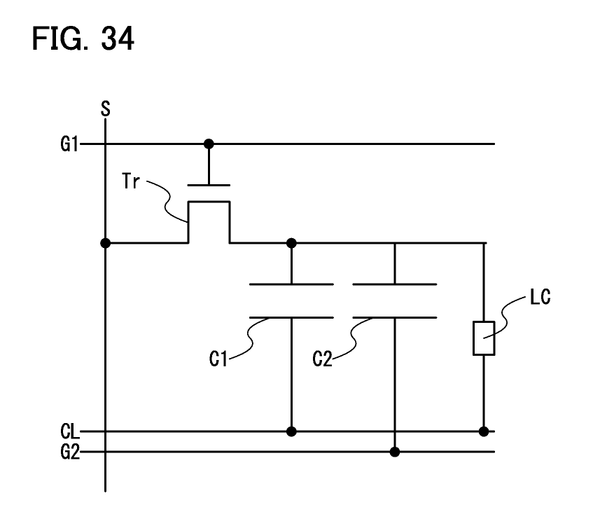

FIG. 34 illustrates an example of a circuit diagram of the case where the structure in FIGS. 31 and 32 is used for a liquid crystal display device using fringe field switching (FFS) driving.

FIG. 34 corresponds to a circuit diagram which is different from the circuit diagram in FIG. 33 in that the capacitor C1 and the wiring CL are provided.

One electrode of the capacitor C1 is electrically connected to the other of the source and the drain of the transistor Tr.

The other electrode of the capacitor C 1 is electrically connected to the wiring CL.

At least part of the structure described in this embodiment can be combined with at least part of a structure described in any of the other embodiments.

### Embodiment 14

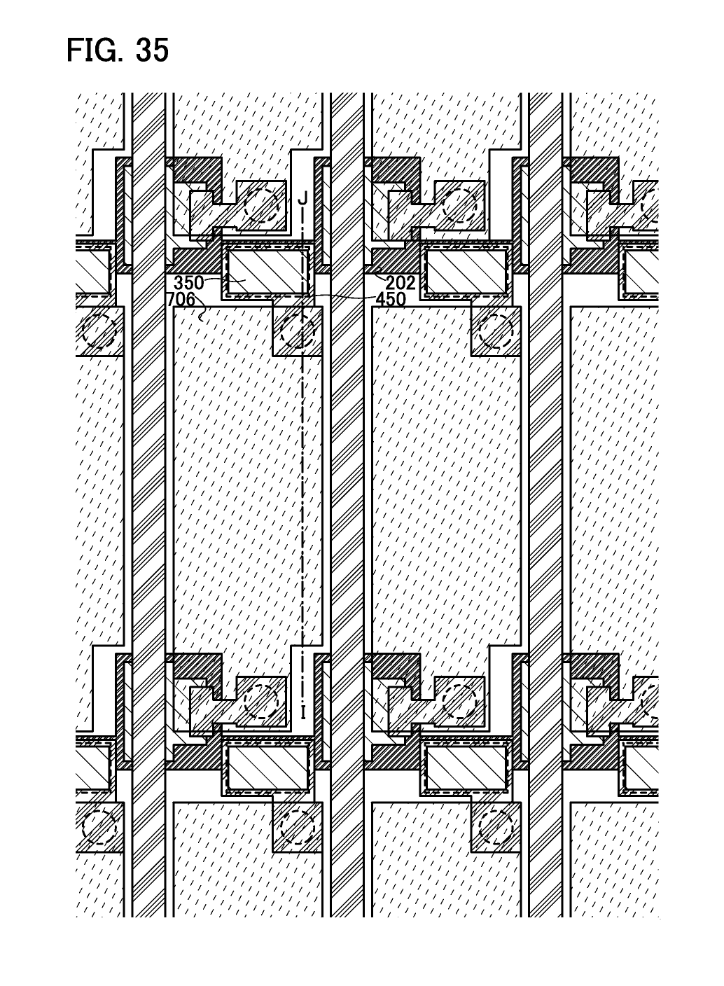

FIG. 35 illustrates an example of a drawing which is different from FIG. 31 in that the edge portion of the oxide semiconductor layer 350 is covered with the conductive layer 450.

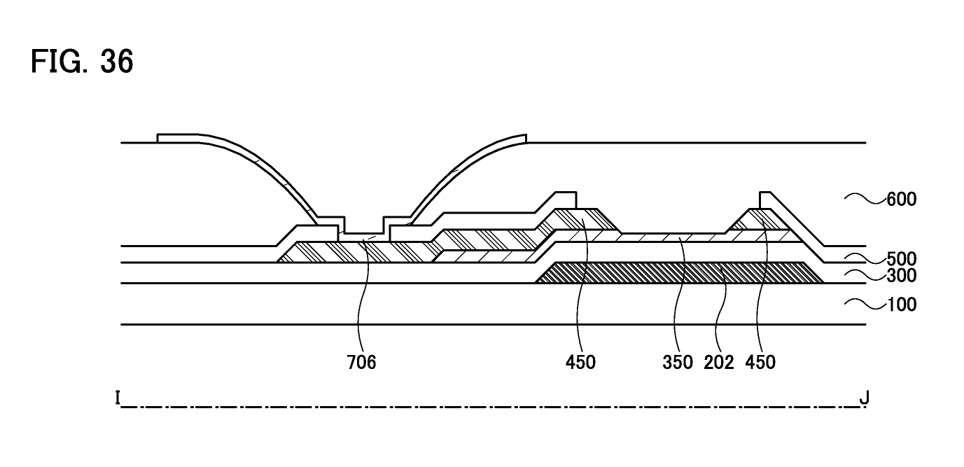

FIG. 36 illustrates an example of a cross-sectional view taken along the line I-J in FIG. 35.

In FIGS. 35 and 36, the conductive layer 450 has a hole, and a portion where the resin layer 600 is in contact with the oxide semiconductor layer 350 is provided in the inside of the hole of the conductive layer 450.

With the structure as in FIGS. 35 and 36, the conductive layer 450 can function as an auxiliary wiring of the oxide semiconductor layer 350.

At least part of the structure described in this embodiment can be combined with at least part of a structure described in any of the other embodiments.

### Embodiment 15

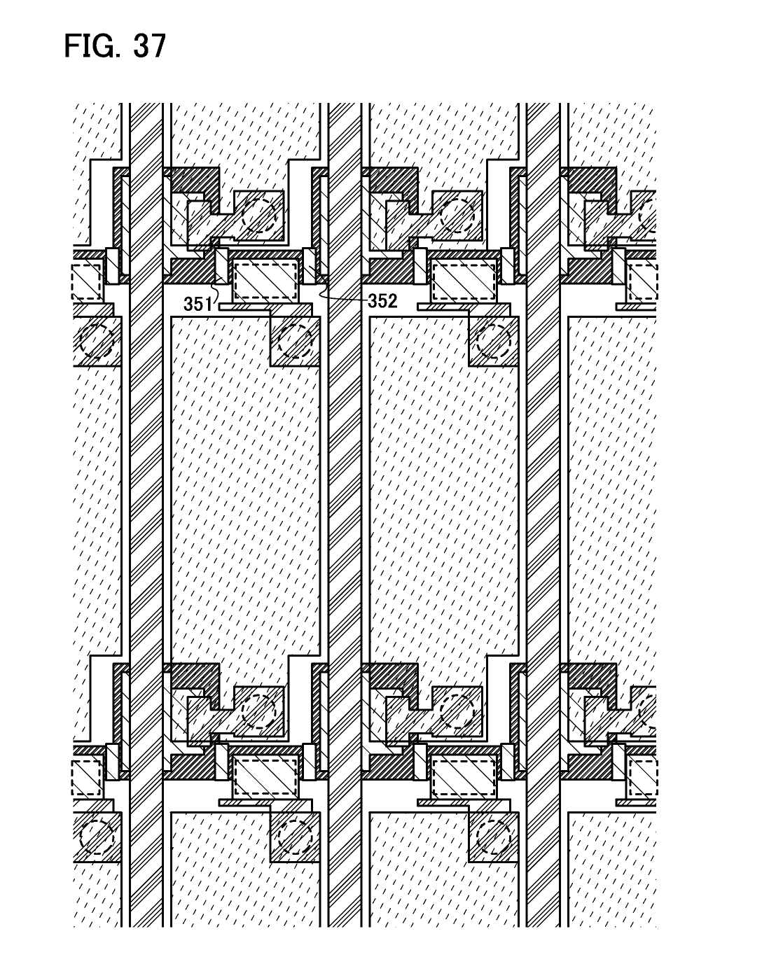

FIG. 37 illustrates an example of a drawing which is different from FIG. 31 in that an oxide semiconductor layer 351, an oxide semiconductor layer 352, and the like are provided.

In FIG. 37, the oxide semiconductor layer 351, the oxide semiconductor layer 352, and the like each include a region overlapping with the conductive layer (e.g., the conductive layer 202) capable of functioning as a gate wiring.

The oxide semiconductor layer which is not in contact with the resin layer is provided between the oxide semiconductor layer capable of functioning as one electrode of the capacitor and the oxide semiconductor layer capable of functioning as the active layer of the transistor. Thus, it is possible to reduce the amount of H₂O reaching the oxide semiconductor layer capable of functioning as the active layer of the transistor.

At least part of the structure described in this embodiment can be combined with at least part of a structure described in any of the other embodiments.

### Embodiment 16

An example of a display device is described.

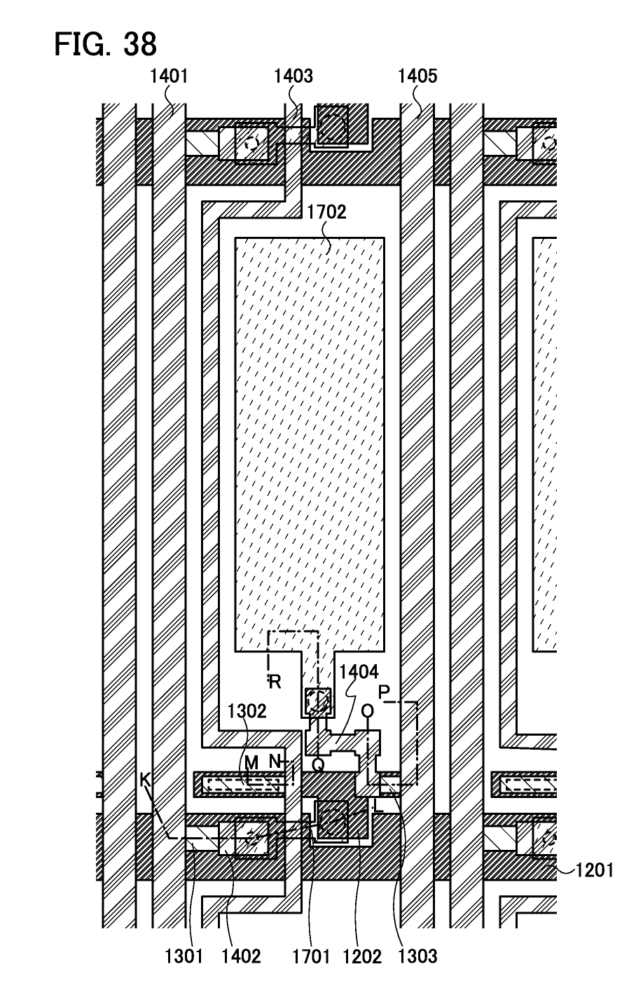

FIG. 38 illustrates an example of a light-emitting device (an EL display device as one kind of semiconductor devices).

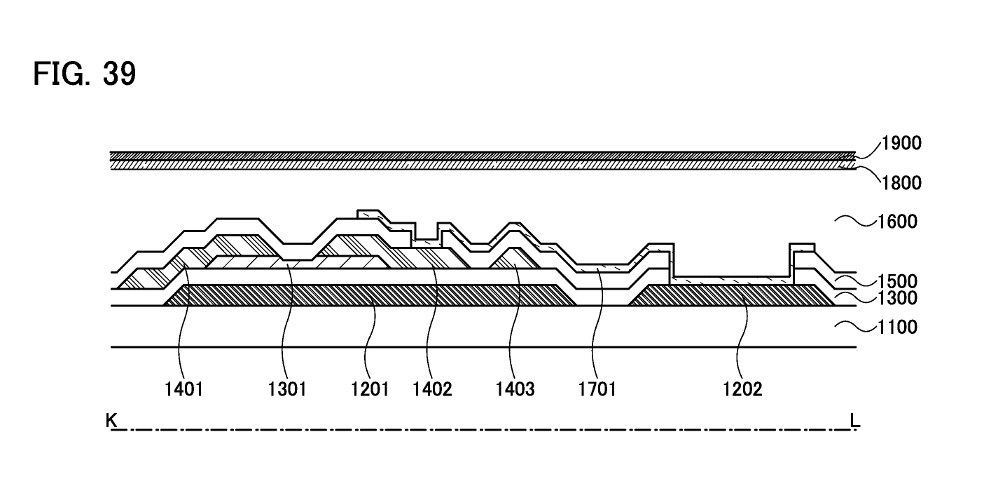

FIG. 39 illustrates an example of a cross-sectional view taken along the line K-L in FIG. 38.

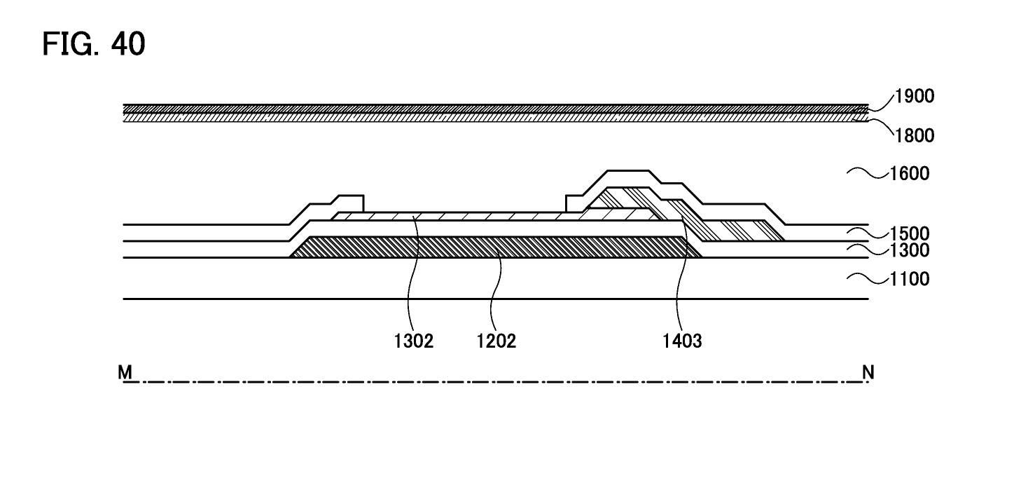

FIG. 40 illustrates an example of a cross-sectional view taken along the line M-N in FIG. 38.

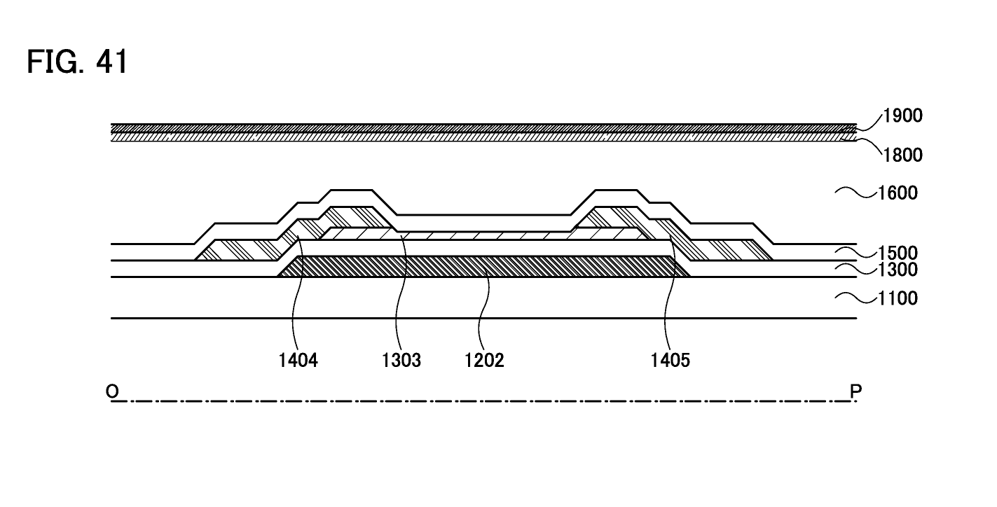

FIG. 41 illustrates an example of a cross-sectional view taken along the line O-P in FIG. 38.

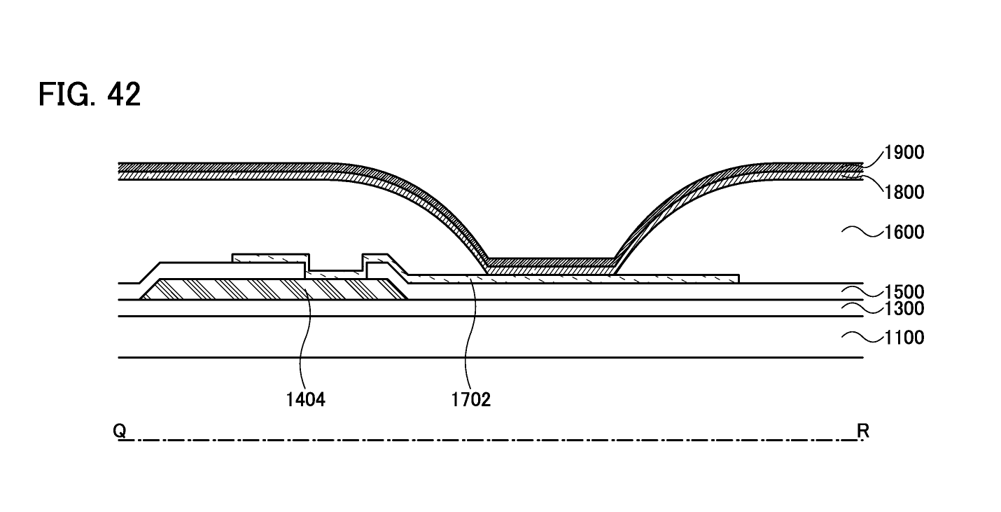

FIG. 42 illustrates an example of a cross-sectional view taken along the line Q-R in FIG. 38.

A conductive layer 1201 is provided over a substrate 1100.

A conductive layer 1202 is provided over the substrate 1100.

An insulating layer 1300 is provided over the conductive layer 1201 and the conductive layer 1202.

An oxide semiconductor layer 1301 is provided over the insulating layer 1300.

An oxide semiconductor layer 1302 is provided over the insulating layer 1300.

An oxide semiconductor layer 1303 is provided over the insulating layer 1300.

A conductive layer 1401 is provided over the oxide semiconductor layer 1301.

A conductive layer 1402 is provided over the oxide semiconductor layer 1301.

A conductive layer 1403 is provided over the oxide semiconductor layer 1302.

A conductive layer 1404 is provided over the oxide semiconductor layer 1303.

A conductive layer 1405 is provided over the oxide semiconductor layer 1303.

An inorganic insulating layer 1500 is provided over the conductive layer 1401, the conductive layer 1402, the conductive layer 1403, the conductive layer 1404, and the conductive layer 1405.

A conductive layer 1701 is provided over the inorganic insulating layer 1500.

A conductive layer 1702 is provided over the inorganic insulating layer 1500.

A resin layer 1600 is provided over the conductive layer 1701 and the conductive layer 1702.

A layer 1800 containing an organic compound is provided over the conductive layer 1702 and the resin layer 1600.

A conductive layer 1900 is provided over the layer 1800 containing an organic compound.

The conductive layer 1701 is electrically connected to the conductive layer 1402 through a contact hole of the inorganic insulating layer 1500.

The conductive layer 1701 is electrically connected to the conductive layer 1202 through a contact hole of the inorganic insulating layer 1500 and a contact hole of the insulating layer 1300.

The conductive layer 1702 is electrically connected to the conductive layer 1404 through a contact hole of the inorganic insulating layer 1500.

The resin layer 1600 includes a portion being in contact with the oxide semiconductor layer 1302 in the inside of a hole of the inorganic insulating layer 1500.

The oxide semiconductor layer 1301 and the oxide semiconductor layer 1303 are covered with the inorganic insulating layer 1500. Hence, the resin layer 1600 is not in contact with the oxide semiconductor layer 1301 and the oxide semiconductor layer 1303.

FIG. 43 illustrates an example of a circuit diagram of a light-emitting device (an EL display device as one kind of semiconductor devices).

The wiring S is electrically connected to one of a source and a drain of the transistor Tr1.

The wiring G is electrically connected to a gate of the transistor Tr1.

A wiring V1 is electrically connected to one of a source and a drain of the transistor Tr2.

A wiring V2 is electrically connected to one electrode of the capacitor C.

The other of the source and the drain of the transistor Tr1 is electrically connected to a gate of the transistor Tr2.

The other of the source and the drain of the transistor Tr 1 is electrically connected to the other electrode of the capacitor C.

The other of the source and the drain of the transistor Tr2 is electrically connected to one electrode of a light-emitting element EL.

The relations between each of FIGS. 38 to 42 and FIG. 43 are described.

At least a part of the conductive layer 1201 can function as a gate electrode of a transistor Tr1, for example.

At least a part of the conductive layer 1201 can function as the wiring G, for example.

At least a part of the conductive layer 1202 can function as a gate electrode of a transistor Tr2, for example.

At least a part of the conductive layer 1202 can function as the other electrode of the capacitor C, for example.

At least a part of the insulating layer 1300 can function as a gate insulating film of the transistor Tr1, for example.

At least a part of the insulating layer 1300 can function as a gate insulating film of the transistor Tr2, for example.

At least a part of the insulating layer 1300 can function as an insulating film (a dielectric film) of the capacitor C, for example.

At least a part of the oxide semiconductor layer 1301 can function as an active layer of the transistor Tr1, for example.

At least a part of the oxide semiconductor layer 1302 can function as one electrode of the capacitor C, for example.

At least a part of the oxide semiconductor layer 1303 can function as an active layer of the transistor Tr2, for example.

At least a part of the conductive layer 1401 can function as one of a source electrode and a drain electrode of the transistor Tr1, for example.

At least a part of the conductive layer 1401 can function as the wiring S, for example.

At least a part of the conductive layer 1402 can function as the other of the source electrode and the drain electrode of the transistor Tr1, for example.

At least a part of the conductive layer 1403 can function as the wiring V2, for example.

At least a part of the conductive layer 1404 can function as the other of a source electrode and a drain electrode of the transistor Tr2, for example.

At least a part of the conductive layer 1405 can function as one of the source electrode and the drain electrode of the transistor Tr2, for example.

At least a part of the conductive layer 1405 can function as a wiring V1, for example.

At least a part of the conductive layer 1701 can function as a wiring for electrically connecting the other of the source electrode and the drain electrode of the transistor Tr1 to the gate electrode of the transistor Tr2, for example.

At least a part of the conductive layer 1701 can function as a wiring for electrically connecting the other of the source electrode and the drain electrode of the transistor Tr1 to the other electrode of the capacitor C, for example.

At least a part of the conductive layer 1702 can function as one electrode of a light-emitting element EL, for example.

At least a part of the layer 1800 containing an organic compound can function as a functional layer of the light-emitting element EL, for example.

At least a part of the conductive layer 1900 can function as the other electrode of the light-emitting element EL, for example.

Further, the resin layer 1600 includes the portion being in contact with the oxide semiconductor layer 1302 in the inside of the hole of the inorganic insulating layer 1500, which makes it possible to contain H₂O in the oxide semiconductor layer 1302.

Note that although the example of the light-emitting device is illustrated in this embodiment, a semiconductor device except the light-emitting device can be fabricated with the use of a functional layer except the layer containing an organic compound.

At least part of the structure described in this embodiment can be combined with at least part of a structure described in any of the other embodiments.

### Embodiment 17

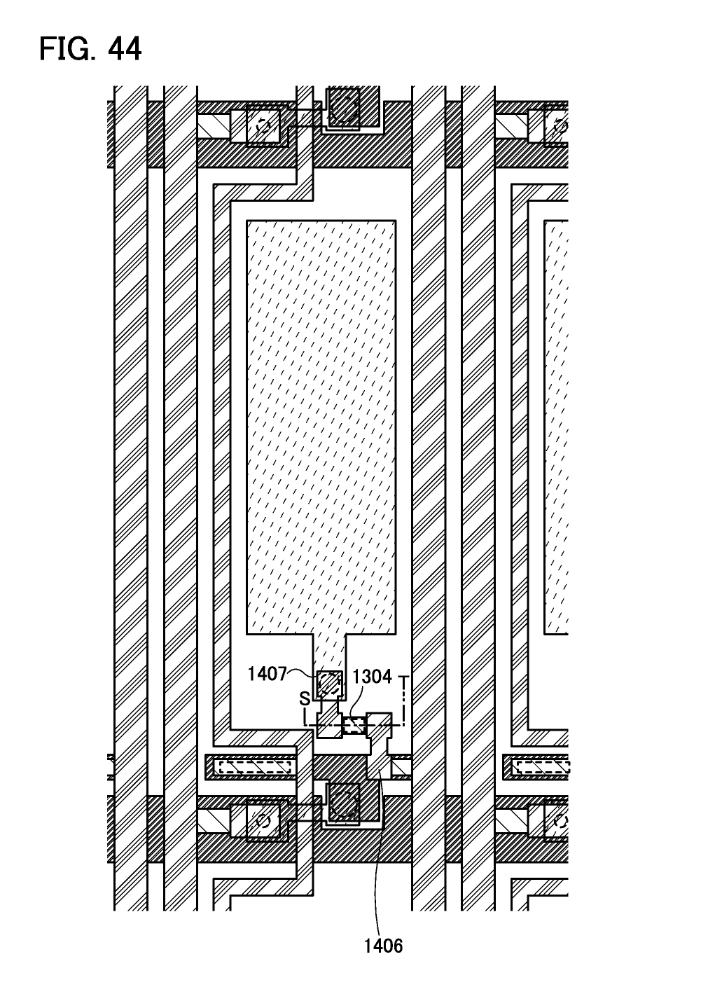

FIG. 44 illustrates an example of a drawing which is different from FIG. 38 in that a conductive layer 1406, an oxide semiconductor layer 1304, and a conductive layer 1407 are provided instead of the conductive layer 1404.

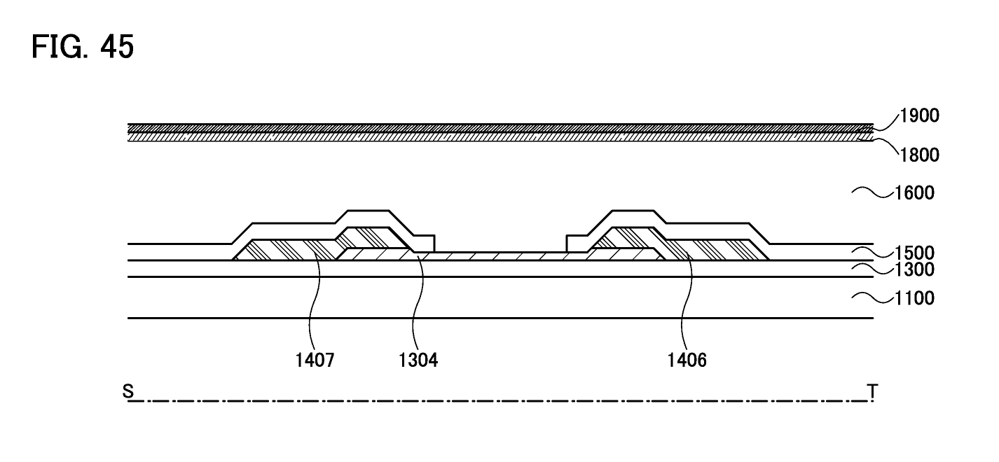

FIG. 45 illustrates an example of a cross-sectional view taken along the line S-T in FIG. 44.

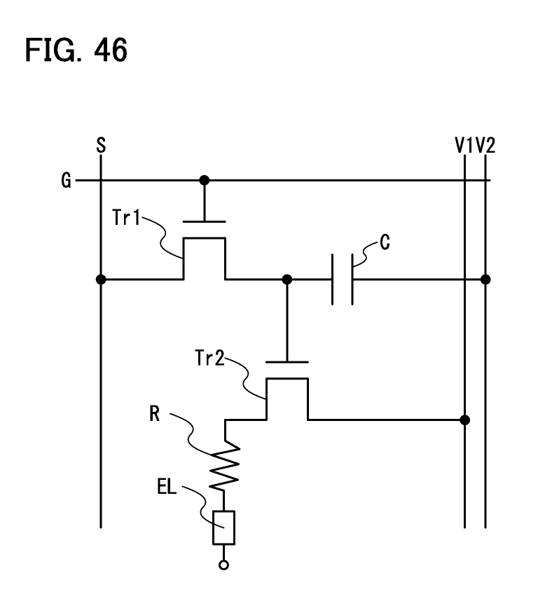

FIG. 46 illustrates an example of a circuit diagram which is different from FIG. 43 in that a resistor R is provided.

One terminal of the resistor R is electrically connected to the other of the source and the drain of the transistor Tr2.

The other terminal of the resistor R is electrically connected to one electrode of the light-emitting element EL.

The relations between a component in each of FIGS. 44 and 45 and the resistor R in FIG. 46 are described.

At least a part of the oxide semiconductor layer 1304 can function as a resistive element of a resistor R, for example.

At least a part of the conductive layer 1406 can function as one terminal of the resistor R.

At least a part of the conductive layer 1407 can function as the other terminal of the resistor R.

Here, the oxide semiconductor layer 1304 is provided over the insulating layer 1300.

The conductive layer 1406 is provided over the oxide semiconductor layer 1304.

The conductive layer 1407 is provided over the oxide semiconductor layer 1304.

The inorganic insulating layer 1500 is provided over the conductive layer 1406 and the conductive layer 1407.

Since the resin layer 1600 includes the portion being in contact with the oxide semiconductor layer 1304 in the inside of the hole of the inorganic insulating layer 1500, H₂O can be contained in the resistive element of the resistor R.

It is preferable that the resistance of the resistor R be sufficiently higher than the resistance of the transistor Tr2 in an on state.

The resistance of the resistor R which is sufficiently higher than the resistance of the transistor Tr2 in an on state allows the amount of current flowing in the light-emitting element to be determined.

However, if the resistivity of the resistor R is too high, the luminance of the light-emitting element is lowered too much in some cases.

Further, the resistivity of the oxide semiconductor layer is much higher than the resistivity of an oxide semiconductor layer containing silicon.

Thus, H₂O is contained in the resistor R, whereby the resistivity of the resistor can be lowered.

Note that although the example of the light-emitting device is illustrated in this embodiment, a semiconductor device except the light-emitting device can be fabricated with the use of a functional layer except the layer containing an organic compound.

At least part of the structure described in this embodiment can be combined with at least part of a structure described in any of the other embodiments.

### Embodiment 18

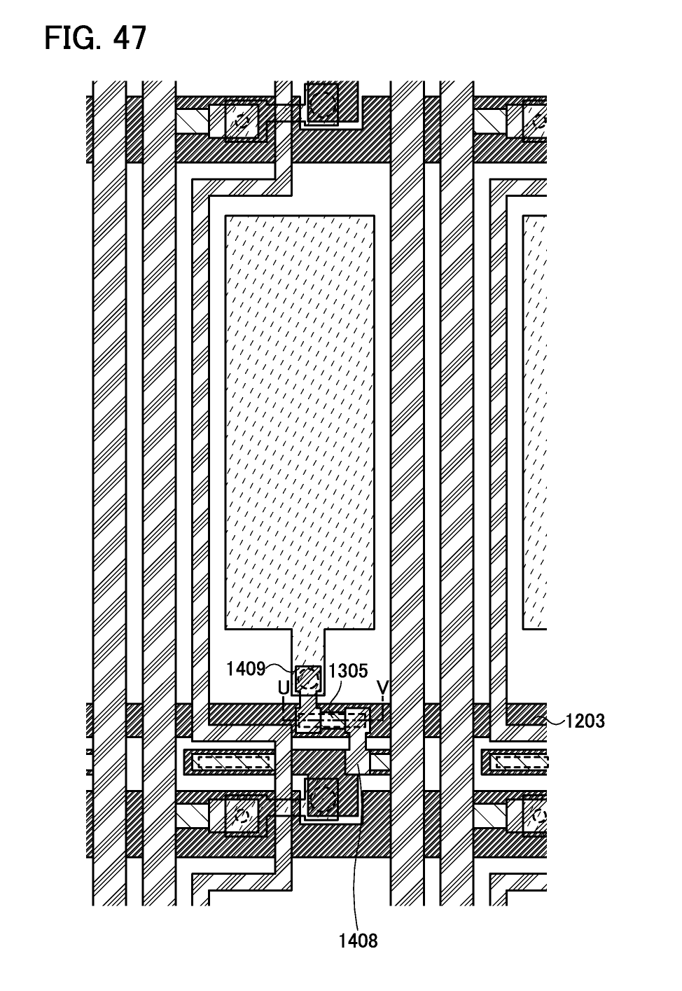

FIG. 47 illustrates an example of a drawing which is different from FIG. 38 in that a transistor is provided instead of the conductive layer 1404.

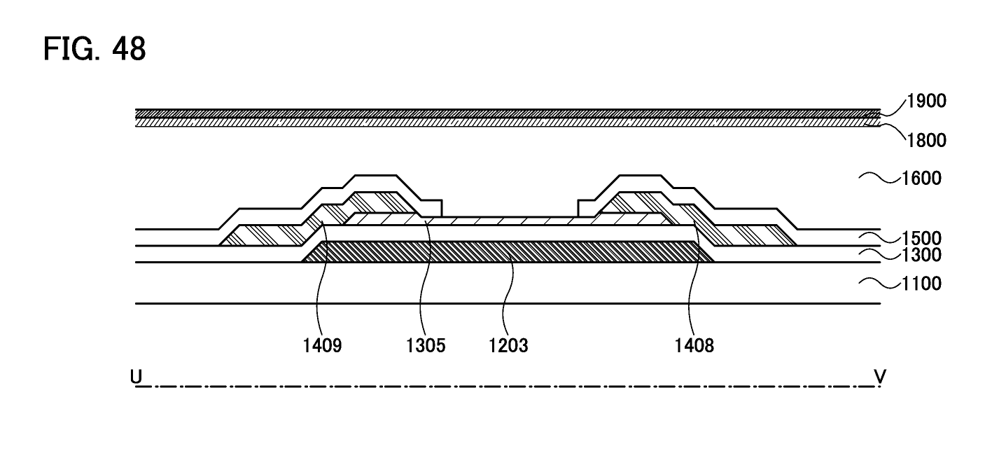

FIG. 48 illustrates an example of a cross-sectional view taken along the line U-V in FIG. 47.

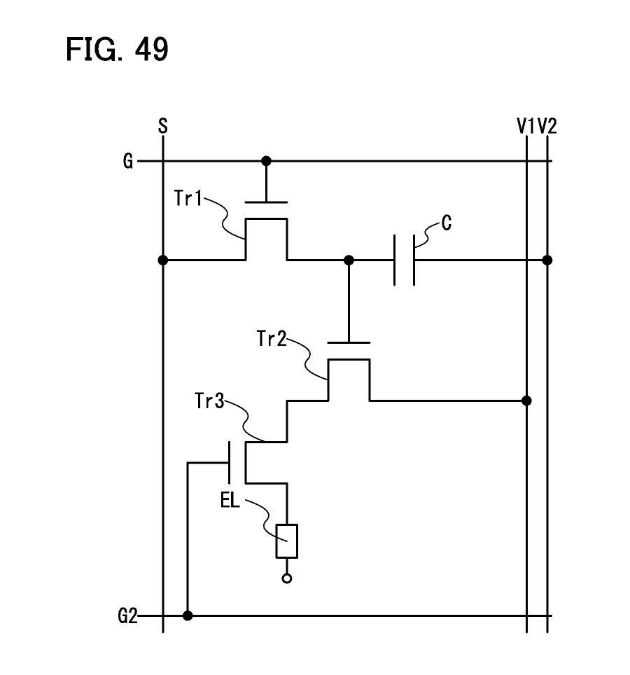

FIG. 49 illustrates an example of a circuit diagram which is different from FIG. 43 in that a transistor Tr3 and the wiring G2 are provided.

One of a source and a drain of the transistor Tr3 is electrically connected to the other of the source and the drain of the transistor Tr2.

The other of the source and the drain of the transistor Tr3 is electrically connected to one electrode of the light-emitting element EL.

A gate of the transistor Tr3 is electrically connected to the wiring G2.

The relations between a component in each of FIGS. 47 and 48 and the transistor Tr3 in FIG. 49 are described.

At least a part of the conductive layer 1203 can function as a gate electrode of a transistor Tr3, for example.

At least a part of the conductive layer 1203 can function as the wiring G2, for example.

At least a part of the insulating layer 1300 can function as a gate insulating film of the transistor Tr3, for example.

At least a part of the oxide semiconductor layer 1305 can function as an active layer of the transistor Tr3, for example.

At least a part of the conductive layer 1408 can function as one of a source electrode and a drain electrode of the transistor Tr3, for example.

At least a part of the conductive layer 1409 can function as the other of the source electrode and the drain electrode of the transistor Tr3, for example.

Here, the conductive layer 1203 is provided over the substrate 1100.

The insulating layer 1300 is provided over the conductive layer 1203.

The oxide semiconductor layer 1305 is provided over the insulating layer 1300.

The conductive layer 1408 is provided over the oxide semiconductor layer 1305.

The conductive layer 1409 is provided over the oxide semiconductor layer 1305.

The inorganic insulating layer 1500 is provided over the conductive layer 1408 and the conductive layer 1409.

Since the resin layer 1600 includes the portion being in contact with the oxide semiconductor layer 1305 in the inside of the hole of the inorganic insulating layer 1500, H₂O can be contained in the active layer of the transistor Tr3.

By thus containing H₂O in the active layer of the transistor Tr3, the transistor Tr3 can be normally on.

Since the active layer of the transistor Tr1 and the active layer of the transistor Tr2 are not in contact with the resin layer 1600, the transistor Tr1 and the transistor Tr2 can be normally off.

The technical significance of the transistor Tr3 is described.

The transistor Tr3 has a function which can operate in a saturation region.

The transistor Tr2 has a function which can operate in a linear region.

In the case where the transistor Tr2 operates in a linear region and the transistor Tr3 operates in a saturation region, the value of current which flows in the light-emitting element EL can be determined on the basis of the relation between the transistor Tr3 and the light-emitting element EL.

Further, in the case where the transistor Tr3 is normally on, voltage to be applied to the gate of the transistor Tr3 can be reduced when the transistor Tr3 operates in a saturation region.

An object is to reduce voltage to be applied to the gate of the transistor Tr3 when the transistor Tr3 operates in a saturation region. Hence, it is sufficient that the threshold voltage of the transistor Tr3 is lower than the threshold voltage of the transistor Tr2.

Hence, the transistor Tr3 may be normally off.

Note that although the example of the light-emitting device is illustrated in this embodiment, a semiconductor device except the light-emitting device can be fabricated with the use of a functional layer except the layer containing an organic compound

At least part of the structure described in this embodiment can be combined with at least part of a structure described in any of the other embodiments.

### Embodiment 19

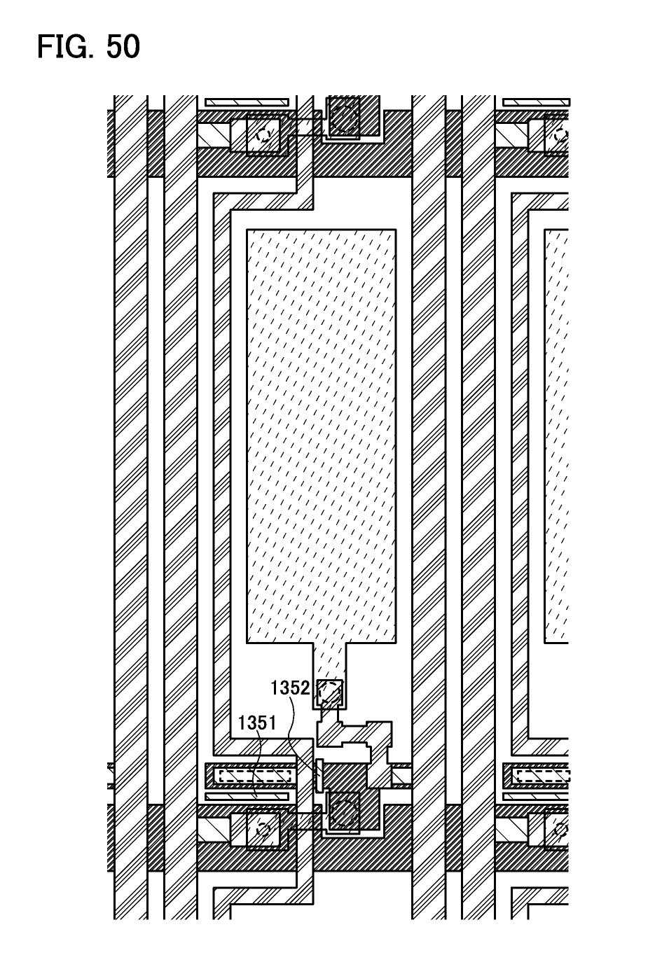

FIG. 50 illustrates an example of a drawing which is different from FIG. 38 in that an oxide semiconductor layer 1351, an oxide semiconductor layer 1352, and the like are provided.

The oxide semiconductor layer which is not in contact with the resin layer is provided between the oxide semiconductor layer capable of functioning as one electrode of the capacitor and the oxide semiconductor layer capable of functioning as the active layer of the transistor. Thus, it is possible to reduce the amount of H₂O reaching the oxide semiconductor layer capable of functioning as the active layer of the transistor.

At least part of the structure described in this embodiment can be combined with at least part of a structure described in any of the other embodiments.

### Embodiment 20

Any circuit can be used for a pixel circuit of the light-emitting device.

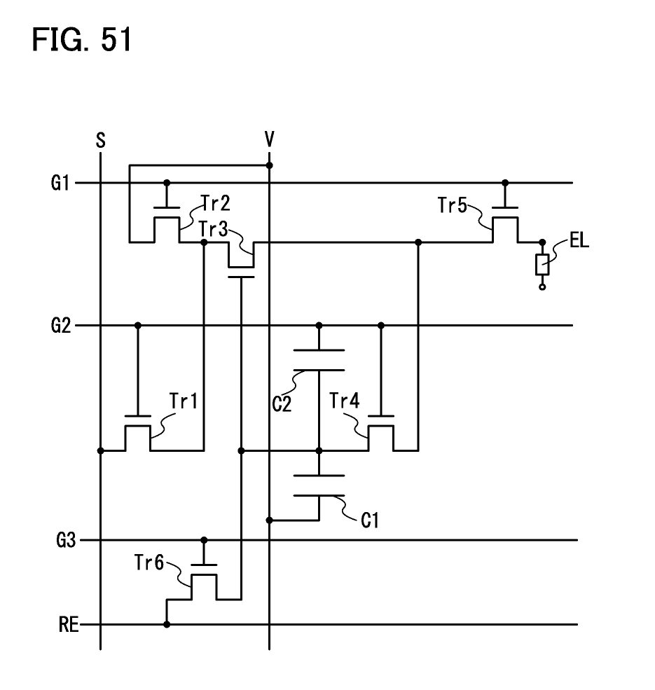

FIG. 51 illustrates an example of the pixel circuit of the light-emitting device.

The pixel circuit of the light-emitting device illustrated in FIG. 51 includes the transistor Tr1, the transistor Tr2, the transistor Tr3, a transistor Tr4, a transistor Tr5, a transistor Tr6, the wiring S, the wiring G1, the wiring G2, a wiring G3, a wiring RE, a wiring V, the capacitor C1, the capacitor C2, and the light-emitting element EL.

The wiring S is electrically connected to one of the source and the drain of the transistor Tr1.

The wiring G1 is electrically connected to the gate of the transistor Tr2.

The wiring G1 is electrically connected to a gate of the transistor Tr5.

The wiring G2 is electrically connected to the gate of the transistor Tr1.

The wiring G2 is electrically connected to a gate of the transistor Tr4.

The wiring G2 is electrically connected to one electrode of the capacitor C2.

The wiring G3 is electrically connected to a gate of the transistor Tr6.

The wiring RE is electrically connected to one of a source and a drain of the transistor Tr6.

The wiring V is electrically connected to one of the source and the drain of the transistor Tr2.

The wiring V is electrically connected to one electrode of the capacitor C1.

The light-emitting element EL is electrically connected to one of a source and a drain of the transistor Tr5.

The other electrode of the capacitor C 1 is electrically connected to the other of the source and the drain of the transistor Tr6.

The other electrode of the capacitor C1 is electrically connected to the gate of the transistor Tr3.

The other electrode of the capacitor C 1 is electrically connected to one of a source and a drain of the transistor Tr4.

The other electrode of the capacitor C 1 is electrically connected to the other electrode of the capacitor C2.

The other of the source and the drain of the transistor Tr1 is electrically connected to the other of the source and the drain of the transistor Tr2.

The other of the source and the drain of the transistor Tr1 is electrically connected to one of the source and the drain of the transistor Tr3.

The other of the source and the drain of the transistor Tr3 is electrically connected to the other of the source and the drain of the transistor Tr4.

The other of the source and the drain of the transistor Tr3 is electrically connected to the other of the source and the drain of the transistor Tr5.

The operation of the circuit of FIG. 51 is described.

In a first period (reset period), the wiring G3 is selected and the transistor Tr6 is turned on, so that the pixel circuit is reset.

Note that the wiring G1 and the wiring G2 are not selected in the first period.

In the second period (write period), the wiring G2 is selected and the transistor Tr1 and the transistor Tr4 are turned on, so that a video signal is written from the wiring S.

Note that the wiring G1 and the wiring G3 are not selected in the second period.

In the third period (display period), the wiring G1 is selected and current is supplied from the wiring V to the light-emitting element EL via the transistor Tr2, the transistor Tr3, and the transistor Tr5.

Note that the wiring G2 and the wiring G3 are not selected in the second period.

In other words, operation of sequentially selecting the wiring G3, the wiring G2, and the wiring G1 is repeated.

For example, one electrode or the other electrode of the capacitor C1 of FIG. 51 can be the oxide semiconductor layer being in contact with the resin layer.

For example, one electrode or the other electrode of the capacitor C2 of FIG. 51 can be the oxide semiconductor layer being in contact with the resin layer.

For example, an active layer of the transistor Tr5 in FIG. 51 can be the oxide semiconductor layer being in contact with the resin layer.

In the case where the active layer of the transistor Tr5 of FIG. 51 is in contact with the resin layer, it is preferable that the active layer of the transistor Tr1, the active layer of the transistor Tr2, the active layer of the transistor Tr3, an active layer of the transistor Tr4, and an active layer of the transistor Tr6 be not in contact with the resin layer.

Note that although the example of the light-emitting device is illustrated in this embodiment, a semiconductor device except the light-emitting device can be fabricated with the use of a functional layer except the layer containing an organic compound

At least part of the structure described in this embodiment can be combined with at least part of a structure described in any of the other embodiments.

### Embodiment 21

Any circuit can be used for the pixel circuit of the light-emitting device.

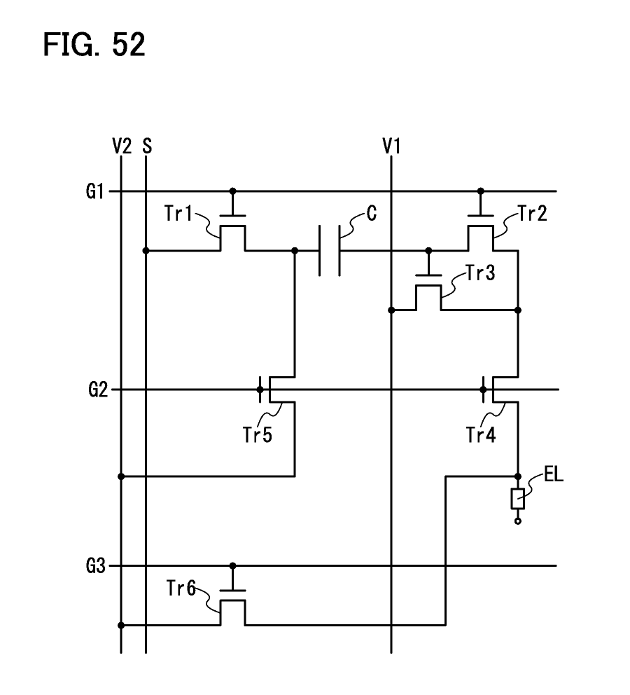

FIG. 52 illustrates an example of the pixel circuit of the light-emitting device.

The pixel circuit of the light-emitting device illustrated in FIG. 52 includes the transistors Tr1 to Tr6, the wiring S, the wirings G1 to G3, the wirings V1 and V2, the capacitor C, and the light-emitting element EL.

The wiring S is electrically connected to one of the source and the drain of the transistor Tr1.

The wiring G1 is electrically connected to the gate of the transistor Tr1.

The wiring G1 is electrically connected to the gate of the transistor Tr2.

The wiring G2 is electrically connected to the gate of the transistor Tr4.

The wiring G2 is electrically connected to the gate of the transistor Tr5.

The wiring G3 is electrically connected to the gate of the transistor Tr6.

The wiring V1 is electrically connected to one of the source and the drain of the transistor Tr3.

The wiring V2 is electrically connected to one of the source and the drain of the transistor Tr5.

The wiring V2 is electrically connected to one of the source and the drain of the transistor Tr6.

The light-emitting element EL is electrically connected to one of the source and the drain of the transistor Tr4.

The light-emitting element EL is electrically connected to the other of the source and the drain of the transistor Tr6.

The other of the source and the drain of the transistor Tr1 is electrically connected to the other of the source and the drain of the transistor Tr5.

The other of the source and the drain of the transistor Tr1 is electrically connected to one electrode of the capacitor C.

One of the source and the drain of the transistor Tr2 is electrically connected to the gate of the transistor Tr3.

One of the source and the drain of the transistor Tr2 is electrically connected to the other electrode of the capacitor C.

The other of the source and the drain of the transistor Tr2 is electrically connected to the other of the source and the drain of the transistor Tr3.

The other of the source and the drain of the transistor Tr2 is electrically connected to the other of the source and the drain of the transistor Tr4.

The operation of the circuit of FIG. 52 is described.

In the first period, the wiring G1 and the wiring G3 are selected and the transistor Tr1, the transistor Tr2, and the transistor Tr6 are turned on.

Note that the wiring G2 is not selected in the first period.

In the second period, the wiring G2 is selected and the transistor Tr4 and the transistor Tr5 are turned on, so that display is performed.

Note that the wiring G1 and the wiring G3 are not selected in the second period.

It is preferable that the wiring G1 and the wiring G3 be electrically connected to each other.

It is preferable that an input terminal of an inverter be electrically connected to the wiring G1 or the wiring G3 and an output terminal of the inverter be electrically connected to the wiring G2.

It is also preferable that the input terminal of the inverter be electrically connected to the wiring G2 and the output terminal of the inverter be electrically connected to the wiring G1 or the wiring G3.

There is no limitation on the kind of the inverter.

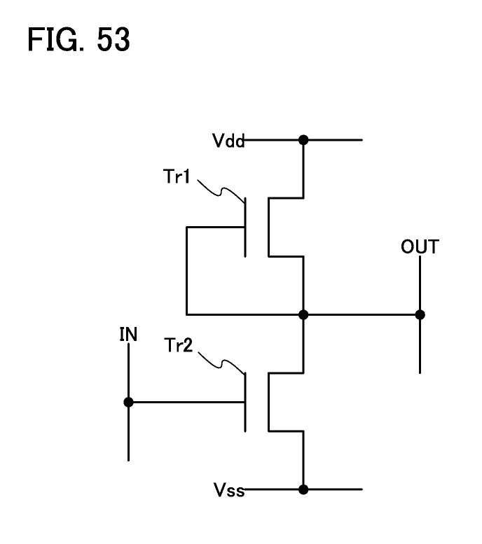

The inverter may have a configuration of FIG. 53.

For example, one electrode or the other electrode of the capacitor C1 of FIG. 52 can be the oxide semiconductor layer being in contact with the resin layer

For example, the active layer of the transistor Tr4 in FIG. 52 can be the oxide semiconductor layer being in contact with the resin layer.

In the case where the active layer of the transistor Tr4 of FIG. 52 is in contact with the resin layer, it is preferable that the active layer of the transistor Tr1, the active layer of the transistor Tr2, the active layer of the transistor Tr3, the active layer of the transistor Tr5, and the active layer of the transistor Tr6 be not in contact with the resin layer.

Note that although the example of the light-emitting device is illustrated in this embodiment, a semiconductor device except the light-emitting device can be fabricated with the use of a functional layer except the layer containing an organic compound.

At least part of the structure described in this embodiment can be combined with at least part of a structure described in any of the other embodiments.

### Embodiment 22

The disclosed invention can also be used for a circuit except the pixel circuit.

FIG. 53 illustrates an example of the inverter.

A circuit of FIG. 53 includes the transistor Tr1, the transistor Tr2, a wiring IN, a wiring OUT, a wiring Vdd, and a wiring Vss.

The wiring IN has a function which can serve as an input terminal.

The wiring OUT has a function which can serve as an output terminal.

The wiring Vdd has a function which can supply first voltage.

The wiring Vss has a function which can supply second voltage.

The transistor Tr1 is preferably an n-channel transistor.

The transistor Tr2 is preferably an n-channel transistor.

The first voltage is preferably higher than the second voltage.

The first voltage is preferably set to Vdd (voltage higher than a reference voltage).

The second voltage is preferably set to Vss (voltage lower than a reference voltage).

One of the source and the drain of the transistor Tr1 is electrically connected to the wiring Vdd.

The other of the source and the drain of the transistor Tr1 is electrically connected to the wiring OUT.

The gate of the transistor Tr1 is electrically connected to the other of the source and the drain of the transistor Tr1.

One of the source and the drain of the transistor Tr2 is electrically connected to the wiring OUT

The other of the source and the drain of the transistor Tr2 is electrically connected to the wiring Vss.

The gate of the transistor Tr2 is electrically connected to the wiring IN.

The operation of FIG. 53 is described.

Third voltage at which the transistor Tr2 can be turned on is input to the wiring IN, whereby the second voltage (e.g., Vss) is output from the wiring OUT.

Fourth voltage at which the transistor Tr2 can be turned off is input to the wiring IN, whereby the first voltage (e.g., Vdd) is output from the wiring OUT.

In FIG. 53, it is preferable that the threshold voltage of the transistor Tr1 be lower than the threshold voltage of the transistor Tr2.

In FIG. 53, it is further preferable that the transistor Tr1 be normally on and the transistor Tr2 be normally off.

The active layer of the transistor Tr1 is preferably in contact with the resin layer.

The active layer of the transistor Tr2 is preferably not in contact with the resin layer.

At least part of the structure described in this embodiment can be combined with at least part of a structure described in any of the other embodiments.

### Embodiment 23

As the transistor, either a bottom-gate transistor or a top-gate transistor may be used.

In the case of a bottom-gate transistor, the source electrode and the drain electrode may be provided over the active layer, or the source electrode and the drain electrode may be provided under the active layer.

The transistor includes at least the conductive layer (the gate electrode), the insulating layer (the gate insulating film), and the semiconductor layer (the active layer). The source electrode and the drain electrode may be regarded as components of the transistor.

At least part of the structure described in this embodiment can be combined with at least part of a structure described in any of the other embodiments.

### Embodiment 24

Materials of the layers are described.

A glass substrate, a quartz substrate, a metal substrate, a semiconductor substrate, a resin substrate (a plastic substrate), or the like can be used for the substrate, but the substrate is not limited to these examples.

The substrate may have flexibility.

A glass substrate becomes flexible by being thinned

A resin substrate has flexibility.

A base insulating film may be formed over the substrate.

The insulating layer can be formed using any material having an insulating property.

The insulating layers may have either a single layer structure or a layered structure.

Examples of the insulating layer include an inorganic insulating layer and a resin layer, but the insulating layer is not limited to these examples.

Examples of the inorganic insulating layer include a film containing silicon oxide, a film containing silicon nitride, a film containing aluminum nitride, a film containing aluminum oxide, and a film containing hafnium oxide, but the inorganic insulating layer is not limited to these examples.

The inorganic insulating layer may have a single layer structure or a layered structure.

A material of the resin layer is not limited as long as the resin layer is a film containing resin.

Examples of the resin include polyimide, acrylic, siloxane, and epoxy, but the resin is not limited to these examples.

The resin layer may have a function as an adhesive.

Examples of the resin layer having a function as an adhesive include a sealant.

It is preferable to use a method for forming the resin layer using a liquid material because a large amount of H₂O is made to be contained in the resin layer.

A printing method, a spin coating method, and the like are given as examples of the method for forming the resin layer using a liquid material, but the method is not limited to these examples.

The resin layer may have a single layer structure or a layered structure.

An inorganic insulating layer is preferably used as an insulating layer capable of functioning as the gate insulating film.

A conductive layer can be formed using any material having a conductive property.

A film containing metal, a film containing a transparent conductor, and the like are given as examples of the conductive layer, but the conductive layer is not limited to these examples.

Examples of the metal include aluminum, titanium, molybdenum, tungsten, chromium, gold, silver, copper, alkali metal, and alkaline earth metal, but the metal is not limited to these examples.

Examples of the transparent conductor include indium tin oxide and indium zinc oxide, but the transparent conductor is not limited to these examples.

The conductive layer may have a single-layer structure or a layered structure.

A material of the oxide semiconductor layer is not limited as long as the oxide semiconductor layer is a film containing metal and oxygen.

For example, a film containing indium and oxygen, a film containing zinc and oxygen, a film containing tin and oxygen, or the like can function as the oxide semiconductor layer.

Examples of the oxide semiconductor layer include an indium oxide film, a tin oxide film, and a zinc oxide film, but the oxide semiconductor layer is not limited to these examples.

For example, as the oxide semiconductor layer, an In—Zn-based oxide film, a Sn—Zn-based oxide film, an Al—Zn-based oxide film, a Zn—Mg-based oxide film, a Sn—Mg-based oxide film, an In—Mg-based oxide film, and an In—Ga-based oxide film are given, but the oxide semiconductor layer is not limited to these examples.

The term “A-B-based oxide film” (A and B are elements) means a film containing A, B, and oxygen.

For example, as the oxide semiconductor layer, an In—Ga—Zn-based oxide film, an In—Sn—Zn-based oxide film, a Sn—Ga—Zn-based oxide film, an In—Al—Zn-based oxide film, an In—Hf—Zn-based oxide film, an In—La—Zn-based oxide film, an In—Ce—Zn-based oxide film, an In—Pr—Zn-based oxide film, an In—Nd—Zn-based oxide film, an In—Sm—Zn-based oxide film, an In—Eu—Zn-based oxide film, an In—Gd—Zn-based oxide film, an In—Tb—Zn-based oxide film, an In—Dy—Zn-based oxide film, an In—Ho—Zn-based oxide film, an In—Er—Zn-based oxide film, an In—Tm—Zn-based oxide film, an In—Yb—Zn-based oxide film, an In—Lu—Zn-based oxide film, an Al—Ga—Zn-based oxide film, a Sn—Al—Zn-based oxide film, and the like are given, but the oxide semiconductor layer is not limited to these examples.

The term “A-B-C-based oxide film” (A, B, and C are elements) means a film containing A, B, C, and oxygen.

For example, as the oxide semiconductor layer, an In—Sn—Ga—Zn-based oxide film, an In—Hf—Ga—Zn-based oxide film, an In—Al—Ga—Zn-based oxide film, an In—Sn—Al—Zn-based oxide film, an In—Sn—Hf—Zn-based oxide film, an In—Hf—Al—Zn-based oxide film, and the like are given, but the oxide semiconductor layer is not limited to these examples.

The term “A-B-C-D-based oxide film” (A, B, C, and D are elements) means a film containing A, B, C, D, and oxygen.

As the oxide semiconductor layer, a film containing indium, gallium, zinc, and oxygen is particularly preferable.

The oxide semiconductor layer preferably has a crystal.

The crystal is preferably aligned so that the direction of its c-axis is perpendicular to a surface of the oxide semiconductor layer or the substrate.

The crystal whose c-axis is aligned to be perpendicular to the surface of the oxide semiconductor layer or the substrate is referred to as a c-axis aligned crystal (CAAC).

An angle between the c-axis of the crystal and the surface of the oxide semiconductor layer or the substrate is preferably 90°, but it may be greater than or equal to 80° and less than or equal to 100°.

As an example of a method for forming the CAAC, there is a first method in which a substrate temperature at the time of forming the oxide semiconductor layer by a sputtering method is set to higher than or equal to 200° C. and lower than or equal to 450° C.

In the first method, the CAAC is formed in the lower portion and the upper portion of the oxide semiconductor layer.

As another example of the method for forming the CAAC, there is a second method in which, after the oxide semiconductor layer is formed, the oxide semiconductor layer is subjected to heat treatment at higher than or equal to 650° C. for 3 minutes or longer.

In the second method, the CAAC is formed at least in the upper portion of the oxide semiconductor layer (a pattern A of the second method).

In the second method, the oxide semiconductor layer having a small thickness is used; thus, the CAAC can be formed in the lower portion and the upper portion of the oxide semiconductor layer (a pattern B of the second method).

As another example of the method for forming the CAAC, there is a third method in which a second oxide semiconductor layer is formed over a first oxide semiconductor layer that is formed using the pattern B of the second method.

The method for forming the oxide semiconductor layer in the second method and the third method is not limited to a sputtering method.

The first to the third methods enables a crystal to be formed, and an angle which the c-axis of the crystal forms with the surface of the oxide semiconductor layer or the substrate is greater than or equal to 80° and less than or equal to 100°.

By the first to the third methods, it is possible to form the CAAC at least in the upper portion (the surface) of the oxide semiconductor layer.

Since the oxide semiconductor layer including the CAAC is dense, H₂O, H, or the like can be blocked.

Thus, the surface of the oxide semiconductor layer being in contact with the resin layer preferably has an amorphous part.

In the case where an oxide semiconductor layer in which the CAAC is formed is used as the oxide semiconductor layer, at least a part of the surface of the oxide semiconductor layer being in contact with the resin layer can be made amorphous by performing plasma treatment on the surface of the oxide semiconductor layer being in contact with the resin layer.

Plasma treatment is preferably not performed on the oxide semiconductor layer which is not in contact with the resin layer so that H₂O is not contained in the oxide semiconductor layer which is not in contact with the resin layer.

As the plasma treatment, hydrogen plasma treatment, rare gas plasma treatment, halogen plasma treatment, and the like are given as examples, but the plasma treatment is not limited to these examples.

The first oxide semiconductor layer (the oxide semiconductor layer which is not in contact with the resin layer, the layer containing hydrogen, or the like) and the second oxide semiconductor layer (the oxide semiconductor layer which is in contact with the resin layer, the layer containing hydrogen, or the like) preferably have different crystal states.

For example, the second oxide semiconductor layer is made to have a crystal state such that entry of H₂O or H into the second oxide semiconductor layer is easier than entry of H₂O or H into the first oxide semiconductor layer, whereby the second oxide semiconductor layer can have lower resistivity than the first oxide semiconductor layer.

For example, a non-single-crystal oxide semiconductor layer such as an amorphous oxide semiconductor layer, a microcrystalline oxide semiconductor layer, or a polycrystalline oxide semiconductor layer is used for the second oxide semiconductor layer, and an oxide semiconductor layer including the CAAC is used for the first oxide semiconductor layer. Thus, the second oxide semiconductor layer can have a crystal state such that entry of H₂O or H into the second oxide semiconductor layer is easier than entry of H₂O or H into the first oxide semiconductor layer.

Examples of the microcrystal include a nanocrystal and a microcrystal.

For example, the second oxide semiconductor layer has higher crystallinity than the first oxide semiconductor layer, in which case the second oxide semiconductor layer can have lower resistivity than the first oxide semiconductor layer.

Particularly in the case where the first oxide semiconductor layer is the oxide semiconductor layer including the CAAC, the second oxide semiconductor layer can be a single crystal oxide semiconductor layer.

Note that a third oxide semiconductor layer (an oxide semiconductor layer for absorbing H₂O) preferably has a crystal state such that entry of H₂O or H into the third oxide semiconductor layer is easier than entry of H₂O or H into the first oxide semiconductor layer.

The crystal state of the first oxide semiconductor layer, the crystal state of the second oxide semiconductor layer, and the crystal state of the third oxide semiconductor layer may be different from one another.

Note that a difference in crystal states can be observed by electron diffraction or the like.

For example, it can be said that different electron diffraction patterns are indicative of different crystal states.

Note that, for example, after the first oxide semiconductor layer and the second oxide semiconductor layer are concurrently formed, a crystal in one of the first oxide semiconductor layer and the second oxide semiconductor layer is destroyed, whereby the first oxide semiconductor layer and the second oxide semiconductor layer can have different crystal states.

As a method for destroying the crystal, plasma treatment, an ion doping method, an ion implantation method, and the like are given as examples, but the method is not limited to these examples.

Further, for example, the first oxide semiconductor layer and the second oxide semiconductor layer can be formed by different formation methods. Thus, the first oxide semiconductor layer and the second oxide semiconductor layer can have different crystal states.

The oxide semiconductor layer may have a single-layer structure or a layered structure.

In the case where the oxide semiconductor layer has a layered structure, oxide semiconductor layers with different electron affinities may be stacked.

As electron affinity increases, an insulating property becomes higher, and accordingly, the off-state current of a transistor becomes lower.

As electron affinity decreases, conductivity becomes higher, and accordingly, the on-state current of a transistor becomes higher.

It is preferable to stack the oxide semiconductor layers with different electron affinities because both the advantage of the oxide semiconductor layer with high electron affinity and the advantage of the oxide semiconductor layer with low electron affinity can be utilized.

The oxide semiconductor layer with high electron affinity may be provided over the oxide semiconductor layer with low electron affinity. The oxide semiconductor layer with high electron affinity may be provided under the oxide semiconductor layer with low electron affinity.

The second oxide semiconductor layer with second electron affinity may be provided over the first oxide semiconductor layer with first electron affinity. The third oxide semiconductor layer with third electron affinity may be provided over the second oxide semiconductor layer with second electron affinity.

In the case where the first electron affinity and the third electron affinity are higher than the second electron affinity, it is possible to inhibit occurrence of leakage current at a surface and a rear surface of the oxide semiconductor layer.

The third electron affinity can be lower than the first electron affinity.

The third electron affinity can be higher than the first electron affinity.

The third electron affinity can be the same as the first electron affinity.

The layer containing an organic compound preferably includes at least a light-emitting layer.

The layer containing an organic compound may include an electron-injection layer, an electron-transport layer, a hole-injection layer, a hole-transport layer, and the like.

The light-emitting element is not limited to an organic EL element.

An LED element, an inorganic EL element, or the like may be used as the light-emitting element.

At least part of the structure described in this embodiment can be combined with at least part of a structure described in any of the other embodiments.

### Embodiment 25

In Embodiment 1, the following point is already explained: the use for the oxide semiconductor layer 32 is not limited to one electrode of the element in FIG. 58.

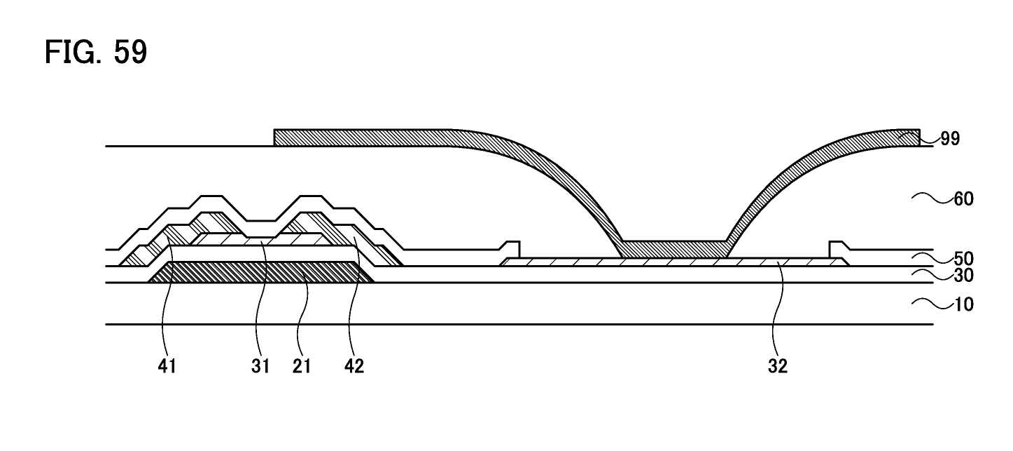

Further, as illustrated in FIG. 59, a layer 99 having a heat dissipation property can be formed in the inside of the hole of the resin layer 60 and over the resin layer 60.

The layer 99 having a heat dissipation property which is provided in the inside the hole of the resin layer 60 can dissipate heat generated in the oxide semiconductor layer 32.

The hole reaching the oxide semiconductor layer 32 is not necessarily provided in the resin layer 60, in which case the layer 99 having a heat dissipation property may be provided under the resin layer 60 and over the oxide semiconductor layer.

However, when the layer 99 having a heat dissipation property is provided under the resin layer 60, the distance between the layer 99 having a heat dissipation property and the transistor is short, in which case the transistor might be heated.

If the transistor is heated, the electrical characteristics of the transistor might be changed.

Hence, the layer 99 having a heat dissipation property is preferably provided over the resin layer 60.

When the layer 99 having a heat dissipation property is provided over the resin layer 60, the distance between the transistor and the layer 99 having a heat dissipation property can be long.

The layer 99 having a heat dissipation property may have an island-like shape as illustrated in FIG. 59.

The layer 99 having a heat dissipation property may be provided over an entire surface of the substrate.

The layer 99 having a heat dissipation property may be any film as long as it is a film including a material having a heat dissipation property.

Silicon nitride, aluminum oxide, diamond-like carbon, aluminum nitride, silicon, metal, and the like are given as examples of the material having a heat dissipation property, but the material is not limited to these examples.

Gold, silver, copper, platinum, iron, aluminum, molybdenum, titanium, tungsten, and the like are given as examples of the metal, but the metal is not limited to these examples.

For example, the thermal conductivity of silicon nitride is approximately 20 W/m·K.

For example, the thermal conductivity of aluminum oxide is approximately 23 W/m·K.

For example, the thermal conductivity of a diamond-like carbon film is approximately 400 W/m·K to approximately 1800 W/m·K.

For example, the thermal conductivity of aluminum nitride is approximately 170 W/m·K to approximately 200 W/m·K.

For example, the thermal conductivity of silicon is approximately 168 W/m·K.

For example, the thermal conductivity of gold is approximately 320 W/m·K.

For example, the thermal conductivity of silver is approximately 420 W/m·K.

For example, the thermal conductivity of copper is approximately 398 W/m·K.

For example, the thermal conductivity of platinum is approximately 70 W/m·K.

For example, the thermal conductivity of iron is approximately 84 W/m·K.

For example, the thermal conductivity of aluminum is approximately 236 W/m·K.

For example, the thermal conductivity of molybdenum is approximately 139 W/m·K.

For example, the thermal conductivity of titanium is approximately 21.9 W/m·K.

For example, the thermal conductivity of tungsten is approximately 177 W/m·K.

The thermal conductivities of gold, silver, copper, and aluminum are particularly high.

In addition, the thermal conductivities of a copper alloy film and an aluminum alloy film are high.

As reference, the thermal conductivity of acrylic is 0.2 W/m·K.

As reference, the thermal conductivity of epoxy is 0.21 W/m·K.

As reference, the thermal conductivity of silicon oxide is 8 W/m·K.

The layer 99 having a heat dissipation property may have a single-layer structure or a layered structure.

The more the thermal conductivity increases, the higher the heat dissipation property becomes. Hence, it is particularly preferable to use a substance having a thermal conductivity of 150 W/m·K or more.

Note that in the case where the oxide semiconductor layer contains indium and is in contact with a film including a predetermined material (e.g., copper, a copper alloy, aluminum, or an aluminum alloy), corrosion is caused in some cases by reaction between the film including a predetermined material and the oxide semiconductor layer.

Thus, the layer 99 having a heat dissipation property except the film having a predetermined material is preferably provided between the film having a predetermined material and the oxide semiconductor layer.

That is, a second layer having a heat dissipation property is provided over a first layer having a heat dissipation property.

A material of the first layer having a heat dissipation property is preferably silicon nitride, aluminum oxide, diamond-like carbon, aluminum nitride, silicon, platinum, iron, molybdenum, titanium, tungsten, or the like which hardly causes corrosion with the oxide semiconductor layer, but the material is not limited to these examples.

In particular, molybdenum, titanium, tungsten, or the like which is stable metal is preferable as the material of the first layer having a heat dissipation property.

The second layer having a heat dissipation property is a film including a predetermined material.

Examples of the predetermined material include copper, a copper alloy, aluminum, and an aluminum alloy.

Note that H is preferably contained in the layer having a heat dissipation property.

By the contact of the layer containing H and having a heat dissipation property with the oxide semiconductor layer, H can be supplied to the oxide semiconductor layer.

The layer containing H and having a heat dissipation property can be formed in such a manner that a film containing silicon is formed using a gas containing H. For example, H is contained in a film formation atmosphere. In the case of using a sputtering method, for example, H is contained in a sputtering gas. In the case of using a plasma CVD method, for example, H is contained in a CVD gas.

At least part of the structure described in this embodiment can be combined with at least part of a structure described in any of the other embodiments.

### Embodiment 26

The semiconductor device is a device including an element having a semiconductor.

Examples of the element having a semiconductor include a transistor, a resistor, a capacitor, and a diode.

It is preferable to use a field-effect transistor as the transistor, but the transistor is not limited thereto.

It is preferable to use a thin film transistor as the transistor, but the transistor is not limited thereto.

Examples of the semiconductor device include a display device including a display element, a memory device including a memory element, an RFID, and a processor, but the semiconductor device is not limited to these examples.

At least part of the structure described in this embodiment can be combined with at least part of a structure described in any of the other embodiments.

### Embodiment 27

The second object of one embodiment of the present invention is to provide a semiconductor device including a novel structure.

For example, the structures illustrated in FIG. 3, FIGS. 4A and 4B, FIG. 5, FIGS. 6A and 6B, FIG. 7, FIGS. 8A and 8B, FIG. 9, FIGS. 10A and 10B, FIGS. 11A and 11B, FIG. 12, FIGS. 13A and 13B, and FIGS. 14 to 30 are novel structures.

Hence, for example, the oxide semiconductor layers 311 to 319 and the like are not necessarily in contact with the resin layer 600 in FIG. 3, FIGS. 4A and 4B, FIG. 5, FIGS. 6A and 6B, FIG. 7, FIGS. 8A and 8B, FIG. 9, FIGS. 10A and 10B, FIGS. 11A and 11B, FIG. 12, FIGS. 13A and 13B, and FIGS. 14 to 30.

In the case where the oxide semiconductor layers 311 to 319 and the like are not in contact with the resin layer 600, holes for contacting the oxide semiconductor layers 311 to 319 with the resin layer 600 and the like are not provided.

Note that the oxide semiconductor layers 311 to 319 and the like can each function as a wiring. Hence, a space in which an active layer is not formed is used effectively; thus, the third object can also be achieved.

Further, for example, the structures shown in FIGS. 31 to 37 are novel structures.

Hence, for example, the oxide semiconductor layer 350 and the like are not necessarily in contact with the resin layer 600 in FIGS. 31 to 37.

In the case where the oxide semiconductor layer 350 and the like are not in contact with the resin layer 600, holes for contacting each of the oxide semiconductor layer 350 and the like with the resin layer 600 are not provided.

Note that the oxide semiconductor layer 350 and the like can function as electrodes. Hence, a space in which an active layer is not formed is used effectively. Thus, the third object can also be achieved.

Furthermore, for example, the structures shown in FIGS. 38 to 53 are novel structures.

Hence, for example, the oxide semiconductor layer 1302, the oxide semiconductor layer 1304, the oxide semiconductor layer 1305, and the like are not necessarily in contact with the resin layer 1600 in FIGS. 38 to 53.

In the case where the oxide semiconductor layer 1302, the oxide semiconductor layer 1304, the oxide semiconductor layer 1305, and the like are not in contact with the resin layer 1600, holes for contacting each of the oxide semiconductor layers 1302, 1304, 1305, and the like with the resin layer 1600 are not provided.

Note that the oxide semiconductor layer 1302 and the like can function as electrodes. Hence, a space in which an active layer is not formed is used effectively. Thus, the third object can also be achieved.

The oxide semiconductor layer 1304 and the like can function as resistors. Hence, a space in which an active layer is not formed is used effectively. Thus, the third object can also be achieved.

The oxide semiconductor layer 1305 and the like can function as active layers. Hence, a space in which an active layer is not formed is used effectively. Thus, the third object can also be achieved.

At least part of the structure described in this embodiment can be combined with at least part of a structure described in any of the other embodiments.

### Embodiment 28

In any of other embodiments, an example in which a predetermined conductive layer is provided between the inorganic insulating layer and the oxide semiconductor layer is illustrated.

That is, in any of other embodiments, an example in which the inorganic insulating layer is formed after the predetermined conductive layer is formed is illustrated.

On the other hand, the predetermined conductive layer may be provided between the inorganic insulating layer and the resin layer.

That is, the predetermined conductive layer may be formed after the inorganic insulating layer is formed.

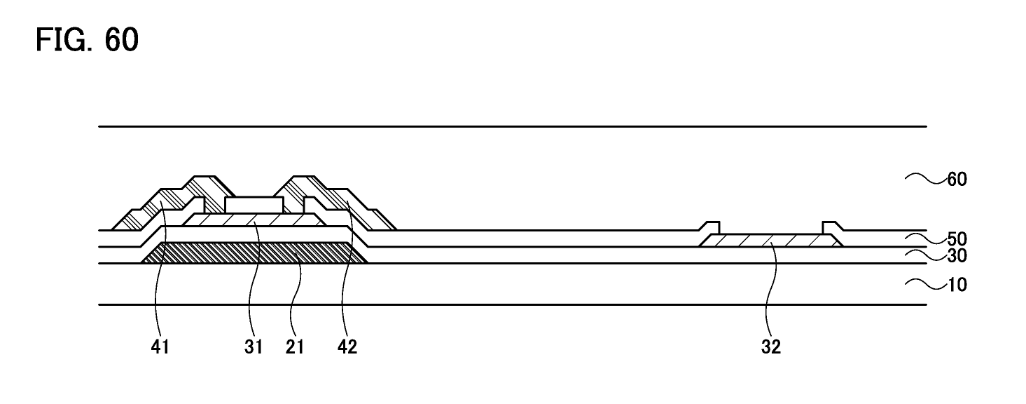

For example, FIG. 60 illustrates an example of a drawing which is different from FIG. 1 in that the conductive layer 41 and the conductive layer 42 are formed after the inorganic insulating layer 50 is formed.

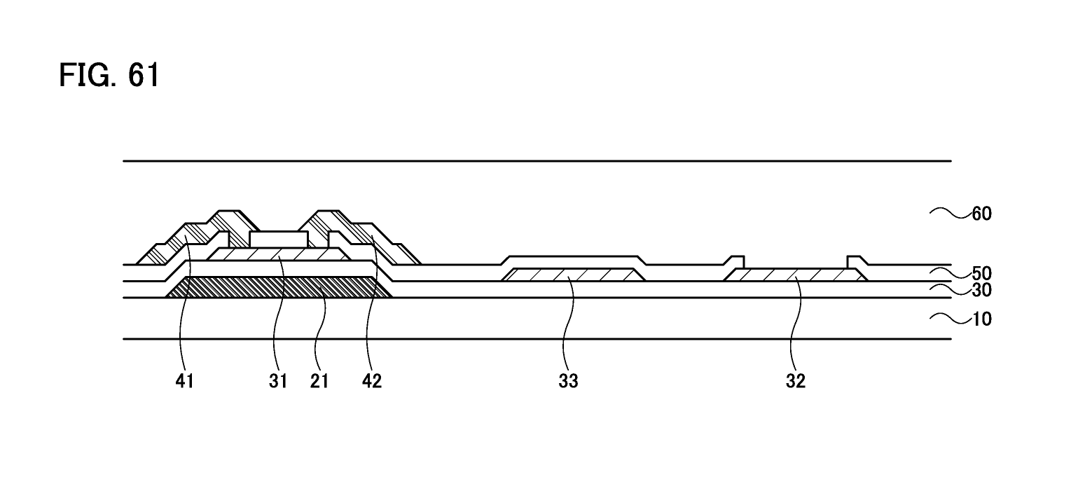

For example, FIG. 61 illustrates an example of a drawing which is different from FIG. 2 in that the conductive layer 41 and the conductive layer 42 are formed after the inorganic insulating layer 50 is formed.

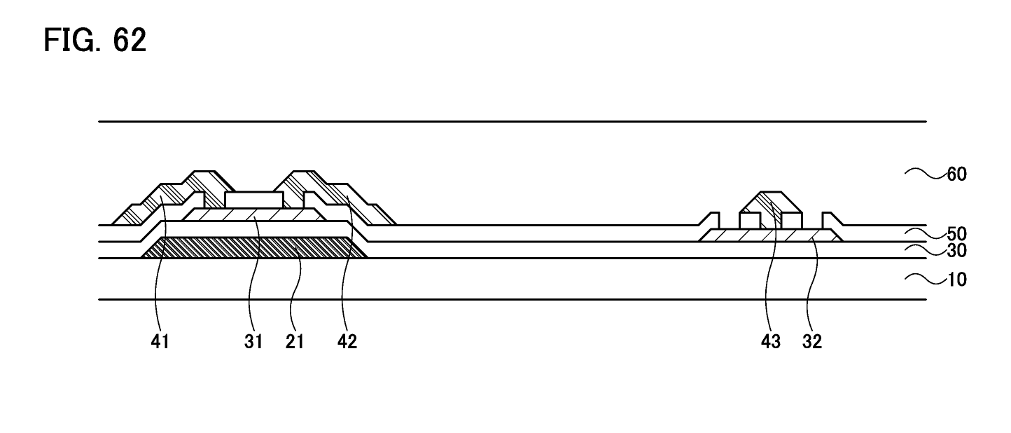

For example, FIG. 62 illustrates an example of a drawing which is different from FIG. 54 in that the conductive layer 41, the conductive layer 42, and the conductive layer 43 are formed after the inorganic insulating layer 50 is formed.

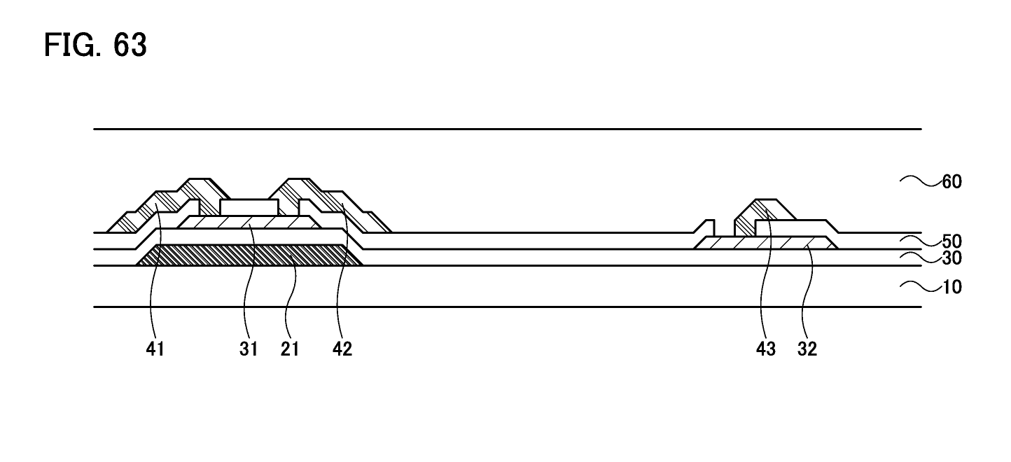

For example, FIG. 63 illustrates an example of a drawing which is different from FIG. 54 in that the conductive layer 41, the conductive layer 42, and the conductive layer 43 are formed after the inorganic insulating layer 50 is formed.

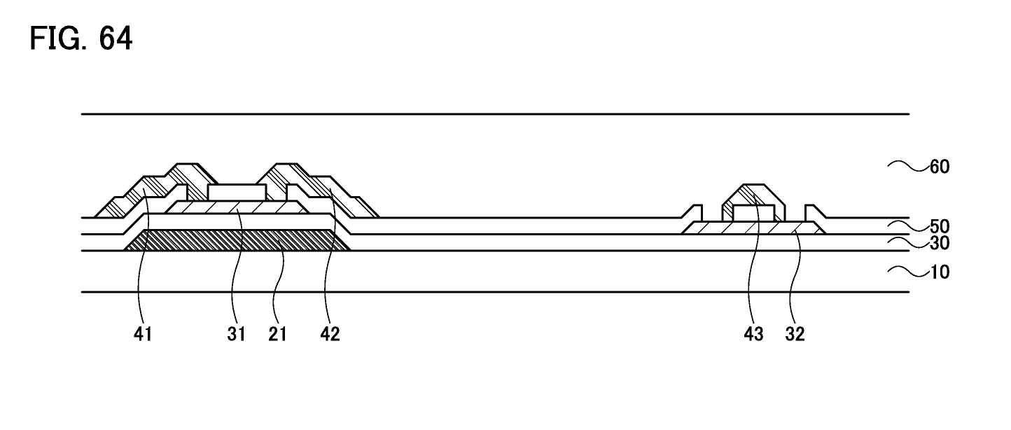

For example, FIG. 64 illustrates an example of a drawing which is different from FIG. 54 in that the conductive layer 41, the conductive layer 42, and the conductive layer 43 are formed after the inorganic insulating layer 50 is formed.

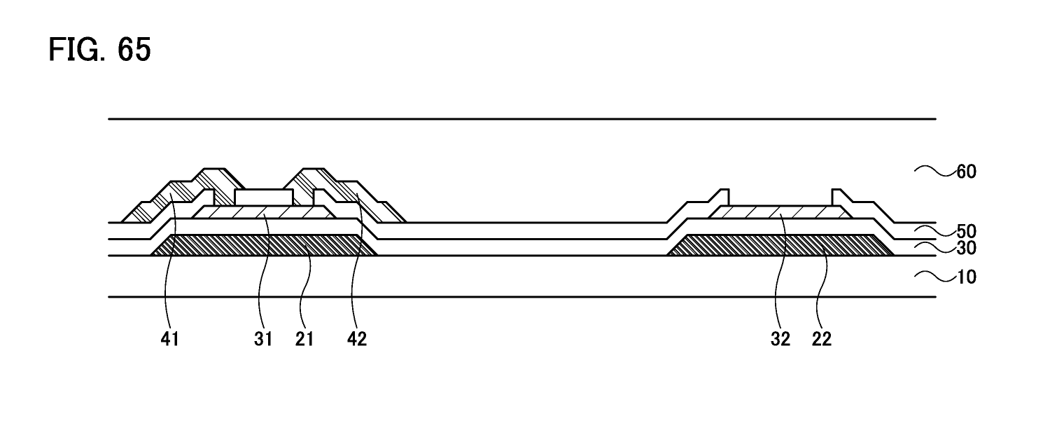

For example, FIG. 65 illustrates an example of a drawing which is different from FIG. 55 in that the conductive layer 41 and the conductive layer 42 are formed after the inorganic insulating layer 50 is formed.

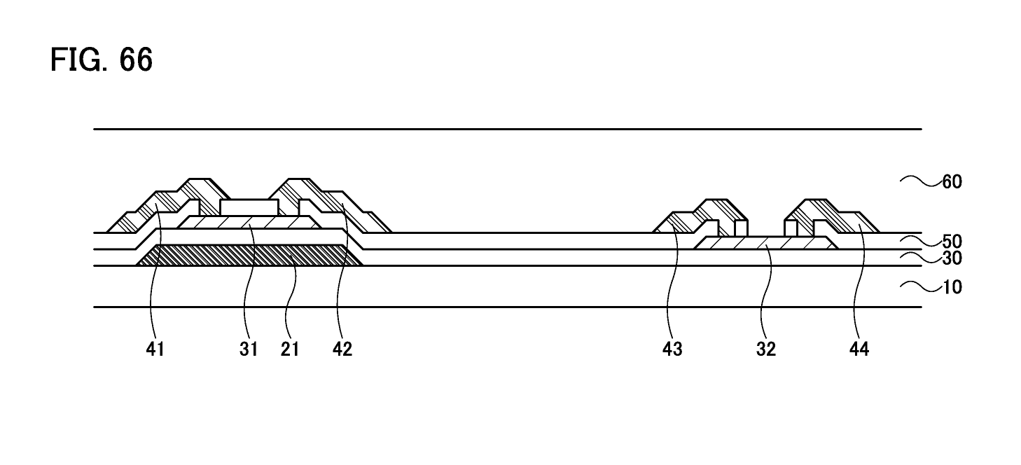

For example, FIG. 66 illustrates an example of a drawing which is different from FIG. 56 in that the conductive layer 41, the conductive layer 42, the conductive layer 43, and the conductive layer 44 are formed after the inorganic insulating layer 50 is formed.

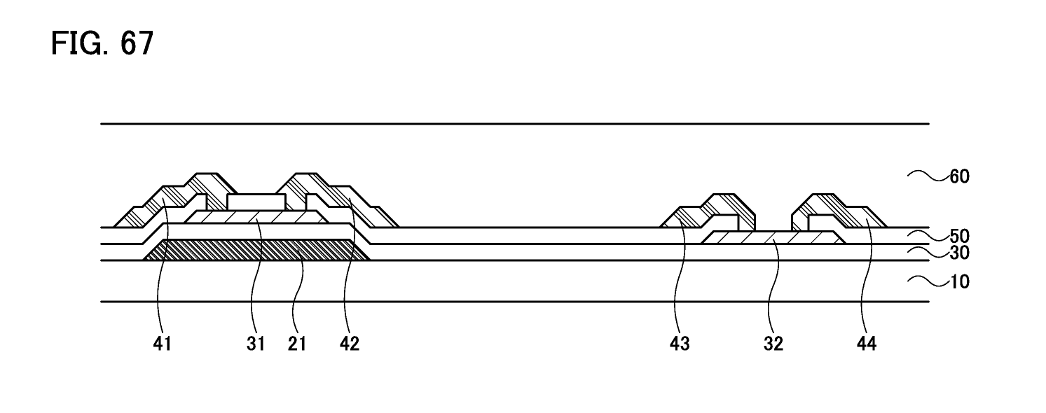

For example, FIG. 67 illustrates an example of a drawing which is different from FIG. 56 in that the conductive layer 41, the conductive layer 42, the conductive layer 43, and the conductive layer 44 are formed after the inorganic insulating layer 50 is formed.

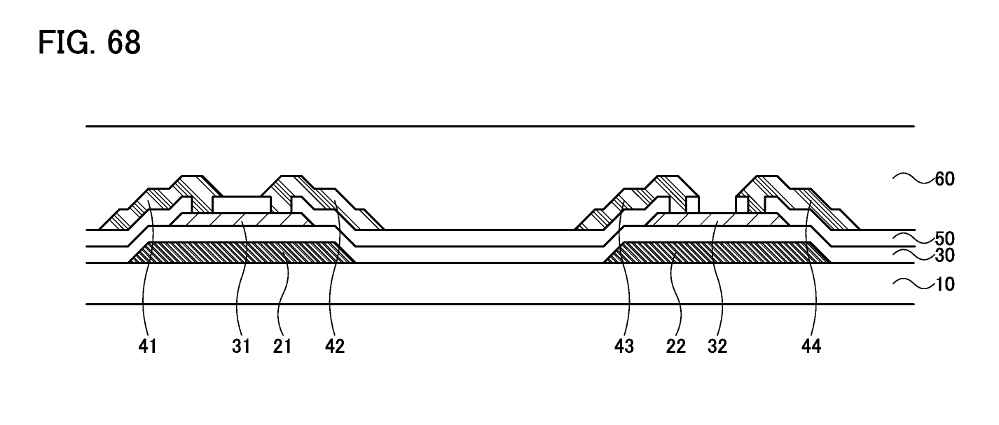

For example, FIG. 68 illustrates an example of a drawing which is different from FIG. 57 in that the conductive layer 41, the conductive layer 42, the conductive layer 43, and the conductive layer 44 are formed after the inorganic insulating layer 50 is formed.

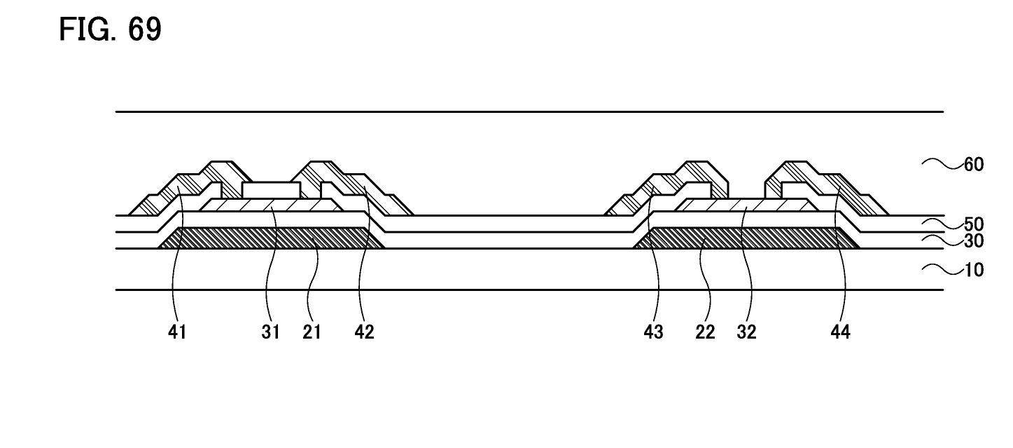

For example, FIG. 69 illustrates an example of a drawing which is different from FIG. 57 in that the conductive layer 41, the conductive layer 42, the conductive layer 43, and the conductive layer 44 are formed after the inorganic insulating layer 50 is formed.

In FIGS. 60 to 69, the conductive layer 41 is provided over the inorganic insulating layer 50.

In FIGS. 60 to 69, the conductive layer 42 is provided over the inorganic insulating layer 50.

In FIGS. 60 to 69, the resin layer 60 is provided over the conductive layer 41 and the conductive layer 42.

In FIGS. 60 to 69, the conductive layer 41 is electrically connected to the oxide semiconductor layer 31 through the contact hole of the inorganic insulating layer 50.

In FIGS. 60 to 69, the conductive layer 42 is electrically connected to the oxide semiconductor layer 31 through the contact hole of the inorganic insulating layer 50.

In FIGS. 62 to 64, the conductive layer 43 is provided between the inorganic insulating layer 50 and the resin layer 60.

In FIG. 62, the oxide semiconductor layer 32 includes a portion being in contact with the resin layer 60 in the inside of one hole of the inorganic insulating layer 50 and a portion being in contact with the conductive layer 43 in the inside of another hole of the inorganic insulating layer 50.

In FIG. 63, the oxide semiconductor layer 32 includes a portion being in contact with the resin layer 60 and a portion being in contact with the conductive layer 43 in the inside of one hole of the inorganic insulating layer 50.

In FIG. 64, the oxide semiconductor layer 32 includes a portion being in contact with the resin layer 60 and a portion being in contact with the conductive layer 43 in the inside of one hole of the inorganic insulating layer 50, and includes a portion being in contact with the resin layer 60 and a portion being in contact with the conductive layer 43 in the inside of another hole of the inorganic insulating layer 50.

FIG. 62 illustrates an example in which a place where the oxide semiconductor layer 32 is in contact with the resin layer 60 is different from a place where the oxide semiconductor layer 32 is in contact with the conductive layer 43.

FIGS. 63 and 64 each illustrate an example in which a place where the oxide semiconductor layer 32 is in contact with the resin layer 60 is the same as a place where the oxide semiconductor layer 32 is in contact with the conductive layer 43.

FIG. 63 illustrates an example in which the oxide semiconductor layer 32 and the conductive layer 43 are in contact with each other at one place. FIG. 64 illustrates an example in which the oxide semiconductor layer 32 and the conductive layer 43 are in contact with each other at a plurality of places.

In FIGS. 66 to 69, the conductive layer 43 and the conductive layer 44 are provided between the inorganic insulating layer 50 and the resin layer 60.

In FIGS. 66 and 68, the oxide semiconductor layer 32 includes a portion being in contact with the resin layer 60 in the inside of one hole of the inorganic insulating layer 50, and includes a portion being in contact with the conductive layer 43 in the inside of another hole of the inorganic insulating layer 50.

In FIGS. 66 and 68, the oxide semiconductor layer 32 includes a portion being in contact with the resin layer 60 in the inside of one hole of the inorganic insulating layer 50, and includes a portion being in contact with the conductive layer 44 in the inside of another hole of the inorganic insulating layer 50.

In FIGS. 67 and 69, the oxide semiconductor layer 32 includes a portion being in contact with the resin layer 60, a portion being in contact with the conductive layer 43, and a portion being in contact with the conductive layer 44 in the inside of one hole of the inorganic insulating layer 50.

FIGS. 66 and 68 illustrate an example in which a place where the oxide semiconductor layer 32 is in contact with the resin layer 60 is different from a place where the oxide semiconductor layer 32 is in contact with the conductive layer 43.

FIGS. 66 and 68 illustrate an example in which a place where the oxide semiconductor layer 32 is in contact with the resin layer 60 is different from a place where the oxide semiconductor layer 32 is in contact with the conductive layer 44.

FIGS. 67 and 69 illustrate an example in which a place where the oxide semiconductor layer 32 is in contact with the resin layer 60, a place where the oxide semiconductor layer 32 is in contact with the conductive layer 43, and a place where the oxide semiconductor layer 32 is in contact with the conductive layer 44 are the same.

At least part of the structure described in this embodiment can be combined with at least part of a structure described in any of the other embodiments.

### Embodiment 29

A small amount of H₂O enters the oxide semiconductor layer through the inorganic insulating layer in some cases.

Thus, a protective layer can be provided to inhibit entry of H₂O into the oxide semiconductor layer.

In particular, when H₂O is contained in a layer existing over the inorganic insulating layer or when H₂O is contained in a gas existing over the inorganic insulating layer, H₂O easily enters the oxide semiconductor layer.

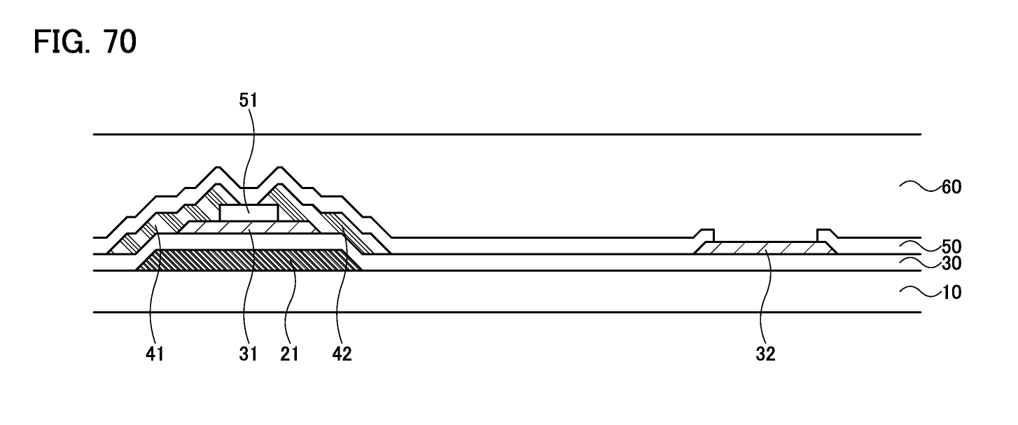

For example, FIG. 70 illustrates an example of a drawing which is different from FIG. 1 in that a protective layer 51 and the like are provided.

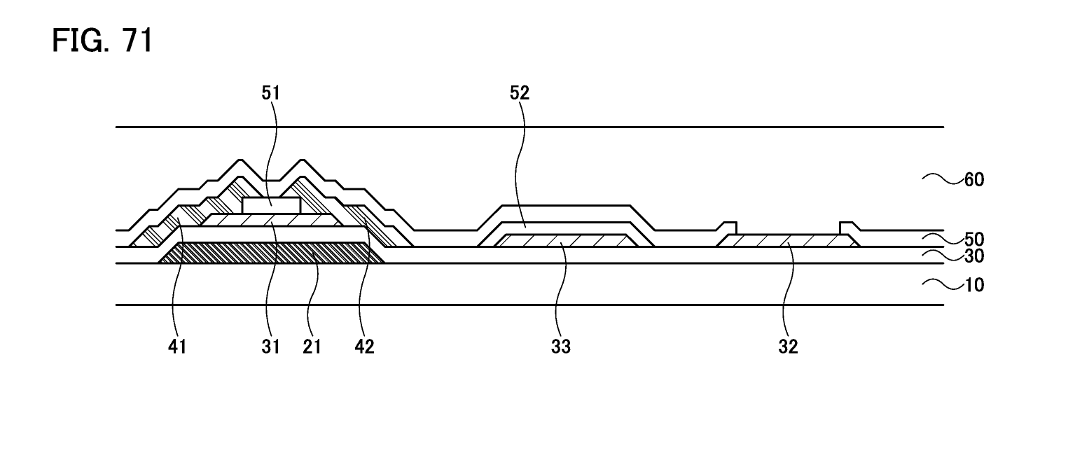

For example, FIG. 71 illustrates an example of a drawing which is different from FIG. 2 in that the protective layer 51, a protective layer 52, and the like are provided.

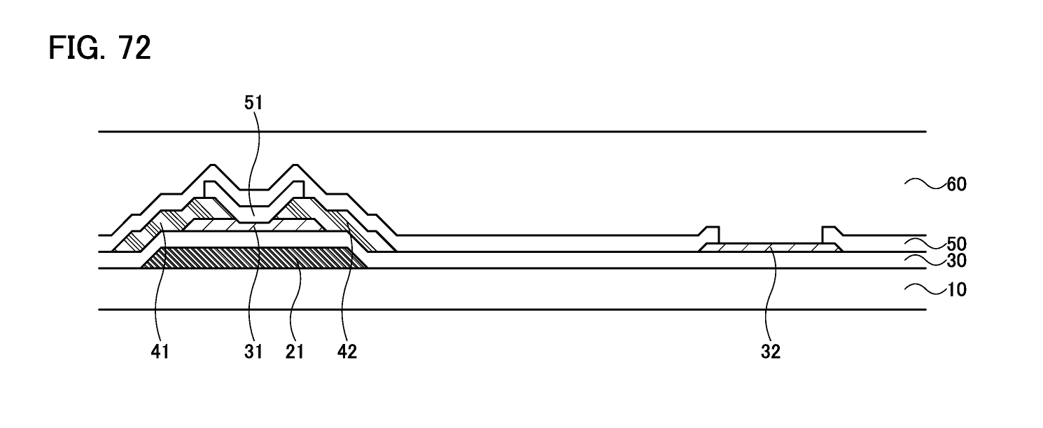

For example, FIG. 72 illustrates an example of a drawing which is different from FIG. 1 in that the protective layer 51 and the like are provided.

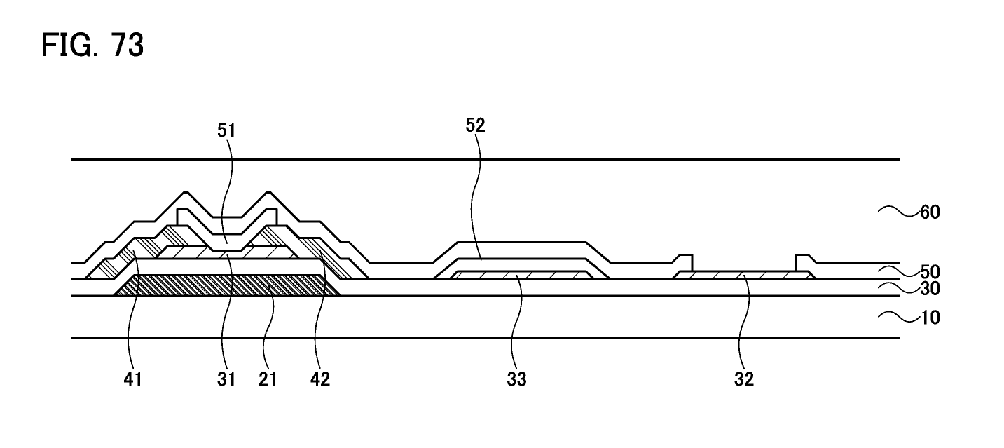

For example, FIG. 73 illustrates an example of a drawing which is different from FIG. 2 in that the protective layer 51, the protective layer 52, and the like are provided.

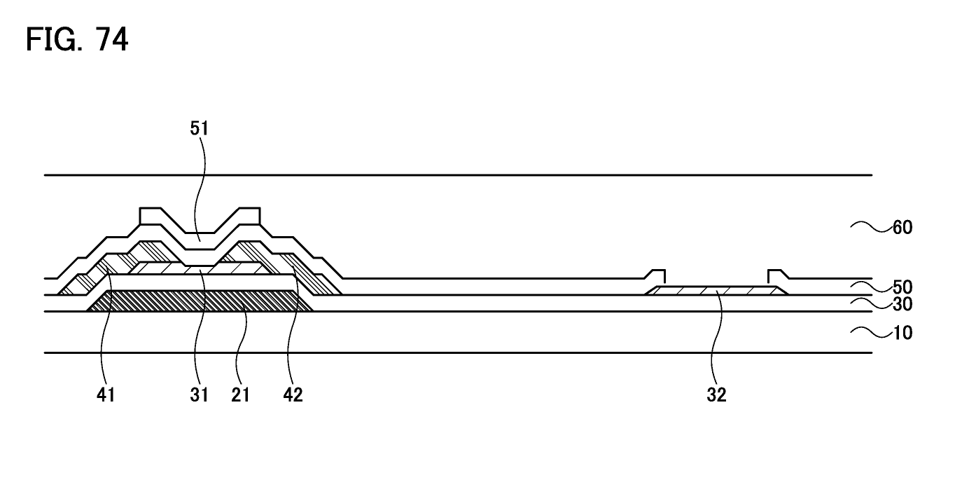

For example, FIG. 74 illustrates an example of a drawing which is different from FIG. 1 in that the protective layer 51 and the like are provided.

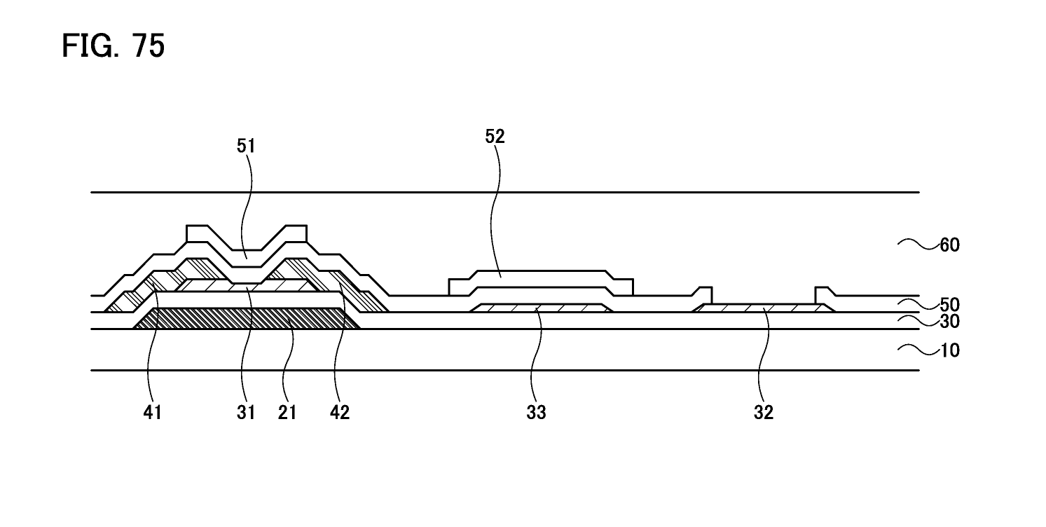

For example, FIG. 75 illustrates an example of a drawing which is different from FIG. 2 in that the protective layer 51, the protective layer 52, and the like are provided.

In FIGS. 70 and 71, the protective layer 51 is provided over the oxide semiconductor layer 31, the conductive layer 41 is provided over the oxide semiconductor layer 31 and the protective layer 51, the conductive layer 42 is provided over the oxide semiconductor layer 31 and the protective layer 51, and the inorganic insulating layer 50 is provided over the conductive layer 41 and the conductive layer 42.

In FIG. 71, the protective layer 52 is provided over the oxide semiconductor layer 33, and the inorganic insulating layer 50 is provided over the protective layer 52.

In FIGS. 72 and 73, the protective layer 51 is provided over the oxide semiconductor layer 31, the conductive layer 41, and the conductive layer 42, and the inorganic insulating layer 50 is provided over the protective layer 51.

In FIG. 73, the protective layer 52 is provided over the oxide semiconductor layer 33, and the inorganic insulating layer 50 is provided over the protective layer 52.

In FIGS. 74 and 75, the protective layer 51 is provided over the inorganic insulating layer 50, and the resin layer 60 is provided over the protective layer 51.

In FIG. 75, the protective layer 52 is provided over the inorganic insulating layer 50, and the resin layer 60 is provided over the protective layer 52.

The protective layer 51 includes a region overlapping with the oxide semiconductor layer 31.

The protective layer 52 includes a region overlapping with the oxide semiconductor layer 33.

The protective layer 51 and the protective layer 52 are separated from each other; alternatively, the protective layer 51 and the protective layer 52 may be provided as one protective layer.

In the case of forming the protective layer 51 and the protective layer 52 as one protective layer, the one protective layer includes a region overlapping with the oxide semiconductor layer 31 and a region overlapping with the oxide semiconductor layer 33.

Further, only one of the protective layer 51 and the protective layer 52 may be provided.

The protective layer can be formed using an inorganic insulating layer, a semiconductor layer, a conductive layer, or the like.

The inorganic insulating layer, the semiconductor layer, the conductive layer, or the like can be formed using the examples described in any of other embodiments, for example.

The protective layer preferably has a heat dissipation property.

Note that in the case where the protective layer 51 includes a portion being in contact with the oxide semiconductor layer 31, in the case where the protective layer 51 includes a portion being n contact with the conductive layer 41, or in the case where the protective layer 51 includes a portion being in contact with the conductive layer 42, the protective layer is preferably an inorganic insulating layer.

The protective layer 51 and the protective layer 52 may be formed in the same layer or different layers.

The protective layer 51 and the protective layer 52 may be formed using the same material or different materials.

When the protective layer 51 and the protective layer 52 are formed in the same step, the protective layer 51 and the protective layer 52 can be formed in the same layer using the same material without increasing the number of steps.

In the case where the protective layer 51 and the protective layer 52 are formed in different layers, one of the protective layer 51 and the protective layer 52 can be provided in a position upper than the inorganic insulating layer 50, and the other of the protective layer 51 and the protective layer 52 can be provided in a position lower than the inorganic insulating layer 50, for example.

For example, it is possible to use a structure in which parts of the structures in FIGS. 70 to 75 are combined as appropriate.

By providing the protective layer as described above, the thickness of a portion upper than the oxide semiconductor layer can be increased. Accordingly, entry of H₂O from the upper portion of the oxide semiconductor layer can be inhibited.

Note that the protective layer may be added to structures such as those illustrated in FIGS. 60 to 69.

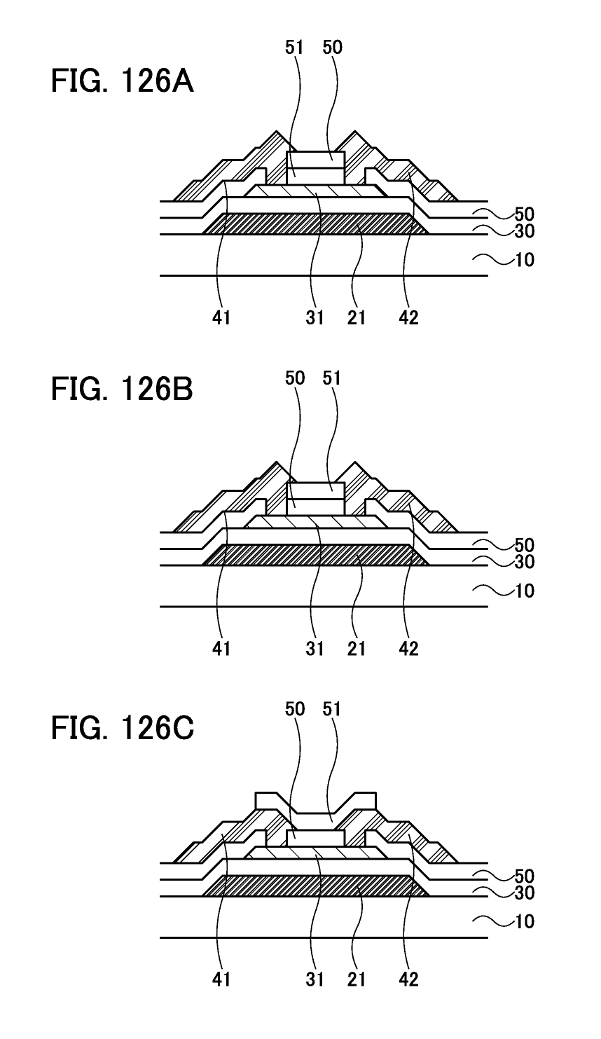

For example, FIG. 126A illustrates an example in which the protective layer 51 is provided between the oxide semiconductor layer 31 and the inorganic insulating layer 50.

For example, FIG. 126B illustrates an example in which the inorganic insulating layer 50 is provided between the oxide semiconductor layer 31 and the protective layer 51.

For example, FIG. 126C illustrates an example in which the protective layer 51 is provided over the inorganic insulating layer 50, the conductive layer 41, and the conductive layer 42.

In the case of providing the protective layer 52, the protective layer 51 and the protective layer 52 may be formed in the same layer or different layers.

In the case of providing the protective layer 52, the protective layer 51 and the protective layer 52 may be formed using the same material or different materials.

In the case of providing the protective layer 52, the protective layer 51 and the protective layer 52 are preferably formed in the same step, in which case the number of steps can be reduced.

In the case of providing the protective layer 52, one of the protective layer 51 and the protective layer 52 may be provided in a position upper than the inorganic insulating layer 50, and the other of the protective layer 51 and the protective layer 52 may be provided in a position lower than the inorganic insulating layer 50.

Further, the protective layer 51 and the protective layer 52 may be provided as one protective layer.

It is preferable that the protective layer be electrically insulated from a wiring or an electrode (be in a floating state or in an electrically isolated state), in which case an adverse effect on a circuit operation is small.

At least part of the structure described in this embodiment can be combined with at least part of a structure described in any of the other embodiments.

### Embodiment 30

In any of the other embodiments, an example is illustrated in which the resin layer is provided over an entire surface of the substrate. However, the resin layer may be provided locally.

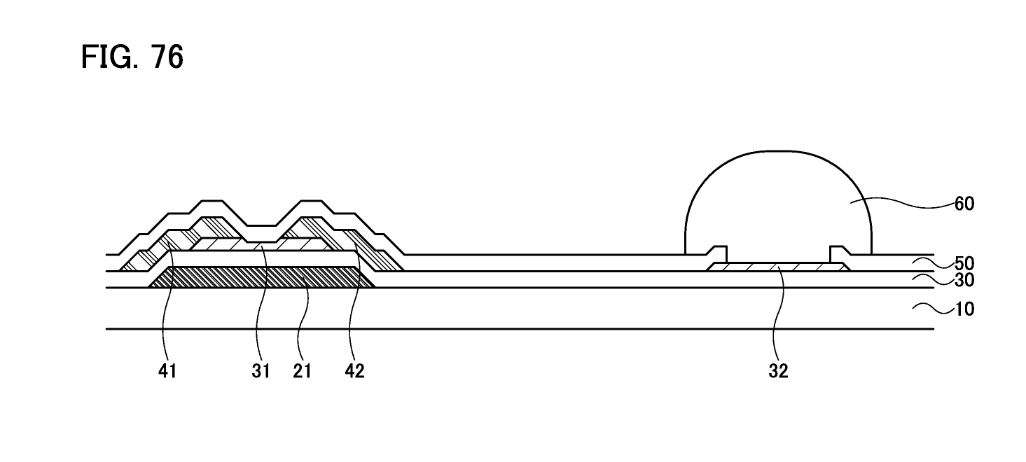

For example, FIG. 76 illustrates an example of a drawing which is different from FIG. 1 in that the resin layer 60 is provided locally.

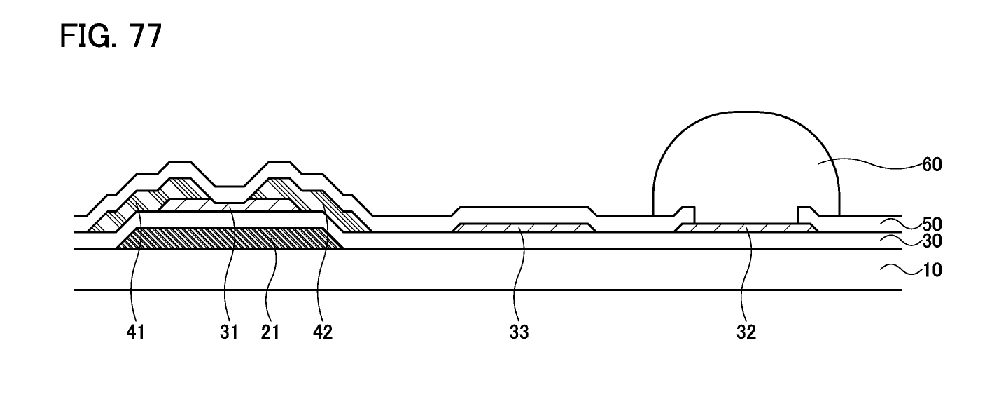

For example, FIG. 77 illustrates an example of a drawing which is different from FIG. 2 in that the resin layer 60 is provided locally.

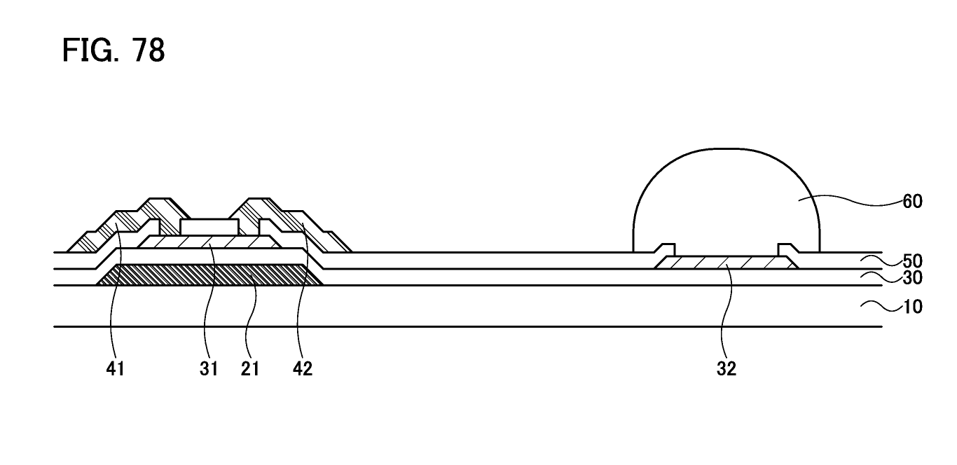

For example, FIG. 78 illustrates an example of a drawing which is different from FIG. 60 in that the resin layer 60 is provided locally.

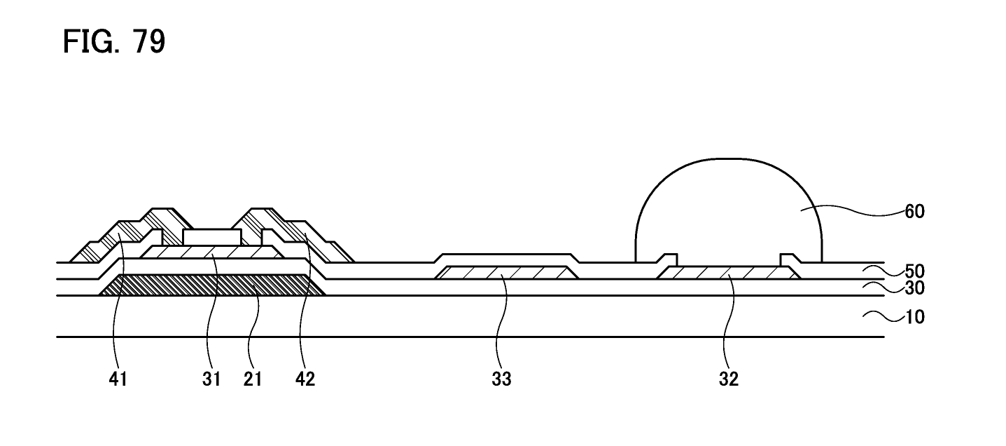

For example, FIG. 79 illustrates an example of a drawing which is different from FIG. 61 in that the resin layer 60 is provided locally.

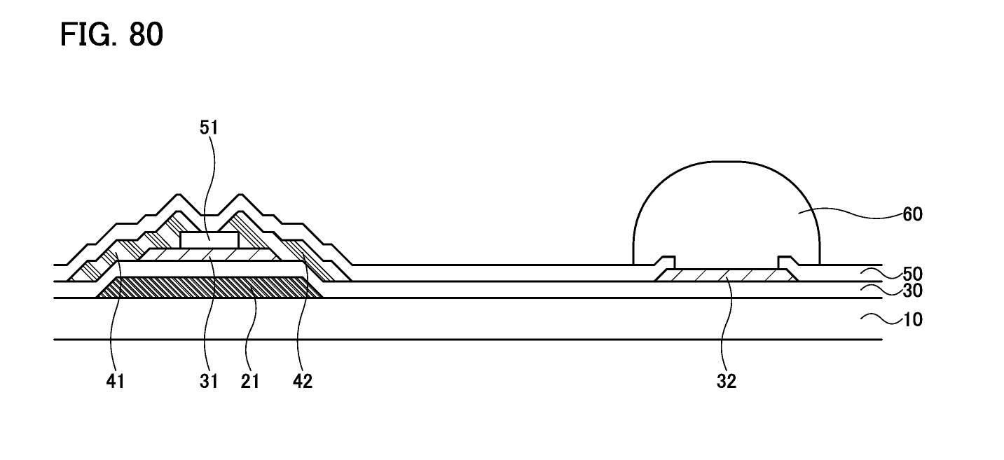

For example, FIG. 80 illustrates an example of a drawing which is different from FIG. 70 in that the resin layer 60 is provided locally.

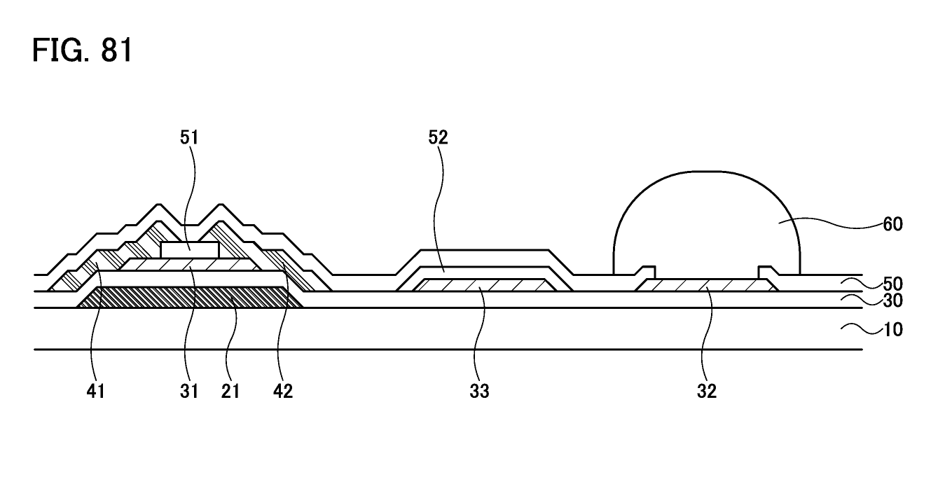

For example, FIG. 81 illustrates an example of a drawing which is different from FIG. 71 in that the resin layer 60 is provided locally.

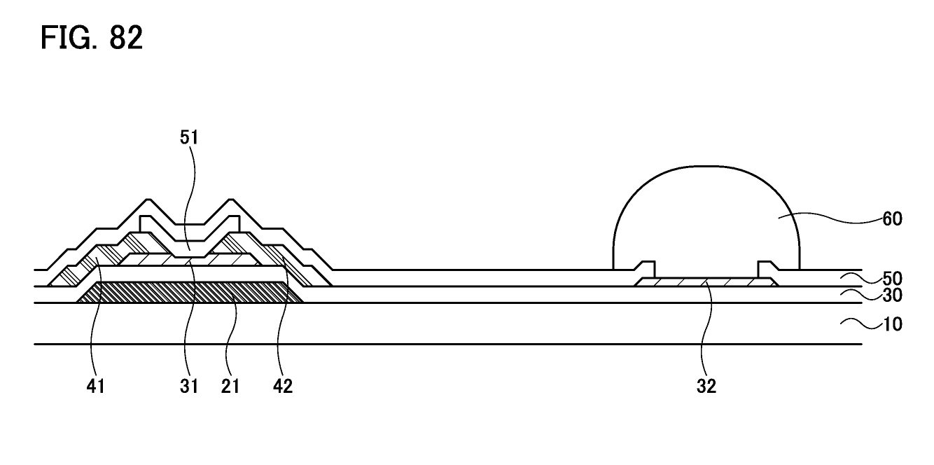

For example, FIG. 82 illustrates an example of a drawing which is different from FIG. 72 in that the resin layer 60 is provided locally.

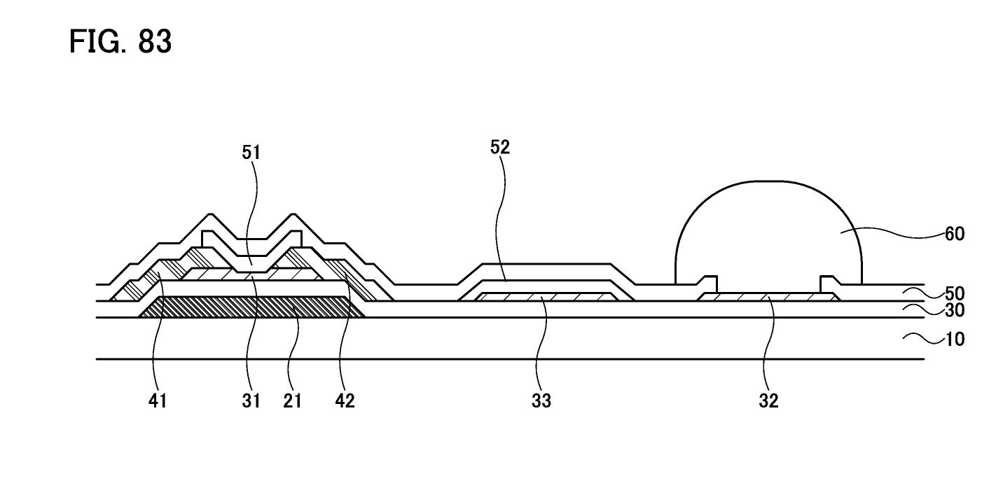

For example, FIG. 83 illustrates an example of a drawing which is different from FIG. 73 in that the resin layer 60 is provided locally.

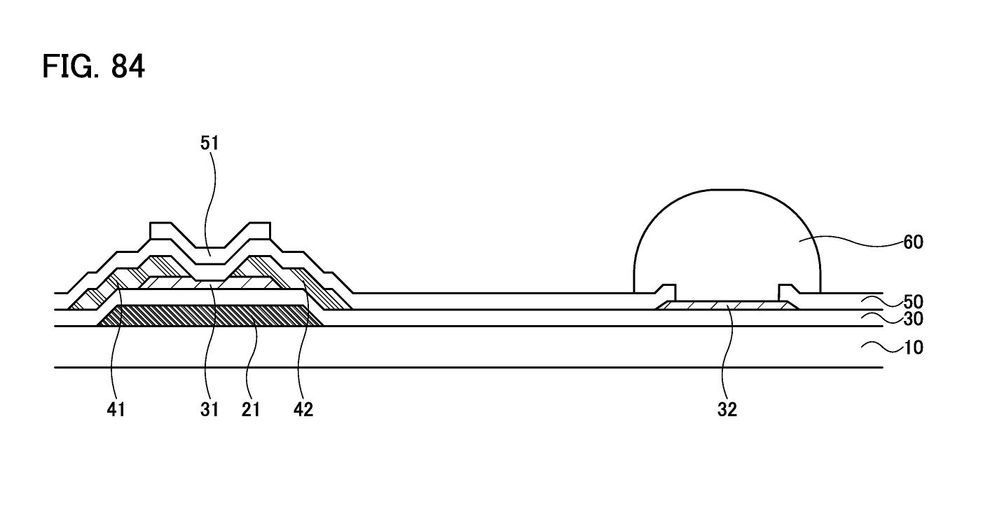

For example, FIG. 84 illustrates an example of a drawing which is different from FIG. 74 in that the resin layer 60 is provided locally.

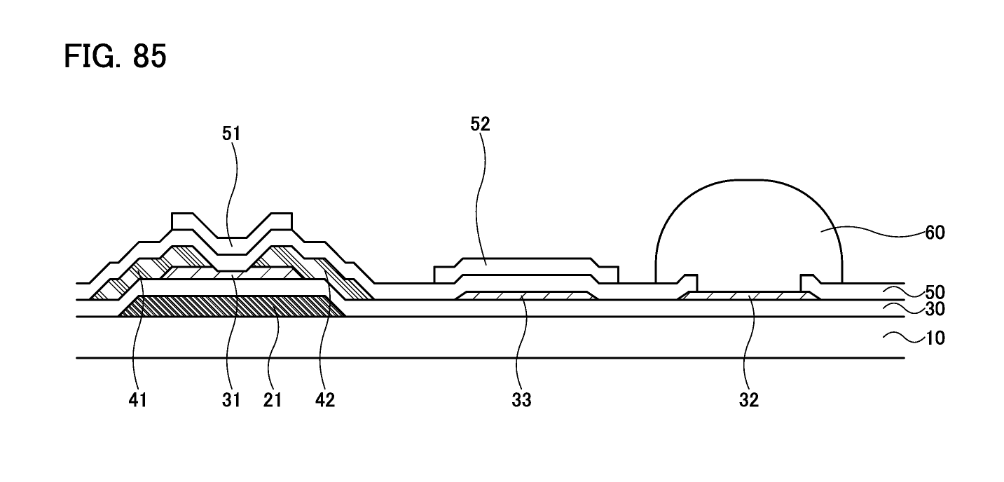

For example, FIG. 85 illustrates an example of a drawing which is different from FIG. 75 in that the resin layer 60 is provided locally.

Note that a similar structure can be used also in a mode using any of the structures of FIGS. 126A to 126C.

The resin layer 60 includes a portion being in contact with the oxide semiconductor layer 32.

It is preferable that the resin layer 60 do not overlap with the oxide semiconductor layer 31 at all.

The resin layer 60 may include a region that overlaps with the oxide semiconductor layer 31 and a region that does not overlap with the oxide semiconductor layer 31.

It is preferable that the resin layer 60 do not overlap with the oxide semiconductor layer 33 at all.

The resin layer 60 may include a region that overlaps with the oxide semiconductor layer 33 and a region that does not overlap with the oxide semiconductor layer 33.

The resin layer 60 includes a region that does not overlap with the oxide semiconductor layer 31. Thus, it is possible to reduce the amount of H₂O entering the oxide semiconductor layer 31 through the inorganic insulating layer 50.

In the case where the resin layer 60 does not overlap with the oxide semiconductor layer 31 at all, the amount of H₂O entering the oxide semiconductor layer 31 through the inorganic insulating layer 50 can be greatly reduced.

The resin layer 60 includes a region that does not overlap with the oxide semiconductor layer 33. Thus, it is possible to reduce the amount of H₂O entering the oxide semiconductor layer 33 through the inorganic insulating layer 50.

In the case where the resin layer 60 does not overlap with the oxide semiconductor layer 33 at all, the amount of H₂O entering the oxide semiconductor layer 33 through the inorganic insulating layer 50 can be greatly reduced.

At least part of the structure described in this embodiment can be combined with at least part of a structure described in any of the other embodiments.

### Embodiment 31

A layer containing hydrogen may be used instead of the resin layer.

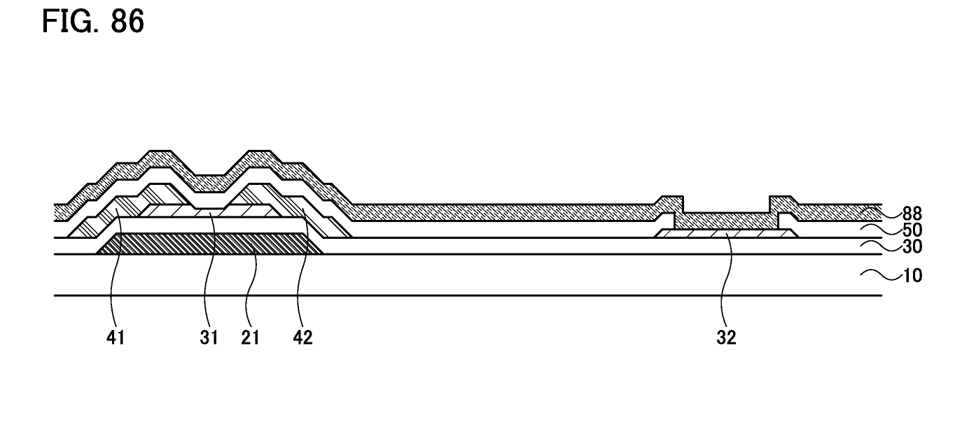

For example, FIG. 86 illustrates an example of a drawing which is different from FIG. 1 in that a layer 88 containing hydrogen is provided instead of the resin layer 60.

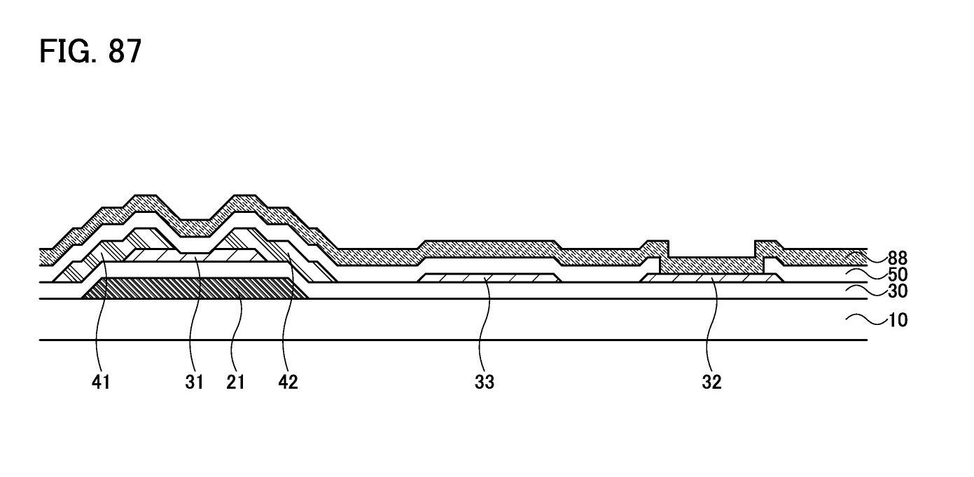

For example, FIG. 87 illustrates an example of a drawing which is different from FIG. 2 in that the layer 88 containing hydrogen is provided instead of the resin layer 60.

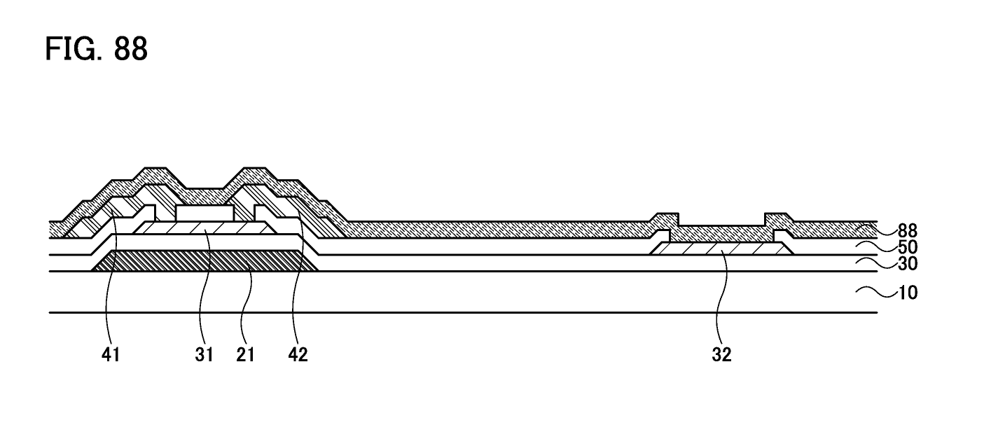

For example, FIG. 88 illustrates an example of a drawing which is different from FIG. 60 in that the layer 88 containing hydrogen is provided instead of the resin layer 60.

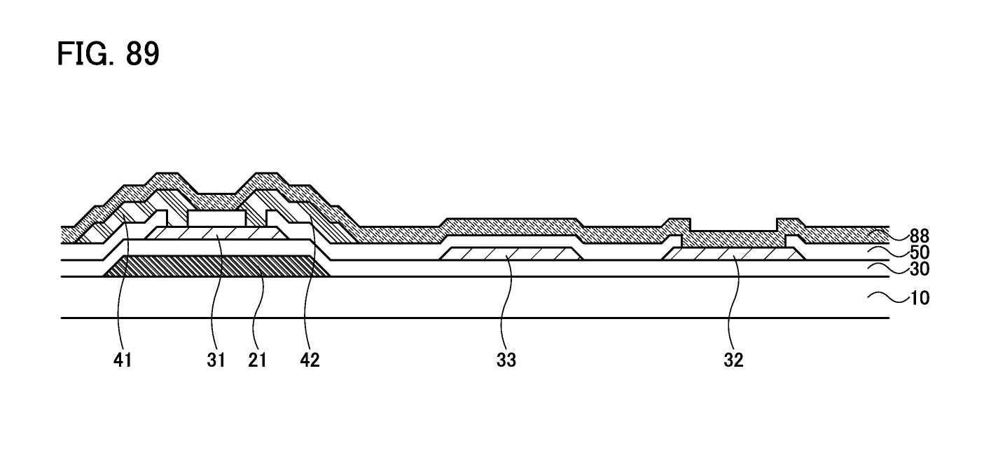

For example, FIG. 89 illustrates an example of a drawing which is different from FIG. 61 in that the layer 88 containing hydrogen is provided instead of the resin layer 60.

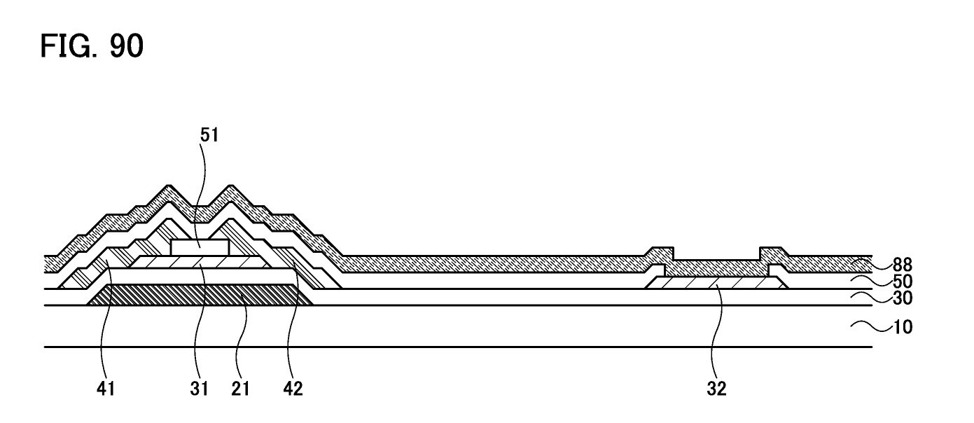

For example, FIG. 90 illustrates an example of a drawing which is different from FIG. 70 in that the layer 88 containing hydrogen is provided instead of the resin layer 60.

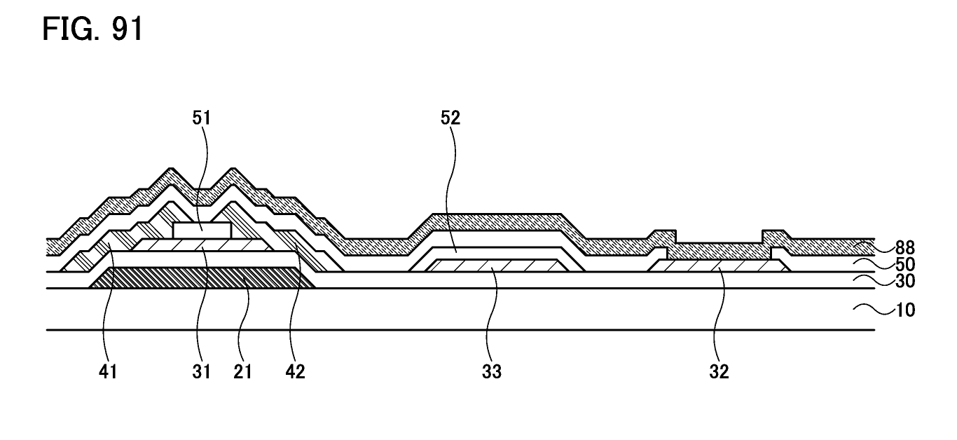

For example, FIG. 91 illustrates an example of a drawing which is different from FIG. 71 in that the layer 88 containing hydrogen is provided instead of the resin layer 60.

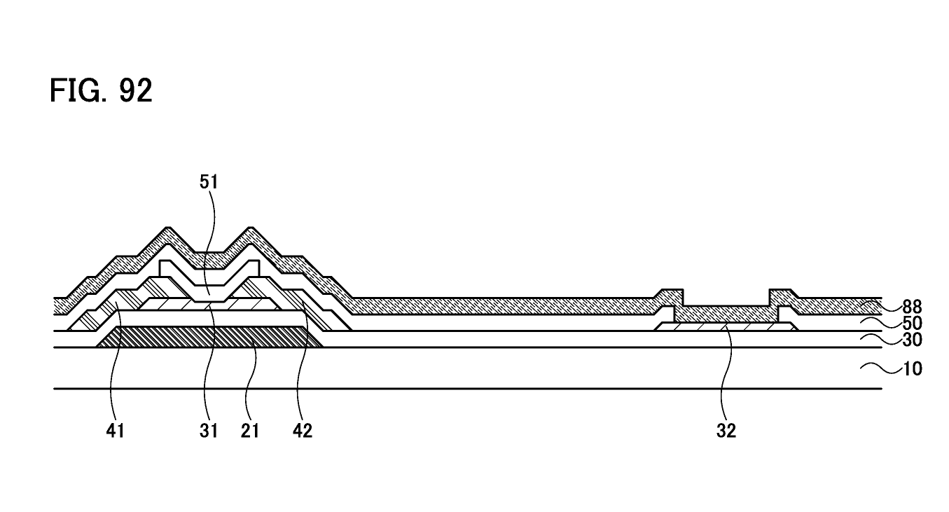

For example, FIG. 92 illustrates an example of a drawing which is different from FIG. 72 in that the layer 88 containing hydrogen is provided instead of the resin layer 60.

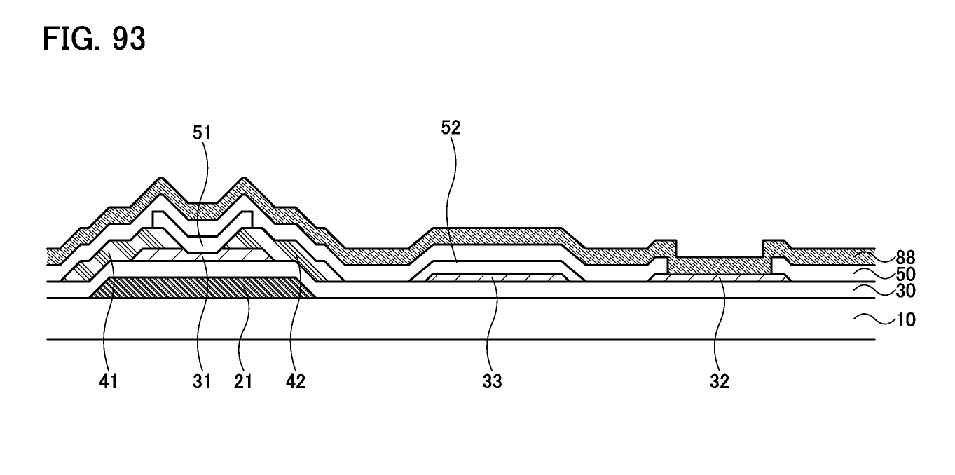

For example, FIG. 93 illustrates an example of a drawing which is different from FIG. 73 in that the layer 88 containing hydrogen is provided instead of the resin layer 60.

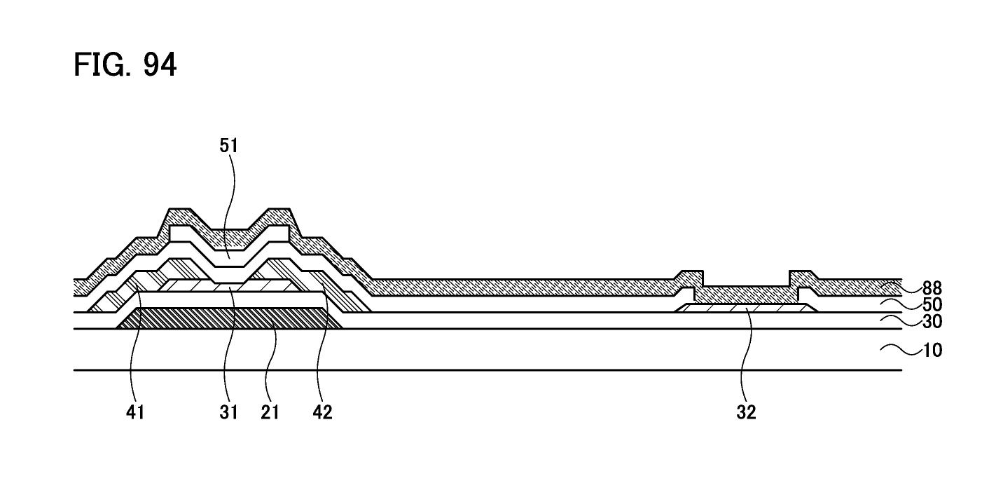

For example, FIG. 94 illustrates an example of a drawing which is different from FIG. 74 in that the layer 88 containing hydrogen is provided instead of the resin layer 60.

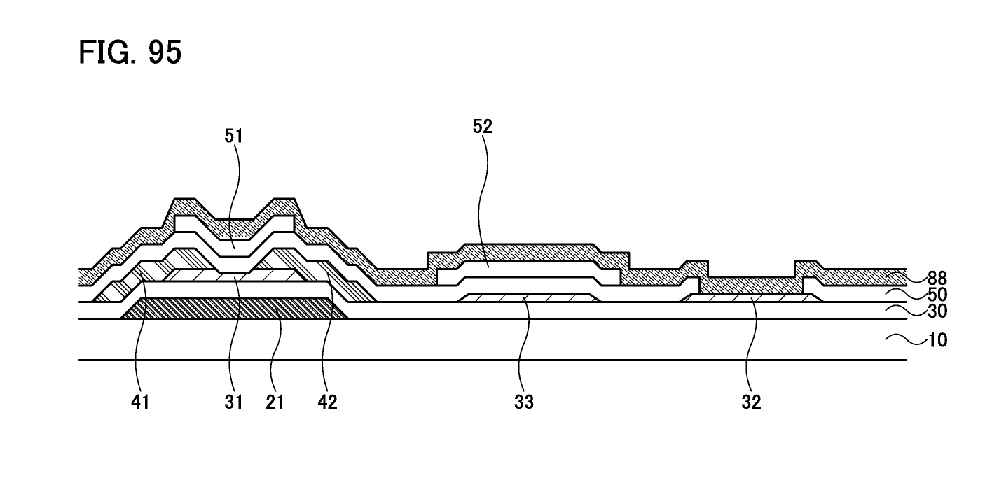

For example, FIG. 95 illustrates an example of a drawing which is different from FIG. 75 in that the layer 88 containing hydrogen is provided instead of the resin layer 60.

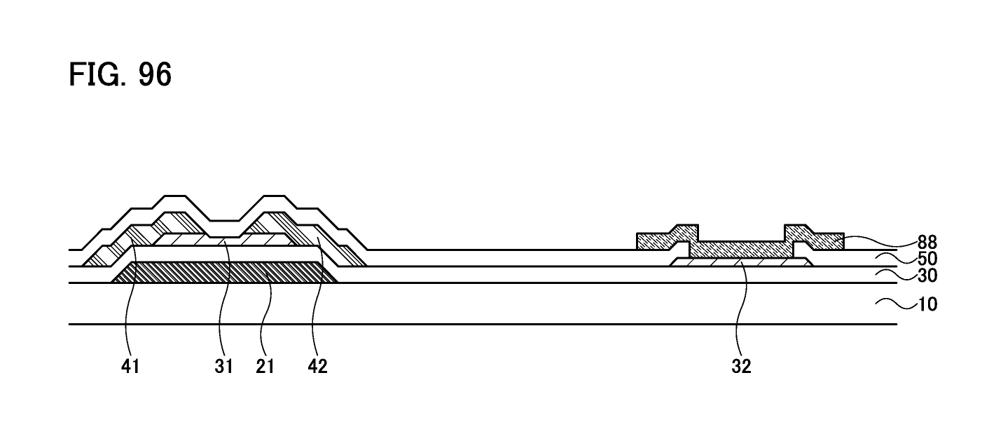

For example, FIG. 96 illustrates an example of a drawing which is different from FIG. 76 in that the layer 88 containing hydrogen is provided instead of the resin layer 60.

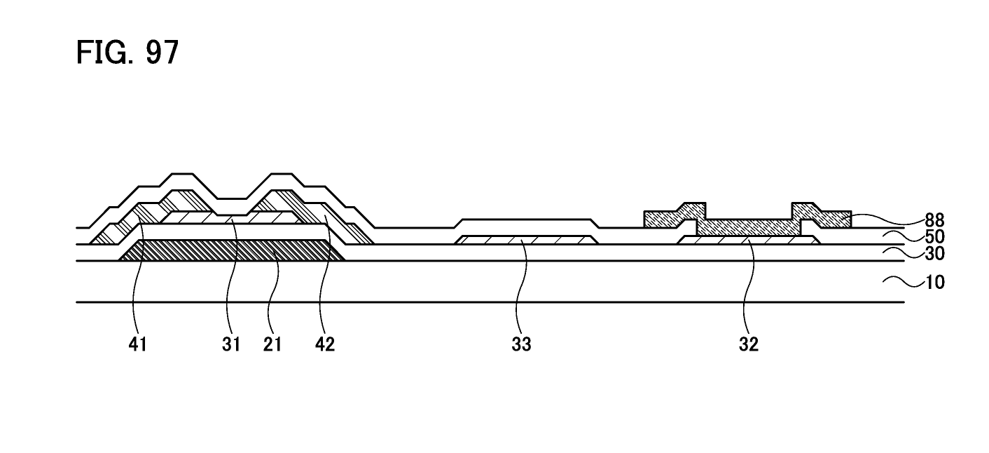

For example, FIG. 97 illustrates an example of a drawing which is different from FIG. 77 in that the layer 88 containing hydrogen is provided instead of the resin layer 60.

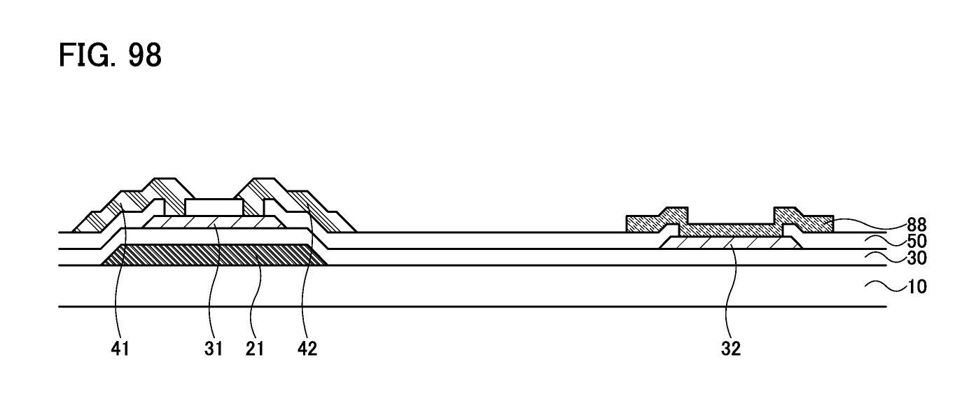

For example, FIG. 98 illustrates an example of a drawing which is different from FIG. 78 in that the layer 88 containing hydrogen is provided instead of the resin layer 60.

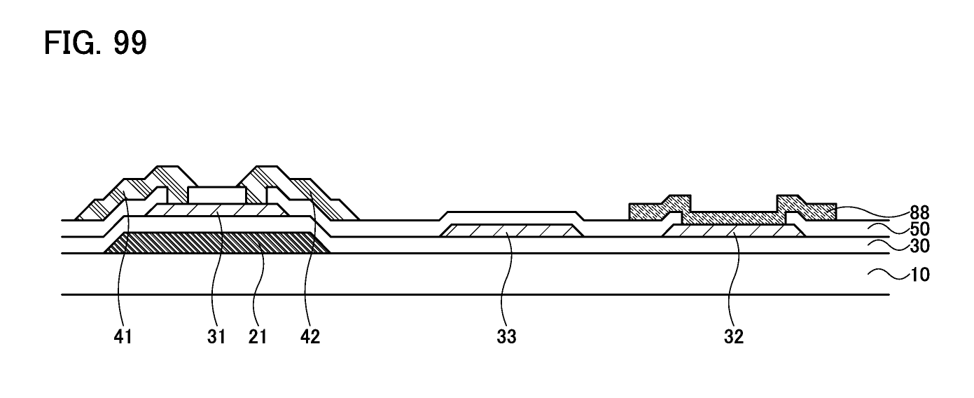

For example, FIG. 99 illustrates an example of a drawing which is different from FIG. 79 in that the layer 88 containing hydrogen is provided instead of the resin layer 60.

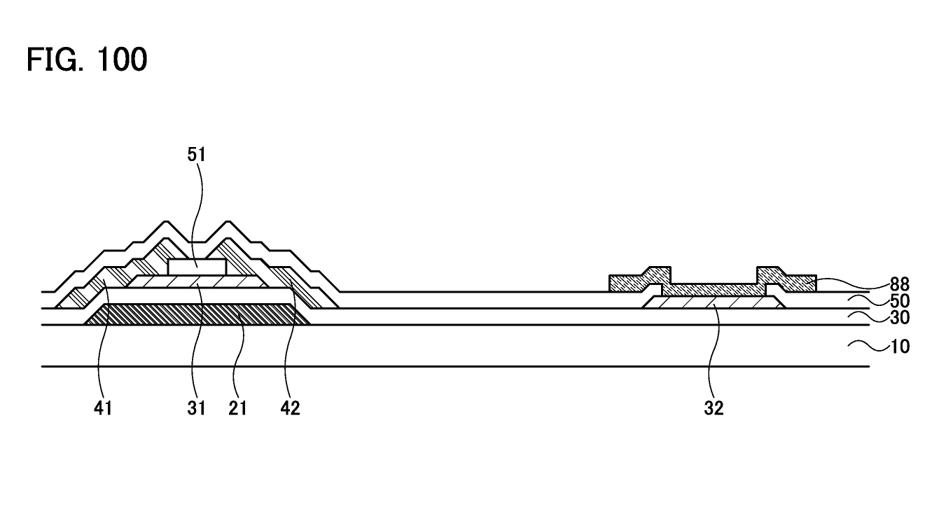

For example, FIG. 100 illustrates an example of a drawing which is different from FIG. 80 in that the layer 88 containing hydrogen is provided instead of the resin layer 60.

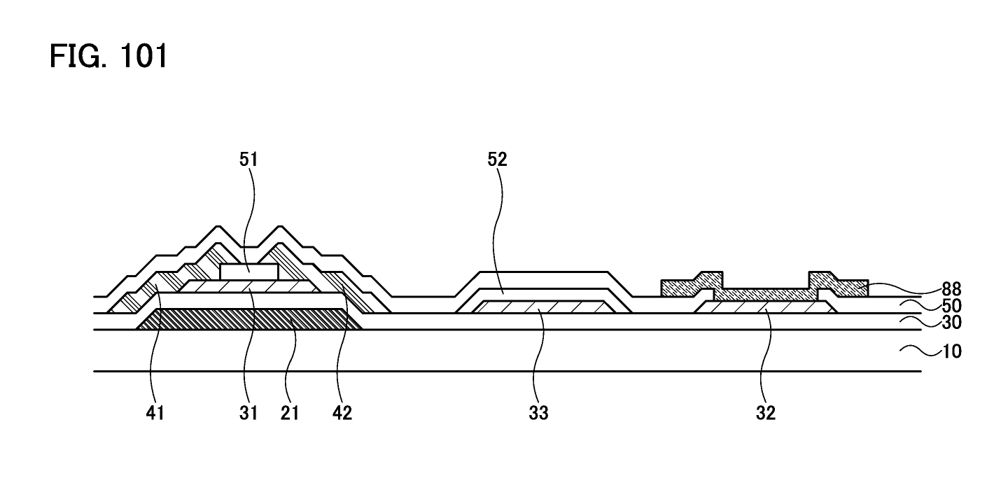

For example, FIG. 101 illustrates an example of a drawing which is different from FIG. 81 in that the layer 88 containing hydrogen is provided instead of the resin layer 60.

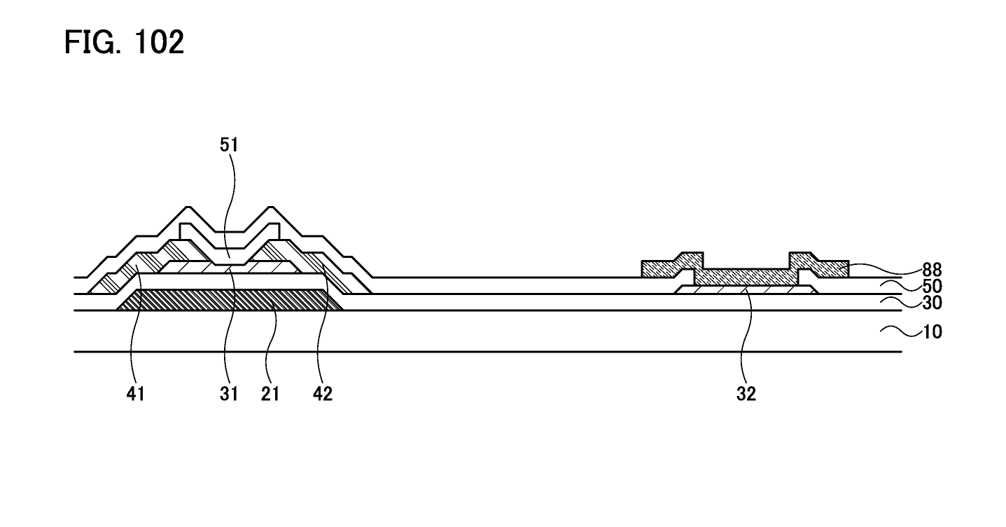

For example, FIG. 102 illustrates an example of a drawing which is different from FIG. 82 in that the layer 88 containing hydrogen is provided instead of the resin layer 60.

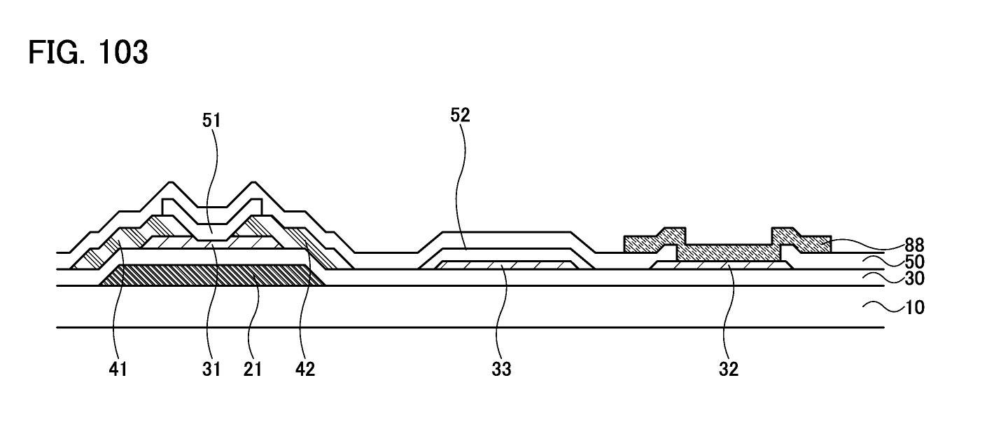

For example, FIG. 103 illustrates an example of a drawing which is different from FIG. 83 in that the layer 88 containing hydrogen is provided instead of the resin layer 60.

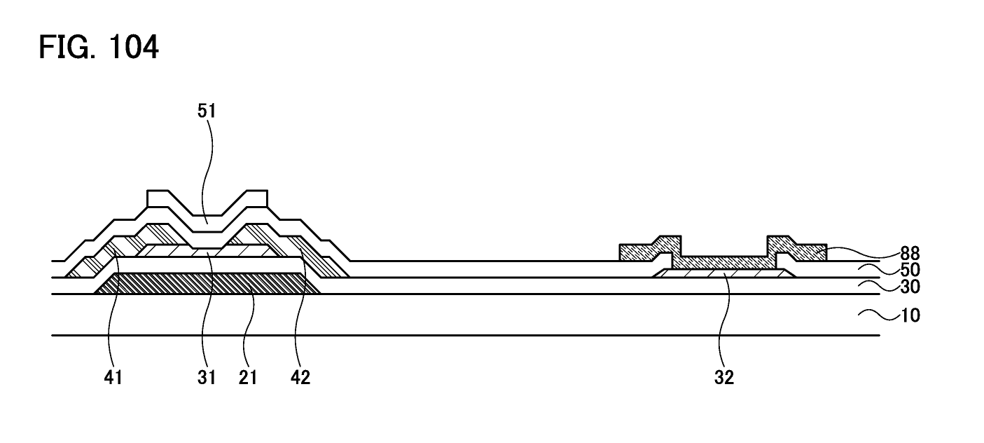

For example, FIG. 104 illustrates an example of a drawing which is different from FIG. 84 in that the layer 88 containing hydrogen is provided instead of the resin layer 60.

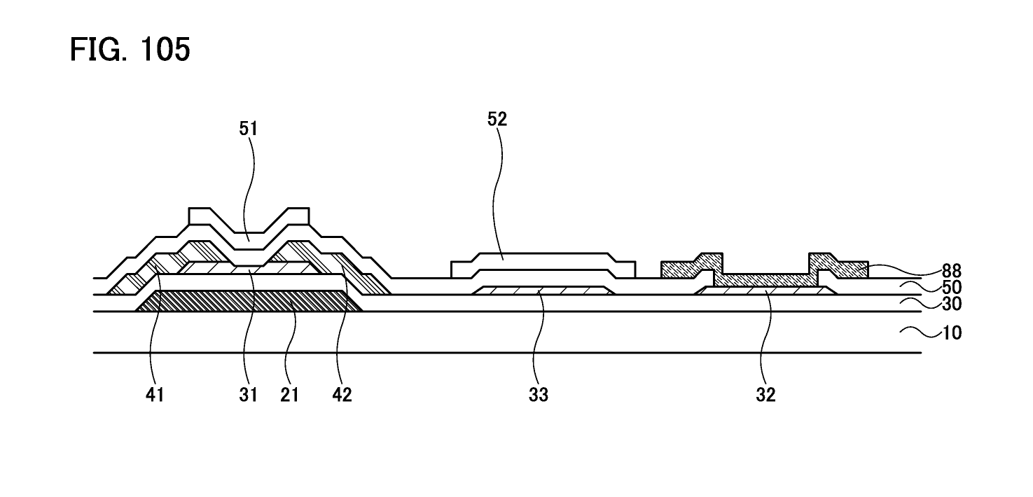

For example, FIG. 105 illustrates an example of a drawing which is different from FIG. 85 in that the layer 88 containing hydrogen is provided instead of the resin layer 60.

Note that a similar structure can be used also in a mode using any of the structures of FIGS. 126A to 126C.

The content of H in the layer 88 containing hydrogen is preferably higher than that in the inorganic insulating layer 50.

The layer 88 containing hydrogen can be formed using an insulating layer (an inorganic insulating layer, a resin layer, or the like), a semiconductor layer, a conductive layer, or the like.

The inorganic insulating layer, the semiconductor layer, the conductive layer, or the like can be formed using the examples described in any of other embodiments, for example.

The layer 88 containing hydrogen is further preferably a layer having a heat dissipation property.

Examples of a method for forming the layer 88 containing hydrogen include the following.

For example, after a predetermined layer (an insulating layer, a semiconductor layer, a conductive layer, or the like) is formed, a substance containing H is made to be contained in the predetermined layer; thus, the layer containing hydrogen can be formed.

A method in which a substance containing H is added by ion doping or ion implantation is given, for example; however, the method for forming the layer containing hydrogen is not limited to this.

For example, a substance containing H is added to a film formation gas when a predetermined layer (an insulating layer, a semiconductor layer, a conductive layer, or the like) is formed; thus, the layer containing hydrogen can be formed.

For example, there are a method in which a substance containing H is used for a film formation gas when the predetermined layer is formed by a sputtering method and a method in which a substance containing H is used for a film formation gas when the predetermined layer is formed by a CVD method. However, the method for forming the layer containing hydrogen is not limited to these examples.

Examples of the substance containing H include H₂, H₂O, PH₃, and B₂H₆, but the substance containing H is not limited to these examples.

Note that when H in the oxide semiconductor layer 32 is released, the H is released in a state where the H is bonded to O in the oxide semiconductor layer 32 in some cases.

Thus, H₂O is released from the oxide semiconductor layer 32 in some cases.

Hence, the oxide semiconductor layer 33 is preferably provided between the oxide semiconductor layer 31 and the oxide semiconductor layer 32.

Further, by providing the protective layer 51, the amount of H reaching the oxide semiconductor layer 31 from the layer 88 containing hydrogen can be reduced.

Further, by providing the protective layer 52, the amount of H reaching the oxide semiconductor layer 33 from the layer 88 containing hydrogen can be reduced.

At least part of the structure described in this embodiment can be combined with at least part of a structure described in any of the other embodiments.

### Embodiment 32

In the case where the resin layer or the layer containing hydrogen is provided locally, the resin layer or the layer containing hydrogen can be provided under the inorganic insulating layer.

In the case where the resin layer or the layer containing hydrogen is provided under the inorganic insulating layer, a hole reaching the oxide semiconductor layer is not necessarily provided in the inorganic insulating layer.

In an etching step of forming the hole reaching the oxide semiconductor layer, the oxide semiconductor layer unfortunately disappears in some cases.

To prevent this, the resin layer or the layer containing hydrogen is preferably provided under the inorganic insulating layer. Thus, the possibility for the oxide semiconductor layer to disappear can be reduced.

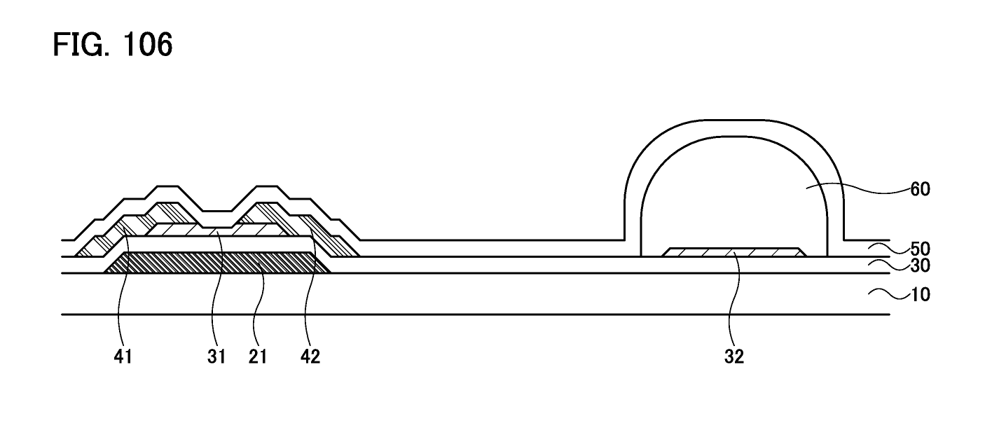

For example, FIG. 106 illustrates an example of a drawing which is different from FIG. 76 in that the resin layer 60 is provided between the oxide semiconductor layer 32 and the inorganic insulating layer 50.

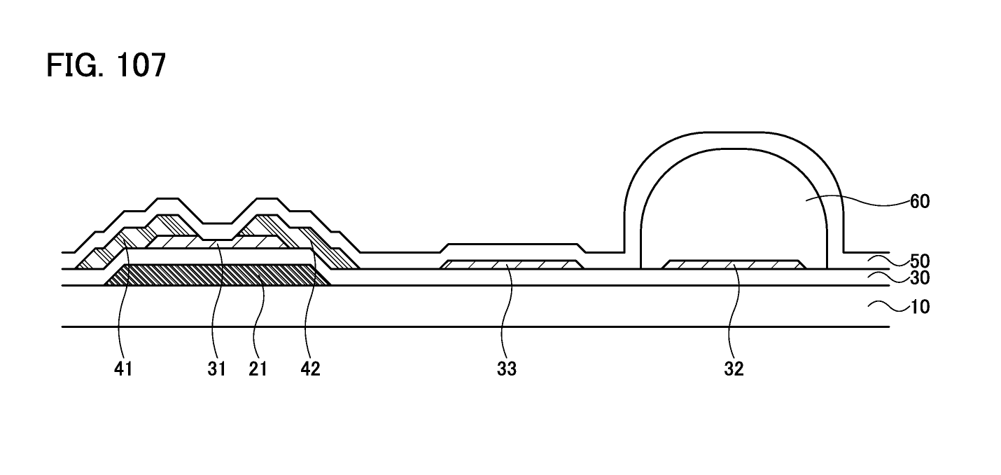

For example, FIG. 107 illustrates an example of a drawing which is different from FIG. 77 in that the resin layer 60 is provided between the oxide semiconductor layer 32 and the inorganic insulating layer 50.

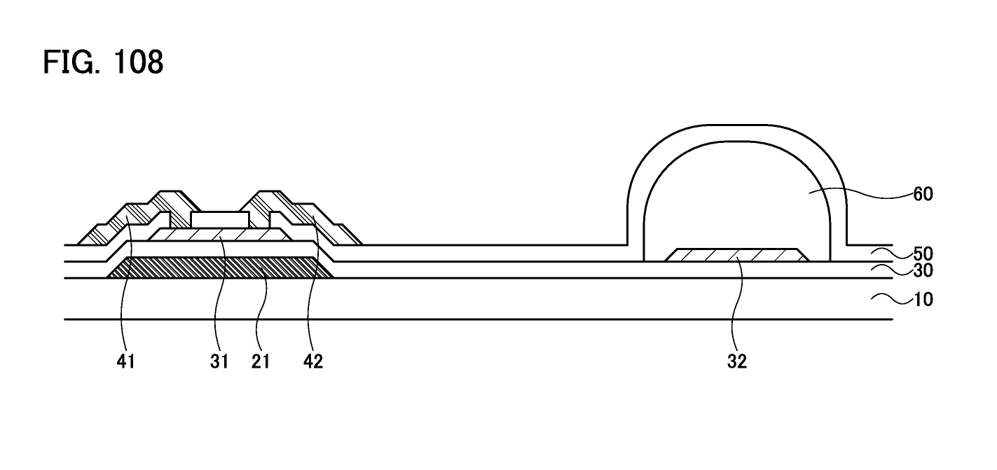

For example, FIG. 108 illustrates an example of a drawing which is different from FIG. 78 in that the resin layer 60 is provided between the oxide semiconductor layer 32 and the inorganic insulating layer 50.

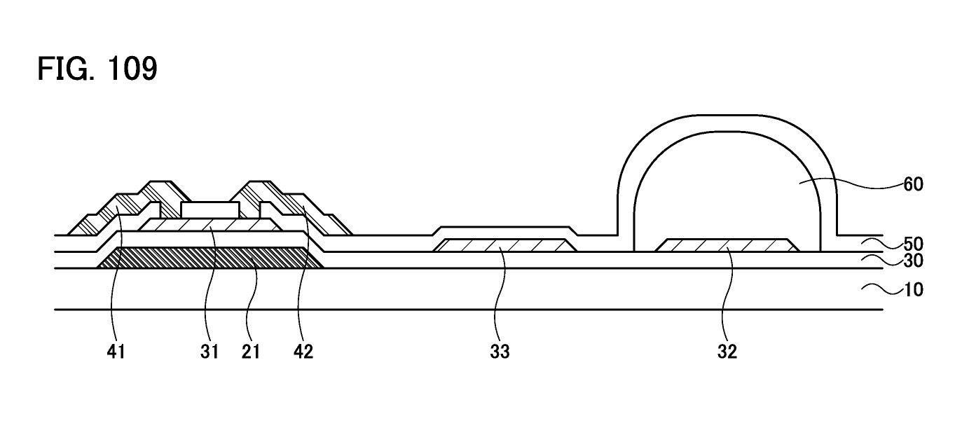

For example, FIG. 109 illustrates an example of a drawing which is different from FIG. 79 in that the resin layer 60 is provided between the oxide semiconductor layer 32 and the inorganic insulating layer 50.

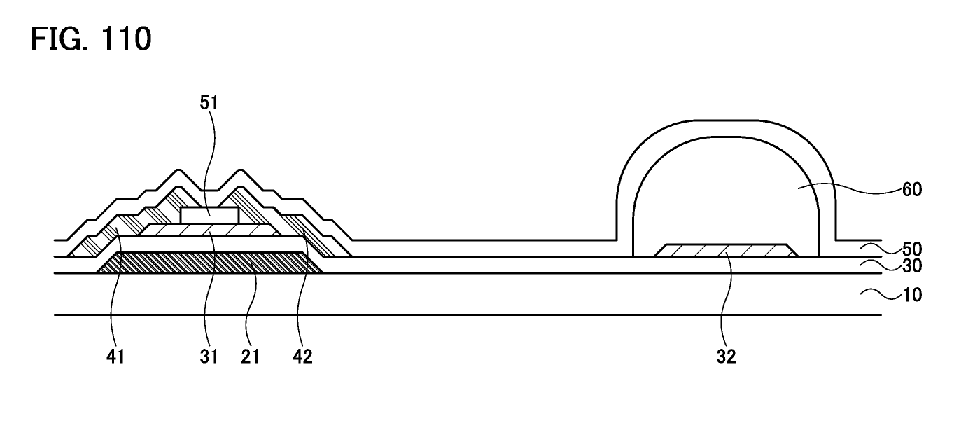

For example, FIG. 110 illustrates an example of a drawing which is different from FIG. 80 in that the resin layer 60 is provided between the oxide semiconductor layer 32 and the inorganic insulating layer 50.

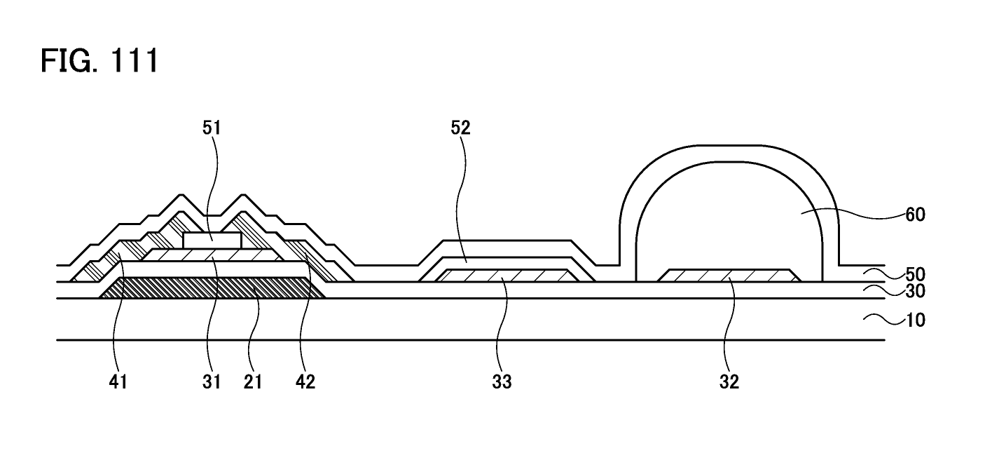

For example, FIG. 111 illustrates an example of a drawing which is different from FIG. 81 in that the resin layer 60 is provided between the oxide semiconductor layer 32 and the inorganic insulating layer 50.

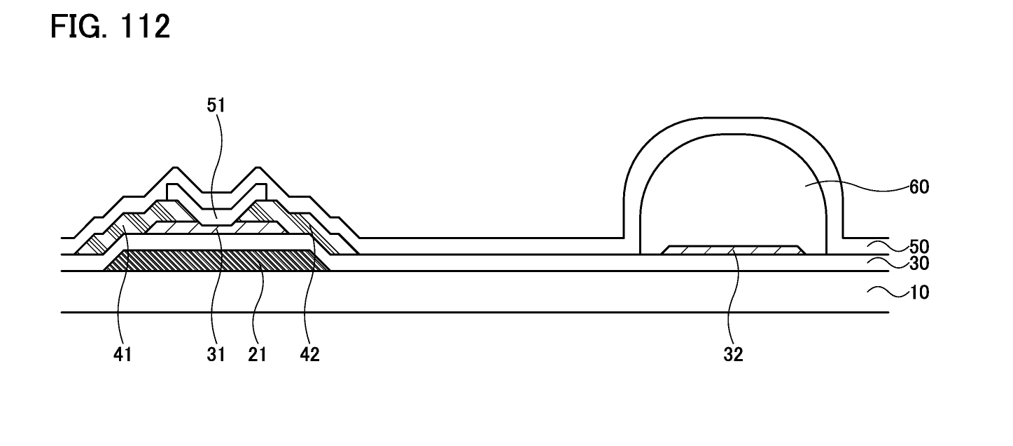

For example, FIG. 112 illustrates an example of a drawing which is different from FIG. 82 in that the resin layer 60 is provided between the oxide semiconductor layer 32 and the inorganic insulating layer 50.

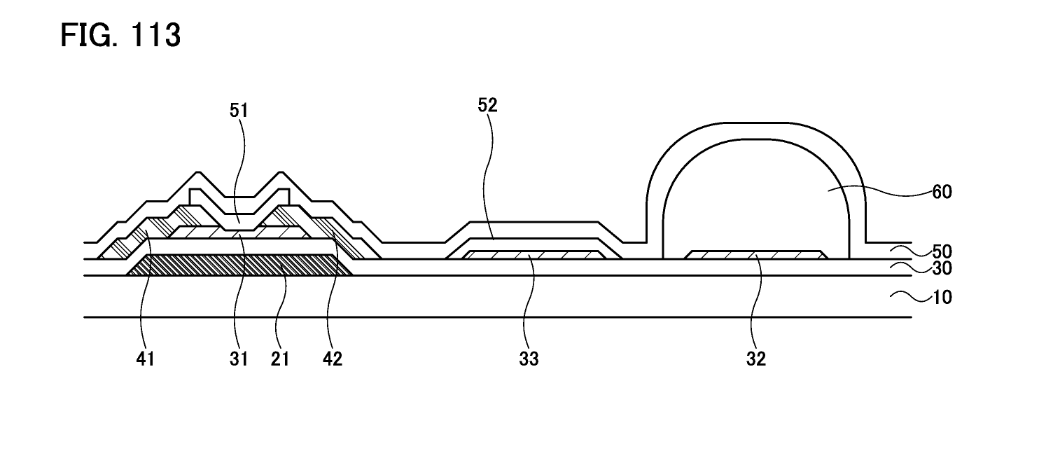

For example, FIG. 113 illustrates an example of a drawing which is different from FIG. 83 in that the resin layer 60 is provided between the oxide semiconductor layer 32 and the inorganic insulating layer 50.

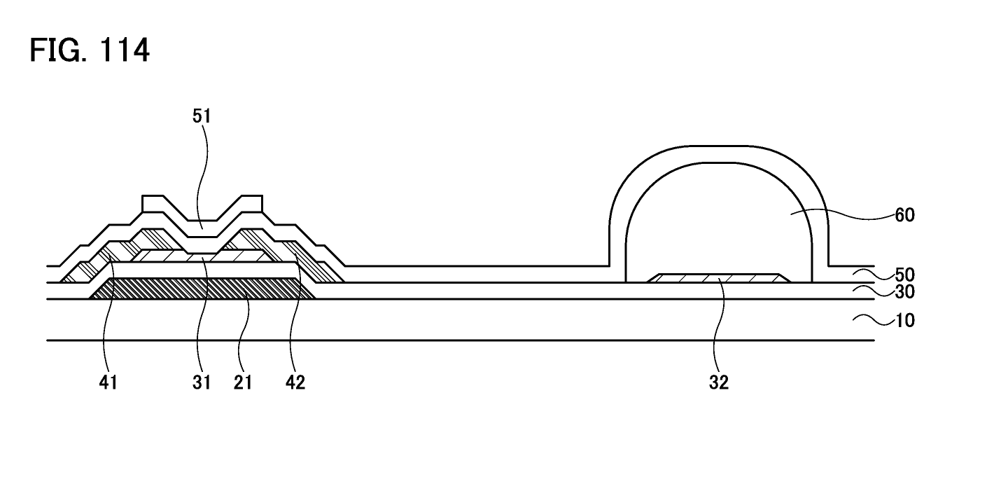

For example, FIG. 114 illustrates an example of a drawing which is different from FIG. 84 in that the resin layer 60 is provided between the oxide semiconductor layer 32 and the inorganic insulating layer 50.

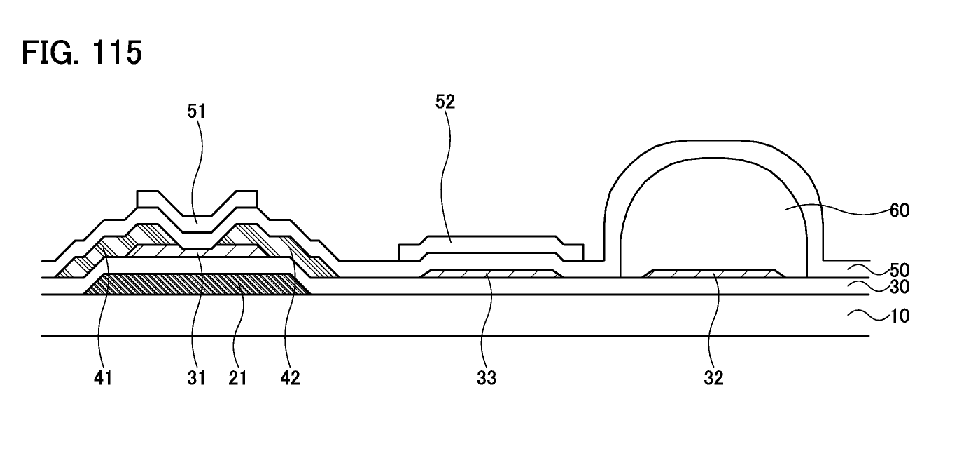

For example, FIG. 115 illustrates an example of a drawing which is different from FIG. 85 in that the resin layer 60 is provided between the oxide semiconductor layer 32 and the inorganic insulating layer 50.

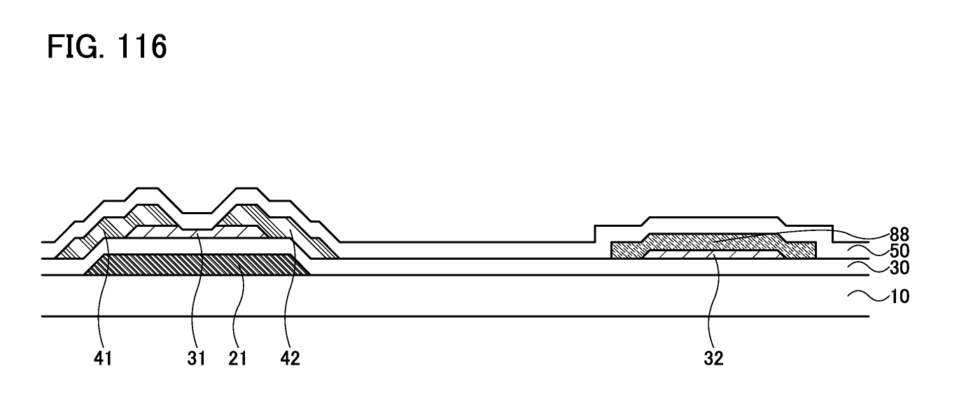

For example, FIG. 116 illustrates an example of a drawing which is different from FIG. 96 in that the layer 88 containing hydrogen is provided between the oxide semiconductor layer 32 and the inorganic insulating layer 50.

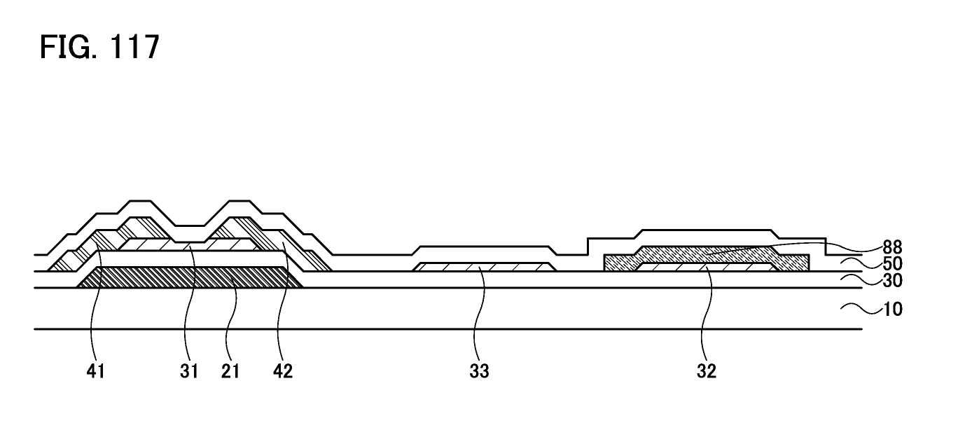

For example, FIG. 117 illustrates an example of a drawing which is different from FIG. 97 in that the layer 88 containing hydrogen is provided between the oxide semiconductor layer 32 and the inorganic insulating layer 50.

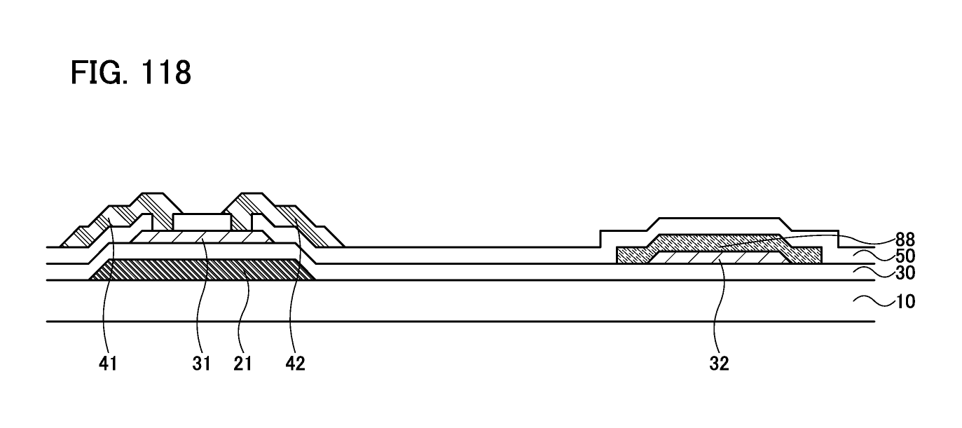

For example, FIG. 118 illustrates an example of a drawing which is different from FIG. 98 in that the layer 88 containing hydrogen is provided between the oxide semiconductor layer 32 and the inorganic insulating layer 50.

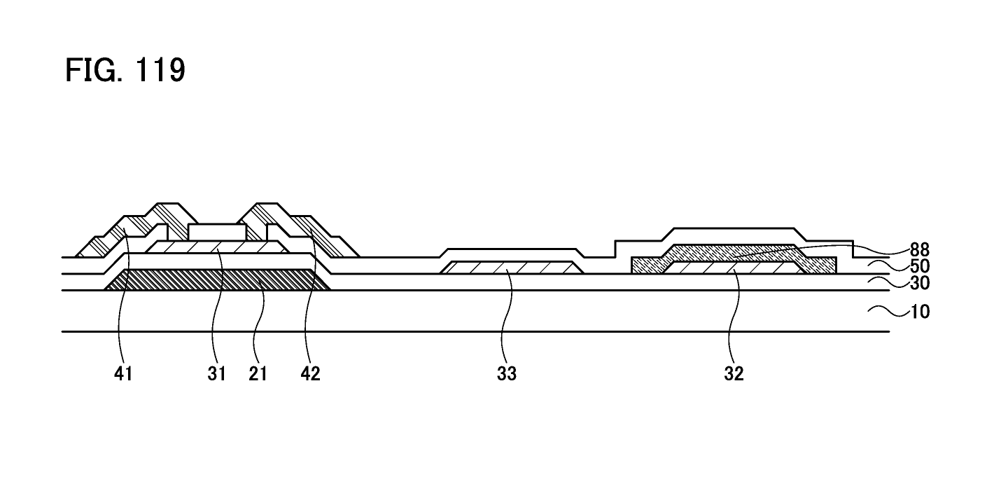

For example, FIG. 119 illustrates an example of a drawing which is different from FIG. 99 in that the layer 88 containing hydrogen is provided between the oxide semiconductor layer 32 and the inorganic insulating layer 50.

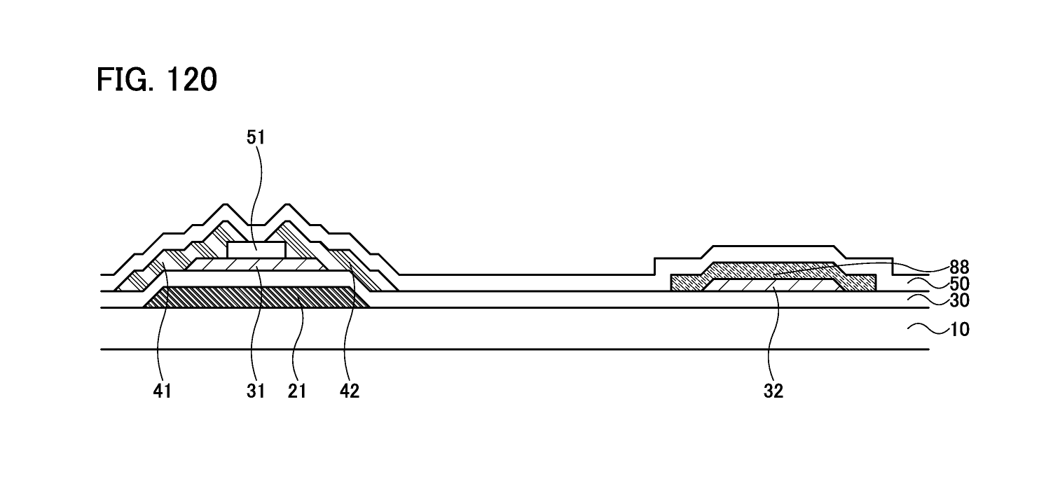

For example, FIG. 120 illustrates an example of a drawing which is different from FIG. 100 in that the layer 88 containing hydrogen is provided between the oxide semiconductor layer 32 and the inorganic insulating layer 50.

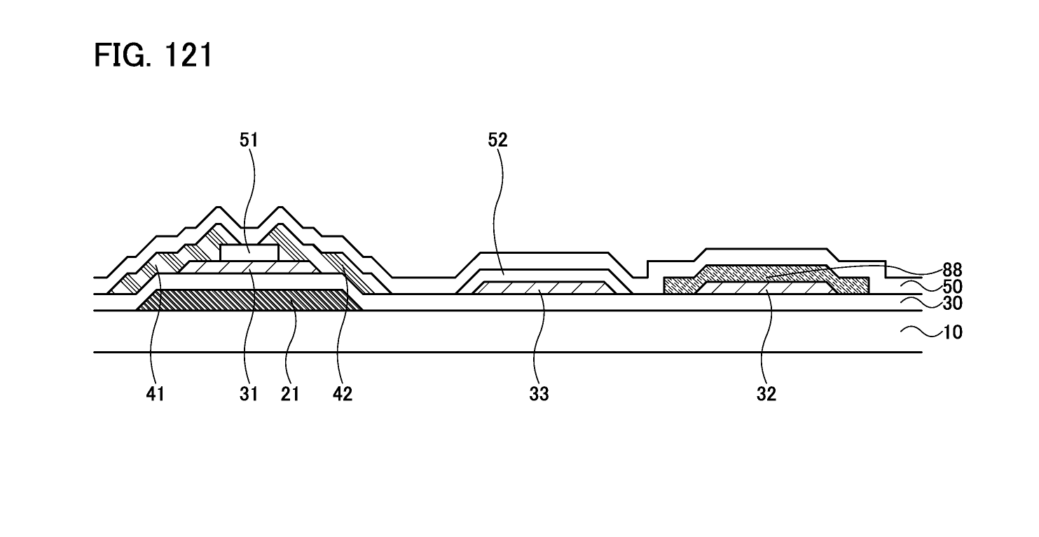

For example, FIG. 121 illustrates an example of a drawing which is different from FIG. 101 in that the layer 88 containing hydrogen is provided between the oxide semiconductor layer 32 and the inorganic insulating layer 50.

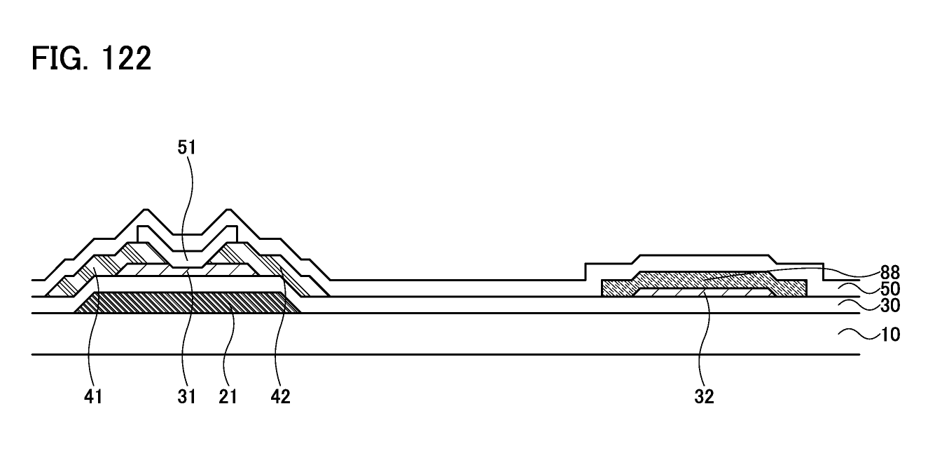

For example, FIG. 122 illustrates an example of a drawing which is different from FIG. 102 in that the layer 88 containing hydrogen is provided between the oxide semiconductor layer 32 and the inorganic insulating layer 50.

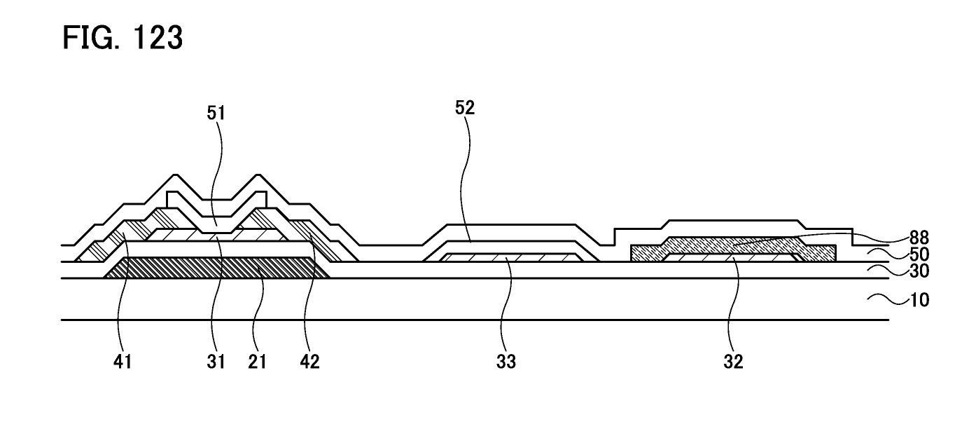

For example, FIG. 123 illustrates an example of a drawing which is different from FIG. 103 in that the layer 88 containing hydrogen is provided between the oxide semiconductor layer 32 and the inorganic insulating layer 50.

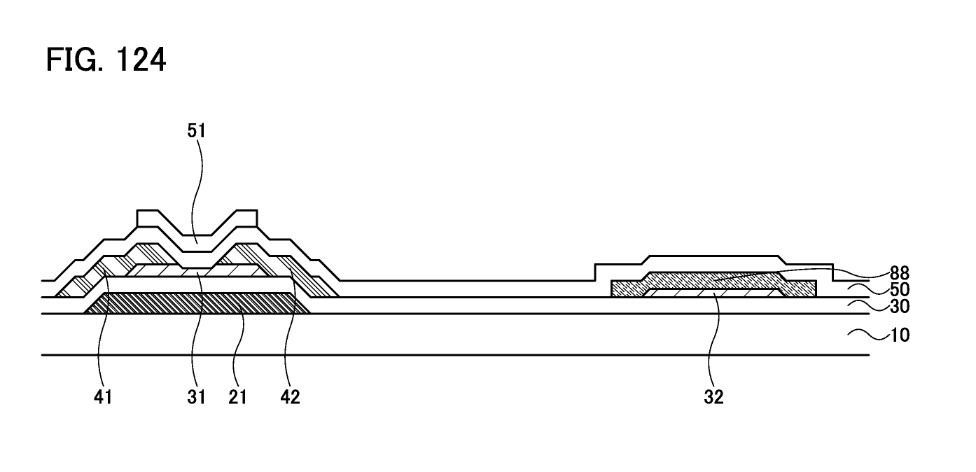

For example, FIG. 124 illustrates an example of a drawing which is different from FIG. 104 in that the layer 88 containing hydrogen is provided between the oxide semiconductor layer 32 and the inorganic insulating layer 50.

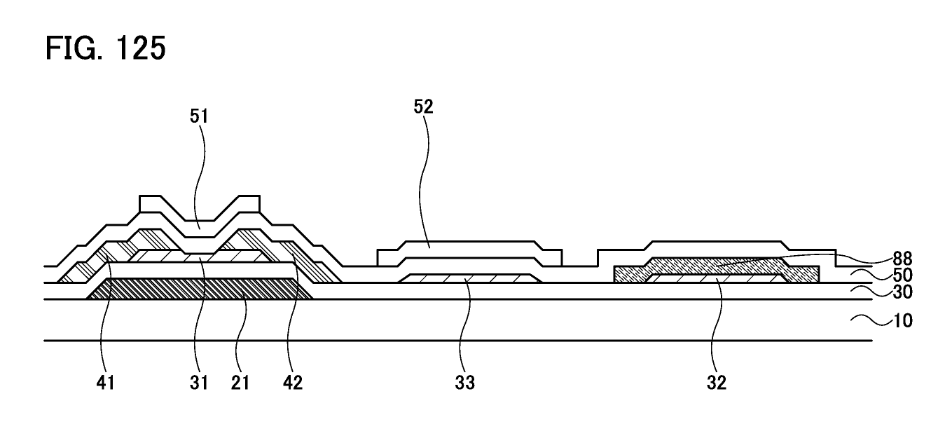

For example, FIG. 125 illustrates an example of a drawing which is different from FIG. 105 in that the layer 88 containing hydrogen is provided between the oxide semiconductor layer 32 and the inorganic insulating layer 50.

Note that a similar structure can be used also in a mode using any of the structures of FIGS. 126A to 126C.

At least part of the structure described in this embodiment can be combined with at least part of a structure described in any of the other embodiments.

This application is based on Japanese Patent Application serial no. 2012-156885 filed with Japan Patent Office on Jul. 12, 2012, the entire contents of which are hereby incorporated by reference.

What is claimed is:

1. A semiconductor device comprising:
a first semiconductor layer and a second semiconductor layer, wherein a transistor comprises the first semiconductor layer;
an insulating layer over the second semiconductor layer and the transistor; and
a resin layer over the insulating layer,
wherein the second semiconductor layer comprises a first region which is in contact with the insulating layer and a second region which is in contact with the resin layer.

2. The semiconductor device according to claim 1, wherein each of the first semiconductor layer and the second semiconductor layer comprises an oxide semiconductor.

3. The semiconductor device according to claim 2, wherein the oxide semiconductor comprises at least one of indium, gallium, and zinc.

4. The semiconductor device according to claim 1, further comprising:
a first substrate under the transistor;
a first conductive layer over the resin layer, the first conductive layer electrically connected to the transistor;
a liquid crystal layer over the first conductive layer;
a second conductive layer over the liquid crystal layer; and
a second substrate over the second conductive layer.

5. The semiconductor device according to claim 1, wherein a content of H₂O in the second semiconductor layer is higher than a content of H₂O in the first semiconductor layer.

6. The semiconductor device according to claim 1, wherein a content of hydrogen in the second semiconductor layer is higher than a content of hydrogen in the first semiconductor layer.

7. The semiconductor device according to claim 1, wherein the second semiconductor layer is included in a part of a wiring, an electrode, a resistor, or a transistor.

8. A semiconductor device comprising:
a first conductive layer over a substrate;
a first insulating layer over the first conductive layer;
a first oxide semiconductor layer and a second oxide semiconductor layer over the first insulating layer, the first oxide semiconductor layer overlapping with the first conductive layer;
a second conductive layer and a third conductive layer which overlap with the first oxide semiconductor layer;
a second insulating layer over the second oxide semiconductor layer, the second conductive layer, and the third conductive layer; and
a resin layer over the second insulating layer,
wherein the second oxide semiconductor layer comprises a first region which is in contact with the second insulating layer and a second region which is in contact with the resin layer.

9. The semiconductor device according to claim 8, wherein each of the first oxide semiconductor layer and the second oxide semiconductor layer comprises at least one of indium, gallium, and zinc.

10. The semiconductor device according to claim 8, further comprising:
a fourth conductive layer over the resin layer, the fourth conductive layer electrically connected to one of the second conductive layer and the third conductive layer;
a liquid crystal layer over the fourth conductive layer;
a fifth conductive layer over the liquid crystal layer; and
a second substrate over the fifth conductive layer.

11. The semiconductor device according to claim 8, wherein a content of H₂O in the second oxide semiconductor layer is higher than a content of H₂O in the first oxide semiconductor layer.

12. The semiconductor device according to claim 8, wherein a content of hydrogen in the second oxide semiconductor layer is higher than a content of hydrogen in the first oxide semiconductor layer.

13. The semiconductor device according to claim 8, wherein the second oxide semiconductor layer is included in a part of a wiring, an electrode, a resistor, or a transistor.

14. A semiconductor device comprising:
a first conductive layer over a substrate;
a first insulating layer over the first conductive layer;
a first oxide semiconductor layer, a second oxide semiconductor layer, and a third oxide semiconductor layer over the first insulating layer, the first oxide semiconductor layer overlapping with the first conductive layer;
a second conductive layer and a third conductive layer which overlap with the first oxide semiconductor layer;
a second insulating layer over the second oxide semiconductor layer, the third oxide semiconductor layer, the second conductive layer, and the third conductive layer; and
a resin layer over the second insulating layer,
wherein the second oxide semiconductor layer comprises a first region which is in contact with the second insulating layer and a second region which is in contact with the resin layer, and
wherein the third oxide semiconductor layer is located between the first oxide semiconductor layer and the second oxide semiconductor layer.

15. The semiconductor device according to claim 14, wherein each of the first oxide semiconductor layer and the second oxide semiconductor layer comprises at least one of indium, gallium, and zinc.

16. The semiconductor device according to claim 14, further comprising:
a fourth conductive layer over the resin layer, the fourth conductive layer electrically connected to one of the second conductive layer and the third conductive layer;
a liquid crystal layer over the fourth conductive layer;
a fifth conductive layer over the liquid crystal layer; and
a second substrate over the fifth conductive layer.

17. The semiconductor device according to claim 14, wherein a content of H₂O in the second oxide semiconductor layer is higher than a content of H₂O in the first oxide semiconductor layer.

18. The semiconductor device according to claim 14, wherein a content of hydrogen in the second oxide semiconductor layer is higher than a content of hydrogen in the first oxide semiconductor layer.

19. The semiconductor device according to claim 14, wherein the second oxide semiconductor layer is included in a part of a wiring, an electrode, a resistor, or a transistor.

20. The semiconductor device according to claim 14, wherein the third oxide semiconductor layer is electrically insulated from the first oxide semiconductor layer and the second oxide semiconductor layer.
